(19) United States
(12) Patent Application Publication
(10) Pub. No.: US 2009/0039336 A1
(43) Pub. Date: Feb. 12, 2009

(54) SEMICONDUCTOR DEVICE

(75) Inventors: Motoyasu Terao, Hinode (JP); Yoshitaka Sasago, Tachikawa (JP); Kenzo Kurotsuchi, Kodaira (JP); Kazuo Ono, Kodaira (JP); Yoshihisa Fujisaki, Hachioji (JP); Norikatsu Takaura, Tokyo (JP); Riichiro Takemura, Los Angeles, CA (US)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/176,606

(22) Filed: Jul. 21, 2008

(30) Foreign Application Priority Data
Aug. 8, 2007 (JP) JP2007-206890

(51) Int. Cl. H01L 45/00

(52) U.S. Cl. 257/4; 257/E45.002

(57) ABSTRACT

The performance of a semiconductor device capable of storing information is improved. A memory layer of a memory element is formed by a first layer at a bottom electrode side and a second layer at a top electrode side. The first layer contains 20-70 atom % of at least one element of a first element group of Cu, Ag, Au, Al, Zn, and Cd, contains 3-40 atom % of at least one element of a second element group of V, Nb, Ta, Cr, Mo, W, Ti, Zr, Hf, Fe, Co, Ni, Pt, Pd, Rh, Ir, Ru, Os, and lanthanoid elements, and contains 20-60 atom % of at least one element of a third element group of S, Se, and Te. The second layer contains 5-50 atom % of at least one element of the first element group, 10-50 atom % of at least one element of the second element group, and 30-70 atom % of oxygen.

### CROSS-REFERENCE TO RELATED APPLICATION

The present application claims priority from Japanese Patent Application No. JP 2007-206890 filed on Aug. 8, 2007, the content of which is hereby incorporated by reference into this application.

### TECHNICAL FIELD OF THE INVENTION

The present invention relates to a semiconductor device. More particularly, the present invention relates to a semiconductor device having a non-volatile storage element.

### BACKGROUND OF THE INVENTION

A non-volatile memory called a polarized memory or a solid electrolyte memory has been known (for example, see Japanese Patent Application Laid-Open Publication No. 2005-197634 (Patent Document 1); T. Sakamoto, S. Kaeriyama, H. Sunamura, M. Mizuno, H. Kawaura, T. Hasegawa, K. Terabe, T. Nakayama and M. Aono, “2004 IEEE International Solid State Circuits Conference (ISSCC)”, Digest of Technical Papers, USA, 2004, No. 16.3, p. 290 (Non-Patent Document 1); and M. N. Kozicki, C. Gopalan, M. Balakrishnan, M. Park, and M. Mitkova, “Non-Volatile Memory Based on Solid Electrolytes,” Proc. Non-Volatile Memory Technology Symposium (NVMTS) 2004, USA, 2004, pp. 10-17 (Non-Patent Document 2)). This is a memory in which memory information is written when the resistance of a storage element is changed depending on the direction of the voltage applied to the storage element. This memory uses the resistance value as a signal; therefore, the read signal thereof is large and sensing operation is easy. Depending on the state, the resistance value is changed by three digits to five digits.

### SUMMARY OF THE INVENTION

According to a study of the inventors of the present invention, the following has been found out.

In a metal-chalcogenide solid electrolyte memory in which a metal is used for electrodes, chalcogenide is used as a solid electrolyte, and the solid electrolyte is disposed between the electrodes, ion migration is the memory mechanism, where a low-resistance conductive path having a high concentration of positive ions of Ag, Cu, or the like is formed in a chalcogenide layer or an oxide layer. The conductive path formed by the metal ions diffused from the metal electrodes to the solid electrolyte layer (in this case, memory layer) can be controlled by controlling the voltage between the electrodes so as to change the resistance value, and it has the property of a non-volatile memory. However, when rewriting of the memory is repeated, metal ions diffuse from the metal electrodes into the solid electrolyte so that the shape of the electrode surfaces is changed in the atomic level, and thus rewriting characteristics become unstable and the resistance may be varied every time of rewrite. In addition, when rewrite of the memory is repeated, the concentration of Ag, Cu, or the like in the solid electrolyte becomes too high due to the diffusion from the electrodes, and there is a possibility that the resistance is not changed from a middle intermediate resistance between ON and OFF. These problems deteriorate the performance of the semiconductor device which can store information. In view of the foregoing, a memory element using a solid electrolyte having more stable data rewriting characteristics is desired.

An object of the present invention is to provide a technique capable of improving the performance of a semiconductor device capable of storing information.

The above and other objects and novel characteristics of the present invention will be apparent from the description of this specification and the accompanying drawings.

The typical ones of the inventions disclosed in this application will be briefly described as follows.

A semiconductor device of the present invention is a semiconductor device having a memory element formed on a semiconductor substrate and including a memory layer and a first electrode and a second electrode respectively formed on both surfaces of the memory layer, where the memory layer has a first layer at the first electrode side and a second layer at the second electrode side adjacent to each other; the first layer comprises a material containing at least one element selected from a first element group of Cu, Ag, Au, Al, Zn, and Cd, at least one element selected from a second element group of V, Nb, Ta, Cr, Mo, W, Ti, Zr, Hf, Fe, Co, Ni, Pt, Pd, Rh, Ir, Ru, Os, and lanthanoid elements, and at least one element selected from a third element group of S, Se, and Te; and the second layer comprises a material containing at least one element selected from the first element group, at least one element selected from the second element group, and oxygen.

The effects obtained by typical aspects of the present invention will be briefly described below.

Performance of a semiconductor device capable of storing information can be improved.

Moreover, a semiconductor device which consumes low power and has stable data rewriting characteristics can be realized.

### BRIEF DESCRIPTIONS OF THE DRAWINGS

FIG. 1 is an explanatory diagram showing a memory element in a semiconductor device according to an embodiment of the present invention;

FIG. 2 is an explanatory diagram showing a set state of the memory element of FIG. 1;

FIG. 3 is an explanatory diagram showing a reset state of the memory element of FIG. 1;

FIG. 4 is an explanatory diagram showing voltage/current characteristics of the memory element;

FIG. 5 is an explanatory diagram showing a preferred composition range of a material forming a first layer of a memory layer of the memory element;

FIG. 6 is an explanatory diagram showing a preferred composition range of a material forming a second layer of the memory layer of the memory element;

FIG. 7 is a graph showing a composition dependence of a film resistance of the memory element;

FIG. 8 is a graph showing a composition dependence of a set resistance of the memory element;

FIG. 9 is a graph showing a composition dependence of the set resistance of the memory element;

FIG. 10 is a graph showing a composition dependence of an allowable temperature limit of the memory element;

FIG. 11 is a graph showing a composition dependence of a set resistance of the memory element;

FIG. 12 is a graph showing a composition dependence of the film resistance of the memory element;

FIG. 13 is a graph showing a composition dependence of a film resistance of the memory element;

FIG. 14 is a graph showing a composition dependence of the set resistance of the memory element;

FIG. 15 is a graph showing a composition dependence of the set resistance of the memory element;

FIG. 16 is a graph showing a composition dependence of an allowable temperature limit of the memory element;

FIG. 17 is a graph showing a composition dependence of the set resistance of the memory element;

FIG. 18 is a graph showing a composition dependence of the film resistance of the memory element;

FIG. 19 is a circuit diagram showing an example of a structure of a memory array of the semiconductor device according to the embodiment of the present invention;

FIG. 20 is a plan view showing a plane layout corresponding to the array configuration of FIG. 19;

FIG. 21 is a cross sectional view of main parts of the semiconductor device according to the embodiment of the present invention;

FIG. 22 is a cross sectional view of main parts of the semiconductor device of the embodiment of the present invention in a fabrication step;

FIG. 23 is a cross sectional view of main parts of the semiconductor device in a fabrication step subsequent to that of FIG. 22;

FIG. 24 is a cross sectional view of main parts of the semiconductor device in a fabrication step subsequent to that of FIG. 23;

FIG. 25 is a cross sectional view of main parts of the semiconductor device in a fabrication step subsequent to that of FIG. 24;

FIG. 26 is a cross sectional view of main parts of the semiconductor device in a fabrication step subsequent to that of FIG. 25;

FIG. 27 is a cross sectional view of main parts of the semiconductor device in a fabrication step subsequent to that of FIG. 26;

FIG. 28 is a cross sectional view of main parts of the semiconductor device in a fabrication step subsequent to that of FIG. 27;

FIG. 29 is a cross sectional view of main parts of the semiconductor device in a fabrication step subsequent to that of FIG. 28;

FIG. 30 is a cross sectional view of main parts of the semiconductor device in a fabrication step subsequent to that of FIG. 29;

FIG. 31 is a cross sectional view of main parts of the semiconductor device in a fabrication step subsequent to that of FIG. 30;

FIG. 32 is an explanatory diagram showing a memory element in a semiconductor device of another embodiment of the present invention;

FIG. 33 is an explanatory diagram showing a desired composition range of the material constituting a top electrode of the memory element of FIG. 32;

FIG. 34 is a graph showing a composition dependence of a set resistance of the memory element;

FIG. 35 is a graph showing a composition dependence of the set resistance of the memory element;

FIG. 36 is a graph showing a composition dependence of the set resistance of the memory element;

FIG. 37 is a graph showing a composition dependence of the number of rewritable times of the memory element;

FIG. 38 is an explanatory diagram showing a memory element in a semiconductor device of still another embodiment of the present invention;

FIG. 39 is an explanatory diagram showing a set state of the memory element of FIG. 38;

FIG. 40 is an explanatory diagram showing a reset state of the memory element of FIG. 38;

FIG. 41 is an explanatory diagram showing a reset state of the memory element of FIG. 38;

FIG. 42 is an explanatory diagram showing a reset state of the memory element of FIG. 38;

FIG. 43 is an explanatory diagram showing a memory element in the semiconductor device of still another embodiment of the present invention;

FIG. 44 is an explanatory diagram showing a set state of the memory element of FIG. 43;

FIG. 45 is an explanatory diagram of a reset state of the memory element of FIG. 43;

FIG. 46 is a circuit diagram showing an example of the structure of a memory array of a semiconductor device of still another embodiment of the present invention;

FIG. 47 is a waveform diagram showing an example of a read operation of the memory array of FIG. 46;

FIG. 48 is a waveform diagram showing an example of a write operation of the memory array of FIG. 46;

FIG. 49 is a circuit diagram showing an example of a structure of a memory array of the semiconductor device of still another embodiment of the present invention;

FIG. 50 is a circuit diagram showing a detailed configuration example of a common discharge circuit, a reading circuit, and a rewriting circuit of FIG. 49;

FIG. 51 is a waveform diagram showing an example of a rewrite operation using the rewriting circuit of FIG. 50;

FIG. 52 is a circuit diagram showing an example of a structure of a memory array of a semiconductor device of yet another embodiment of the present invention; and

FIG. 53 is a waveform diagram showing an example of a read operation of the memory array of FIG. 52.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Hereinafter, embodiments of the present invention will be described in detail with reference to the accompanying drawings. Note that, components having the same function are denoted by the same reference symbols throughout the drawings for describing the embodiment, and the repetitive description thereof will be omitted. In addition, the description of the same or similar portions is not repeated in principle unless particularly required in the following embodiments.

Also, in some drawings used in the embodiments, hatching is used even in a plan view so as to make the drawings easy to see.

### First Embodiment

A semiconductor device of an embodiment of the present invention and a fabrication method thereof will be described with reference to the accompanied drawings.

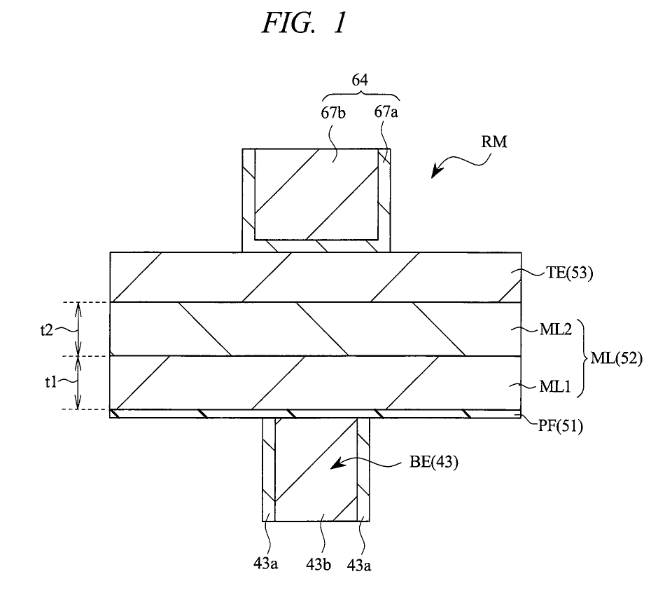

FIG. 1 is an explanatory diagram (cross sectional view) schematically showing a memory element in the semiconductor device of the present embodiment. In FIG. 1, to facilitate understanding, illustration of insulating films (corresponding to insulating films 41, 61, and 62, which will be described later) surrounding the periphery of the memory element RM is omitted.

As shown in FIG. 1, the memory element (storage element) RM of the present embodiment has a memory layer (recording layer, memory material layer) ML, a bottom electrode (plug-type electrode, conductive portion, first electrode) BE, and a top electrode (top electrode film, conductive portion, second electrode) TE, and the bottom and top electrodes are respectively formed on both surfaces (mutually opposite surfaces, which are the lower surface and the upper surface herein) of the memory layer ML. Such a memory element RM is formed on a semiconductor substrate (corresponding to a semiconductor substrate 11, which will be described later), thereby forming the semiconductor device. Thus, the semiconductor device of the present embodiment is a semiconductor device comprising the memory element RM having the bottom electrode BE, the memory layer ML formed on the bottom electrode BE, and the top electrode TE formed on the memory layer ML.

A peeling prevention film (interface layer, and corresponding to a peeling prevention film 51, which will be described later) PF is preferably interposed between the bottom electrode BE and the memory layer ML of the memory element as shown in FIG. 1, and the reason therefor will be described later; however, the bottom electrode BE and the memory layer ML may be brought into direct contact (connection) with each other without interposing the peeling prevention film PF therebetween. In other words, the bottom electrode BE neighbors a first layer ML1 of the memory layer ML with the interposition of the peeling prevention film PF; however, in the case where the peeling prevention film PF is not formed, the bottom electrode BE directly neighbors the first layer ML1 of the memory layer ML. The peeling prevention film PF is formed of, for example, a chromium oxide (for example, Cr₂O₃) or a tantalum oxide (for example, Ta₂O₅), and, in this case, a layer formed of the chromium oxide or tantalum oxide (that is, the removal prevention film) is formed between the bottom electrode BE and the first layer ML1 of the memory layer ML.

The bottom electrode BE is buried in an opening portion (corresponding to a through hole 42, which will be described later) of the insulating film (corresponding to the later-described insulating film 41, but illustration thereof is omitted in FIG. 1) formed on the semiconductor substrate, the peeling prevention film PF is formed on the insulating film in which the bottom electrode BE is buried, and the memory layer ML and the top electrode TE are sequentially formed from the lower side on the peeling prevention film PF. And, at least a part of the memory layer ML is planarly (viewed in the plane parallel to the main surface of the semiconductor substrate) overlapped with the bottom electrode BE. In other words, the upper surface of the bottom electrode BE is formed to be included in the planar pattern of the memory layer ML.

The memory layer ML disposed between the top electrode TE and the bottom electrode BE has a stacked structure of the first layer ML1 (metal chalcogenide layer) at the bottom electrode BE-side and a second layer ML2 (metal oxide layer) at the top electrode TE-side. The first layer ML1 and the second layer ML2 neighbor each other. The first layer ML1 is the layer which serves as a solid electrolyte (although the layer is abbreviated as a solid electrolyte layer, a material forming the layer is not necessary to be a material that is known as a solid electrolyte), and the second layer ML2 is the layer which serves as an ion feeding layer.

On the top electrode TE, a conductive plug (conductive portion) 64 is formed, and the top electrode TE and the plug 64 are electrically connected to each other.

The top electrode TE neighbors the second layer ML2 of the memory layer ML. The top electrode TE is preferably formed by an element(s) which does not readily diffuse into the second layer ML2 of the memory layer ML. The top electrode TE is formed of a conductive material and, in order to prevent diffusion into the second layer ML2, preferably contains, as a main component, at least one element selected from the group of tungsten (W), molybdenum (Mo), tantalum (Ta), platinum (Pt), palladium (Pd), rhodium (Rh), iridium (Ir), ruthenium (Ru), osmium (Os), and titanium (Ti); however, the top electrode may contain a small amount of impurity. For example, the top electrode TE can be formed by a single-substance metal, an alloy (mixture of metals), or a metal compound of the element(s) (preferably, W, Mo, Ta, Pt, Pd, Rh, Ir, Ru, Os, Ti) which does not readily diffuse into the second layer ML2, where a metal nitride having a low resistance, for example, a titanium nitride (Ti nitride) is preferred as the metal compound. When the top electrode TE has such a constitution, excessive feeding of metal elements or metal ions from the top electrode TE into the memory layer ML (second layer ML2) can be prevented. Therefore, in a reset operation, which will be described later, the phenomenon that disconnection of a conductive path (corresponding to a conductive path CDP, which will be described later) between the top electrode TE and the bottom electrode BE becomes insufficient so that the resistance thereof becomes low can be prevented, stability of the reset state can be enhanced, and the rewrite of the memory element RM can be improved.

The bottom electrode BE is preferably formed of an element(s) which does not readily diffuse into the first layer ML1 of the memory layer ML. The bottom electrode BE is formed of a conductive material and, to prevent diffusion into the first layer ML1, preferably contains, as a main component, at least one element selected from the group of tungsten (W), molybdenum (Mo), tantalum (Ta), platinum (Pt), palladium (Pd), rhodium (Rh), iridium (Ir), ruthenium (Ru), osmium (Os), and titanium (Ti); however, the bottom electrode may contain a small amount of impurity. For example, the bottom electrode BE can be formed by a single-substance metal, an alloy (mixture of metals), or a metal compound of an element(s) (preferably W, Mo, Ta, Pt, Pd, Rh, Ir, Ru, Os, Ti) which does not readily diffuse into the first layer ML1, wherein a metal nitride or the like is preferred as the metal compound. For example, the bottom electrode BE can be formed of a conductive barrier film 43a comprising, for example, a titanium (Ti) film, a titanium nitride (Ti—N) film, or stacked films thereof and a main conductive film 43b comprising, for example, tungsten (W) or titanium nitride (Ti—N). When the bottom electrode BE has such a constitution, excessive feeding of metal elements or metal ions from the bottom electrode BE into the memory layer ML (first layer ML1) when the top electrode TE side is caused to have a negative electric potential with respect to the bottom electrode BE can be prevented. Therefore, the memory element RM can be appropriately operated, and the rewrite ability of the memory element RM can be improved.

The first layer ML1 of the memory layer ML comprises a material which contains, as main components: at least one element selected from the group of Cu (copper), Ag (silver), Au (gold), Al (aluminum), Zn (zinc), and Cd (cadmium) (this group will be referred to as a first element group); at least one element selected from the group of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements (this group will be referred to as a second element group); and at least one element selected from the group of S (sulfur), Se (selenium), and Te (tellurium) (this group will be referred to as a third element group). The first layer ML1 of the memory layer ML contains the chalcogen element(s) (S, Se, Te); therefore, the first layer can be considered to be formed of a chalcogenide material (chalcogenide, chalcogenide semiconductor), in other words, the first layer can be considered to be a chalcogenide layer (metal chalcogenide layer). Preferred compositions of the first layer ML of the memory layer ML will be described later in detail.

The second layer ML2 of the memory layer ML comprises a material which contains, as main components: at least one element selected from the group (first element group) of Cu (copper), Ag (silver), Au (gold), Al (aluminum), Zn (zinc), and Cd (cadmium); at least one element selected from the group (second element group) of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements; and oxygen (O). The second layer ML2 of the memory layer ML contains oxygen element (O); therefore, the second layer can be considered to be formed by an oxide (metal oxide), in other words, the second layer can be considered to be an oxide layer (metal oxide layer). Preferred compositions of the second layer ML2 of the memory layer ML will be described later in detail.

Hereinafter, for simplification, the above-described group of Cu (copper), Ag (silver), Au (gold), Al (aluminum), Zn (zinc), and Cd (cadmium) will be referred to as the first element group. Also, the above-described group of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements will be referred to as the second element group. Also, the above-described group of S (sulfur), Se (selenium), and Te (tellurium) will be referred to as the third element group. Also, the element(s) which belongs to the first element group and is contained in the memory layer ML will be referred to as an element(s) α. Also, the element(s) which belongs to the second element group and is contained in the memory layer ML will be referred to as an element(s) β. Also, the element(s) which belongs to the third element group and is contained in the memory layer ML will be referred to as an element(s) γ.

As described above, the first layer ML1 of the memory layer ML comprises the material containing the element(s) α, the element(s) β, and the element(s) γ; and the second layer ML2 of the memory layer ML comprises the material containing the element(s) α, the element(s) β, and oxygen (O).

In the first layer ML1 of the memory layer ML, the element(s) β and the element(s) γ are bonded to each other and are stable even when an electric field (voltage) is applied thereto so that they are not readily changed and do not readily diffuse into the memory layer ML; however, the element(s) α rather readily diffuses into the memory layer ML when an electric field (voltage) is applied compared with the element(s) β and the element(s) γ. This is for the reason that the bonding force between the element(s) β and the element(s) γ is larger than the bonding force between the element(s) α and the element(s) γ. Moreover, in the second layer ML2 of the memory layer ML, the element(s) β and oxygen (O) are bonded to each other and are stable even when an electric field (voltage) is applied thereto so that they are not readily changed and do not readily diffuse into the memory layer ML; however, compared with the element(s) β and oxygen (O), the element(s) α readily diffuse into the memory layer ML when an electric field (voltage) is applied thereto. This is for the reason that the bonding force between the element(s) β and oxygen (O) is larger than the bonding force between the element(s) α and oxygen (O).

The element(s) α (element(s) of the first element group) contained in the memory layer ML is an element(s) having a function of diffusing or moving into the memory layer ML (mainly, the first layer ML1) so as to form a conductive path (conductive path CDP, which will be described later) in the memory layer ML. Among the elements of the first element group, Cu (copper) and Ag (silver) are preferred in the point that this conductive path can be readily formed. Therefore, when the first layer ML1 and the second layer ML2 of the memory layer ML contain Cu (copper) or Ag (silver) as the element α, the conductive path (conductive path CDP, which will be described later) can be readily formed, which is more preferable. Moreover, if the element α contained in the memory layer ML (the first layer ML1 and the second layer ML2) is Cu (copper), the possibility of metal contamination or the like is low since Cu (copper) is used in a fabrication step (for example, a formation step of buried copper wiring) of the semiconductor device. Moreover, if the element α contained in the memory layer ML (the first layer ML1 and the second layer ML2) is Ag (silver), Ag (silver) has a smaller ion radius than Cu (copper) and has a high diffusion speed; therefore, the diffusion speed of the element α in the memory layer ML upon writing can be increased, thereby further improving the writing speed.

More preferably, the element(s) which is contained in the first layer ML1 of the memory layer ML and belongs to the first element group and the element(s) which is contained in the second layer ML2 of the memory layer ML and belongs to the first element group are the same (in other words, the element(s) α contained in the first layer ML1 and the element (s) α contained in the second layer ML2 are the same). For example, in the case where the element which is contained in the first layer ML1 and belongs to the first element group is Cu, the element which is contained in the second layer ML2 and belongs to the first element group is also preferred to be Cu. As a result, the conductive path can be more appropriately formed in the memory layer ML.

More preferably, the element(s) which is contained in the first layer ML1 of the memory layer ML and belongs to the second element group and the element(s) which is contained in the second layer ML2 of the memory layer ML and belongs to the second element group are the same (in other words, the element(s) β contained in the first layer ML1 and the element(s) β contained in the second layer ML2 are the same). For example, in the case where the element which is contained in the first layer ML1 and belongs to the second element group is Ta, the element which is contained in the second layer ML2 and belongs to the second element group is also preferred to be Ta. As a result, there are advantages that change in the composition due to rewriting is not caused, and contribution to formation of the inter-electrode conductive path (conductive path CDP, which will be described later) of the element which belongs to the second element group is facilitated.

The element(s) β (element(s) of the second element group) in the memory layer ML is partly contained in the conductive path CDP, which will be described later, and has a function of facilitating formation of the conductive path CDP and increasing the stability of the conductive path CDP when the temperature is increased. Furthermore, in the case where, different from the present embodiment, no element β (elements of the second element group) is in the memory layer ML, the structure of the whole film (layer) of the memory layer ML becomes unstable since the metal element(s) (element(s) α) occupying a considerable rate of the atoms in the memory layer ML moves; however, in the present embodiment, since the element(s) β (element(s) of the second element group) which is strongly bonded to the element(s) γ or oxygen is present in the memory layer ML, the film (layer) structure of the memory layer ML is stable even when the element(s) α moves. Therefore, even when rewriting of the memory element RM is repeated, the film structure of the memory layer ML is stable, and the rewrite ability of the memory element can be improved. In order to enhance such effects, the element(s) β contained in the memory layer ML is particularly preferred to be Ta (tantalum), V (vanadium), Nb (niobium), and Cr (chromium) among the elements of the second element group. Therefore, more preferably, the first layer ML1 and the second layer ML2 of the memory layer ML contain, as the element β, at least one element selected from the group of Ta (tantalum), V (vanadium), Nb (niobium), and Cr (chromium).

The second layer ML2 of the memory layer ML is a feeding layer of metal ions or metal elements (herein, corresponding to the elements α) which move (diffuse) in the memory layer ML (mainly, the first layer ML1), in other words, an ion feeding layer or a metal element feeding layer. The first layer ML1 of the memory layer ML is a solid electrolyte layer in which the metal ions or metal elements (herein, corresponding to the elements α) move (diffuse). In the present application, the solid electrolyte is a solid electrolyte in a broad sense which enables some sort of charge migration where resistance change is detected.

The elements which readily move when an electric field is applied compared with the elements β, the elements γ, and oxygen (O) are used as the elements α; therefore, when an electric field is applied, the element(s) α can diffuse from the second layer ML2 to the first layer ML1 or return from the first layer ML1 to the second layer ML2. On the other hand, the element(s) β and oxygen (O) in the second layer ML2 are bonded to each other; and, even when an electric field is applied, they are stable, are not readily changed, and do not readily diffuse into the first layer ML1. Moreover, the element(s) β and the element(s) γ in the first layer ML1 bond to each other; and, even when an electric field is applied, they are stable so that they are not readily changed and do not readily diffuse into the second layer ML2. Therefore, even when an electric field is applied, the element(s) β and oxygen (O) in the second layer ML2 do not diffuse into the first layer ML1, and the element(s) β and the element(s) γ in the first layer ML1 do not diffuse into the second layer ML2; therefore, even when the movement of the element(s) α is repeated by repeating rewrites of the information of the memory layer ML, the shape of the second layer ML2 can be maintained by the element(s) β and oxygen (O), and the shape of the first layer ML1 can be maintained by the element(s) β and the element(s) γ. Thus, even when rewrite of the memory element RM is repeated, deformation or degeneration of the memory layer ML can be prevented, and the film structure of the memory layer ML can be stabilized. Therefore, many times of rewrites of the memory element RM can be stably performed.

The layers (the first layer ML1 and the second layer ML2) of the memory layer ML contain the elements that belong to the group 16 (VIB) of the periodic table. The second layer ML2 contains oxygen (O), on the other hand, the first layer ML1 contains at least one element selected from the group (third element group) of S (sulfur), Se (selenium), and Te (tellurium). Therefore, in the memory layer ML, the first layer ML1 has a higher mobility (having a definition similar to that of the mobility of carriers such as electrons in a semiconductor) of the element(s) (herein, element(s) α) that contributes to formation of the conductive path (corresponding to the conductive path CDP, which will be described later) than that of the second layer ML2. The reason thereof will be described below.

Oxygen (O), sulfur (S), selenium (Se), and tellurium (Te), which are the elements belonging to the group 16 (VIB) of the periodic table have larger sizes (ion radiuses) than the positive ions of metals when they become divalent negative ions; and, in the ascending order of the atomic numbers thereof, oxygen (O), sulfur (S), selenium (Se), and tellurium (Te), the sizes of ions (ion radiuses) become larger. In each of the layers (the first layer ML1 and the second layer ML2) of the memory layer ML, it is conceived that, the larger the contained amount of the elements having large ion sizes (ion radiuses), the larger the gap between atoms or ions and more readily metal ions (element α) pass therethrough; in other words, mobility is increased. Also, the larger the ion radiuses of the elements which are contained in each of the layers (the first layer ML1 and the second layer ML2) of the memory layer ML and belong to the 16 (VIB) group of the periodic table, the smaller the attraction force or bonding force between the element(s) (element(s) α), which contributes to formation of the conductive path, and the other elements (the element(s) β and the elements of the group 16 (VIB)) constituting the memory layer ML, and this is also conceived to contribute to increase mobility.

Therefore, while the second layer ML2 contains oxygen (O), the first layer ML1 contains at least one element selected from the group (third element group) of S (sulfur), Se (selenium), and Te (tellurium) having larger ion radiuses than oxygen (O); thus, the first layer ML1 has larger gaps between the atoms or ions and smaller attraction force or bonding force that acts on the element(s) (herein, the element(s) α), which contributes to conduction path formation, than the second layer ML2. Therefore, it is conceived that the mobility of the element(s) (herein, the element (s) α), which contributes to conductive formation, is increased since the metal ions (herein, the ions of the element(s) α) more readily pass through (move) in the first layer ML1 than in the second layer ML2.

Further, while the second layer ML2 contains oxygen (O), the second layer ML2 is preferred not to contain S (sulfur), Se (selenium), and Te (tellurium). Also, while the first layer ML1 contains at least one element selected from the group (third element group) of S (sulfur), Se (selenium), and Te (tellurium), the first layer ML1 is preferred not to contain oxygen (O). As a result, the mobility of the element(s) (element(s) α) that contributes to formation of the conductive path (corresponding to the conductive path CDP, which will be described later) can be caused to be appropriately higher in the first layer ML1 than in the second layer ML2.

In this manner, the memory layer ML comprises the first layer ML1 and the second layer ML2 having different mobility of the element(s) (element(s) α) that contributes to formation of the conductive path. Therefore, since the element(s) (element(s) α) that contributes to formation of the conductive path readily moves in the first layer ML1 in which the mobility is high, after once a conductive path is formed in the first layer ML1, the connection between the conductive path and the bottom electrode BE can be disconnected or connected depending on the direction of an applied voltage (reset voltage and set voltage) or the difference in the manner of voltage application (for example, pulse widths and the magnitude of pulse voltages). On the other hand, in the second layer ML2 in which the mobility is low, since the element(s) that contributes to formation of the conductive path (herein, the element(s) α) does not readily move, after a conductive path is once formed in the second layer ML2, the element(s) (herein, the element(s) α) constituting the conductive path in the second layer ML2 is almost not moved even when voltages (reset voltage, set voltage, and read voltage) are applied, so that the electrical connection between the conductive path and the top electrode TE can be maintained.

Among the elements of the third element group, S (sulfur) is particularly preferred since the resistance of a high-resistance state (reset state) of the memory element RM can be increased since the bandgap thereof is wide. Therefore, more preferably, the first layer ML1 of the memory layer ML contains S (sulfur) as the element γ since the resistance of the high-resistance state (reset state) of the memory element RM can be increased.

Further, the mobility of the ions (herein, the ions of the element(s) α) of both the first layer ML1 and the second layer ML2 is preferably lower than that of a Cu₂S layer; and the reason thereof is that the connection of the conductive path (conductive path CDP, which will be described later) penetrating through these layers with the electrodes is not readily disconnected.

When the first layer ML1 or the second layer ML2 has low resistivity, the first layer ML1 or the second layer ML2 can also serve as an electrode. In this case, the first layer ML1 or the second layer ML2 which functions as the electrode preferably serves in place of a part of the bottom electrode BE or the top electrode TE; however, when it can have the same shape as the bottom electrode BE or the top electrode TE, the bottom electrode BE or the top electrode TE can be omitted. Even in the case where the second layer ML2 functions as an electrode so as to omit the top electrode TE, some sort of a conductive portion (for example, the plug 64) is connected to the second layer ML2 for voltage application; therefore, the conductive portion connected to the second layer ML2 can be considered to be an electrode (second electrode) of the memory element RM. Similarly, even in the case where the first layer ML1 functions as an electrode so as to omit the bottom electrode BE, some sort of a conductive portion (for example, wiring 37a) is connected to the first layer ML1 for voltage application (wherein, in some cases, the peeling prevention film PF or the like is interposed between the connected conductive portion and the first layer ML1); therefore, the conductive portion connected to the first layer ML1 can be considered to be an electrode (first electrode) of the memory element RM.

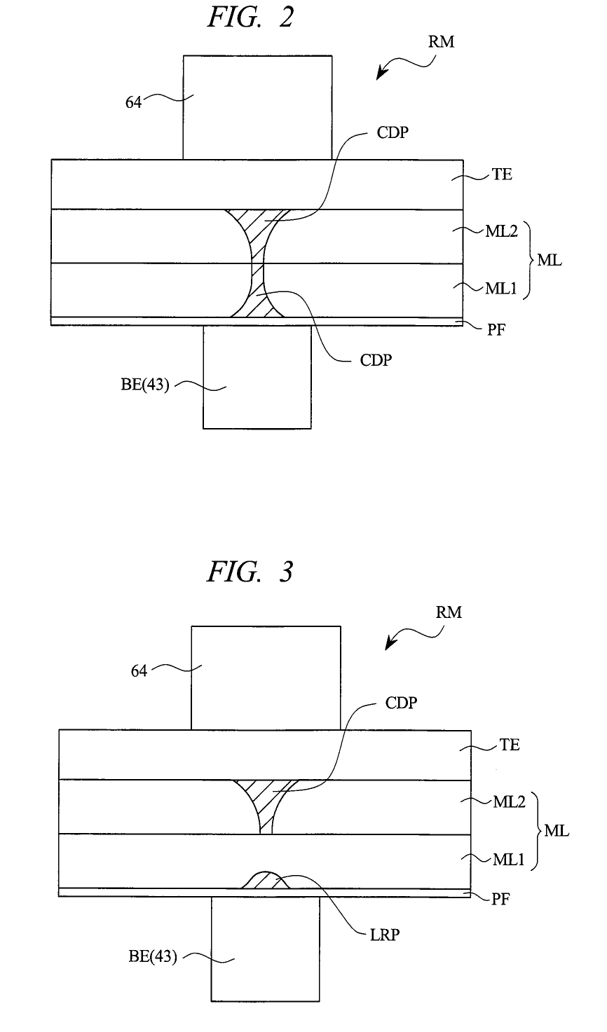

Formation of the conductive path CDP in the memory layer ML will be described in more detail. FIG. 2 is an explanatory diagram (cross sectional view) schematically showing the memory element RM in the state (set state, ON state) in which the conductive path CDP is formed so as to connect the bottom electrode BE and the top electrode TE in the memory layer ML. FIG. 3 is an explanatory diagram (cross sectional view) schematically showing the memory element RM in the state (reset state, OFF state) in which the conductive path CDP is disconnected between the bottom electrode BE and the top electrode TE in the memory layer ML. FIG. 2 and FIG. 3 are cross sectional views as with above-described FIG. 1; however, in order to facilitate viewability of the drawings, merely the regions having low resistivity in the memory layer ML, that is, the regions which are the conductive path CDP and a low-resistance part LRP in the memory layer ML are hatched, and hatching of the other part is omitted.

In the state immediately after the semiconductor device is fabricated, no voltage has been applied to the memory layer ML; therefore, the conductive path has not been formed. Therefore, voltages are applied after fabrication of the semiconductor device in order to once form the conductive path CDP which connects the top electrode TE and the bottom electrode BE in the memory layer ML. This voltage application can be performed by repeatedly applying comparatively-large initialization voltages (the voltages higher than the reset voltage, set voltage, and read voltage, which will be applied later) in mutually opposite directions. Specifically, applying a first initialization voltage which causes the electric potential of the bottom electrode BE to be lower than the electric potential of the top electrode TE, for example, by causing the bottom electrode BE to have a negative electric potential and causing the top electrode TE to have a positive electric potential so as to cause a comparatively large current to flow through the memory layer ML between the bottom electrode BE and the top electrode TE, and applying a second initialization voltage which causes the electric potential of the bottom electrode BE to be higher than the electric potential of the top electrode TE by, for example, causing the bottom electrode BE to have a positive electric potential and causing the top electrode TE to have a negative electric potential so as to cause a comparatively large current to flow through the memory layer ML between the bottom electrode BE and the top electrode TE are repeated.

Such initialization voltage application (repetition of first initialization voltage application and second initialization voltage application) causes metal ions to gather (move) along the current path, thereby forming the conductive path (conductive channel, low-resistance part) CDP, in which the metal ions are present at a high concentration, in the memory layer ML so as to connect the bottom electrode BE and the top electrode TE each other, as shown in FIG. 2. The conductive path CDP is the part in which metal ions (mainly, the element(s) α, however, the element(s) β can be also contained) are present at a high concentration in the memory layer ML. In the conductive path CDP, since electrons can be readily moved from the metal ions (metal atoms) to other metal ions (metal atoms) adjacent thereto, a low resistance value (resistivity) can be realized. Therefore, in the memory layer ML, the conductive path CDP has lower resistivity than the other region. When the conductive path CDP is formed in the memory layer ML so as to connect (couple) the bottom electrode BE and the top electrode TE to each other, the resistance of the memory layer ML becomes low, and the resistance of the memory element RM becomes low.

In this manner, when the reset voltage is applied in the state (set state, ON state) in which the conductive path CDP is formed in the memory layer ML in the manner as shown in FIG. 2 so as to connect the bottom electrode BE and the top electrode TE to each other, the conductive path CDP connecting the bottom electrode BE and the top electrode TE to each other can be disconnected in the memory layer ML as shown in FIG. 3.

For example, the bottom electrode BE is caused to have a positive electric potential, and the top electrode TE is caused to have a negative electric potential, thereby applying the reset voltage that causes the electric potential of the bottom electrode BE to be higher than that of the top electrode TE between the top electrode TE and the bottom electrode BE (that is, between the plug 64 and the bottom electrode BE). The reset voltage is arranged so that the absolute value of the voltage (the absolute value of the electric potential difference between the top electrode TE and the bottom electrode BE) is smaller than the absolute value of the first initialization voltage and the second initialization voltage (the absolute value of the electric potential difference between the top electrode TE and the bottom electrode BE), or the voltage application time is shorter than the voltage application time of the first initialization voltage and that of the second initialization voltage. The reset voltage is set to be such a value to suppress movement of the element(s) α in the second layer ML2 upon resetting so that the conductive path CDP in the second layer ML2 is maintained. In other words, the reset voltage is set so that the element(s) α moves in the first layer ML1, while the element(s) α hardly moves in the second layer ML reflecting the difference of the mobility of the element(s) α between the first layer ML1 and the second layer ML2.

By the reset voltage, the element(s) α (ions of the element(s) α) forming the conductive path CDP in the first layer ML1 of the memory layer ML moves to the top electrode TE side which is the negative electric potential side and is kept in the second layer ML2. On the other hand, since the mobility of the element(s) α is smaller in the second layer ML2 than in the first layer ML1 as described above, even when the reset voltage is applied, the element(s) α hardly moves in the second layer ML2. Therefore, when the reset voltage is applied, as shown in FIG. 3, the conductive path CDP in the second layer ML2 is hardly changed, on the other hand, the region in the first layer ML1 adjacent to the second layer ML2 attains the state in which the conductive path CDP is disconnected (the state in which the conductive path CDP is not formed), and the part between the bottom electrode BE and the top electrode TE in the memory layer ML attains the state in which they are not connected by the conductive path CDP; therefore, the resistance of the memory layer ML becomes high, and the resistance of the memory element RM becomes high.

The element(s) β have stronger bonding force with the element(s) γ or oxygen (O) compared with the element(s) α; therefore, even when the reset voltage is applied, the element(s) β hardly moves. Therefore, even when the reset voltage is applied, as shown in FIG. 3, sometimes the low-resistance part LRP, in which the element(s) β is present at a comparatively high concentration, remains in a region of the first layer ML1 adjacent to the bottom electrode BE; however, since the element(s) α has been moved by the reset voltage, the low-resistance part LRP is not connected with the conductive path CDP in the second layer ML2. Therefore, even when the low-resistance part LRP remains in the region of the first layer ML1 adjacent to the bottom electrode BE when the reset voltage is applied, the memory layer ML does not attain the state in which the part between the bottom electrode BE and the top electrode TE is connected by the low-resistance regions (the low-resistance part LRP and the conductive path CDP) in the memory layer ML, the resistance of the memory layer ML becomes high, and the resistance of the memory element RM becomes high. Note that, even when the low-resistance part LRP is not formed in the region of the first layer ML1 adjacent to the bottom electrode BE, there is no problem in the operation of the memory element RM.

Meanwhile, when the set voltage is applied in the state (reset state, OFF state) where the conductive path CDP between the bottom electrode BE and the top electrode TE is disconnected in the memory layer ML as shown in FIG. 3, the part between the bottom electrode BE and the top electrode TE can be connected again by the conductive path CDP in the memory layer ML as shown in FIG. 2.

For example, the bottom electrode BE is caused to have a negative electric potential, and the top electrode TE is caused to have a positive electric potential, thereby applying the set voltage, which causes the electric potential of the bottom electrode BE to be lower than the electric potential of the top electrode TE, between the top electrode TE and the bottom electrode BE (that is, between the plug 64 and the bottom electrode BE). The set voltage is arranged so that the absolute value of the voltage is smaller than that of the first initialization voltage and that of the second initialization voltage, or the voltage application time is shorter than the voltage application time of the first initialization voltage and the second initialization voltage.

By the set voltage, the element(s) α (ions of the element(s) α) of the second layer ML2 in the vicinity of the first layer ML1 diffuses into the first layer ML1, moves to the bottom electrode BE side which is the negative electric potential side, and forms the conductive path CDP again, thereby attaining the state where the conductive path CDP is formed in the first layer ML1 so as to connect the second layer ML2 to the bottom electrode BE. On the other hand, as described above, since the mobility of the element(s) α is smaller in the second layer ML2 compared with that in the first layer ML1, most of the conductive path CDP in the second layer ML2 is maintained even when the set voltage is applied. Therefore, when the set voltage is applied, as shown in FIG. 2, in the memory layer ML, the state in which the conductive path CDP is formed to connect (couple) the bottom electrode BE and the top electrode TE to each other is attained, the resistance of the memory layer ML becomes low, and the resistance of the memory element RM becomes low. In the set state, the thin (filament-like) conductive path CDP having high conductivity is formed so as to electrically connect the top electrode TE and the bottom electrode BE to each other; therefore, the resistance of the part between the top electrode TE and the bottom electrode BE is reduced.

Since oxygen (O) has an ion radius smaller than that of S (sulfur), Se (selenium), and Te (tellurium) as described above, oxygen has the effect of restricting the movement of ions; therefore, the second layer ML2 containing oxygen (O) functions to prevent the situation that most ions move in one direction or in the opposite direction thereof due to the potential gradient so that connection with either one of the electrodes is disconnected, and the conductive path CDP which connects the both the electrodes (the top electrode TE and the bottom electrode BE) to each other cannot be formed. Thus, the electrical connection between the second layer ML2 and the layer (top electrode TE) which is adjacent thereto and has high conductivity can be always maintained even when the layer (top electrode TE) having high conductivity contains almost no metal element (element α) which forms the conductive path.

If the electric potential difference between the top electrode TE and the bottom electrode BE is zero or smaller than a predetermined threshold value, the element(s) α does not move in the memory layer ML (particularly, the first layer ML1), and the state of the conductive path in the memory layer ML is maintained.

The electric potential (voltage) of the bottom electrode BE can be controlled by the voltage applied to the bottom electrode BE via, for example, a memory transistor QM1 or QM2, which will be described later, and the electric potential (voltage) of the top electrode TE can be controlled by the voltage applied to the top electrode TE via wiring 72 (72a), which will be described later, and the plug 64. in the case where the reset voltage and the set voltage are caused to be the voltages of mutually opposite directions so as to control the memory element RM as described herein, the semiconductor device having the memory element RM has the circuit which can apply the voltages of mutually opposite directions to the top electrode and the bottom electrode upon resetting and setting.

In the present application, when the conductive path CDP is formed in the memory layer ML so as to connect (couple) the bottom electrode BE and the top electrode TE as shown in FIG. 2, the resistance of the memory layer ML becomes low, and the resistance of the memory element RM becomes low; and this state is referred to as the set state or the on (ON) state. The operation of applying the set voltage so as to cause the memory layer ML of the memory element RM to be the set state is referred to as a set operation (or, simply, setting). Therefore, the set voltage is the voltage for causing the memory layer ML of the memory element RM to be the set state. Moreover, in the present application, the state in which, as shown in FIG. 3, the part between the bottom electrode BE and the top electrode TE is not connected by the conductive path CDP in the memory layer ML, the conductive path CDP between the bottom electrode BE and the top electrode TE is in a disconnected state, the resistance of the memory layer ML becomes high, and the resistance of the memory element RM becomes high is referred to as the reset state or the off (OFF) state. The operation of applying the reset voltage so as to cause the memory layer ML of the memory element RM to be the reset state is referred to as a reset operation (or, simply, resetting). Therefore, the reset voltage is a voltage for causing the memory layer ML of the memory element RM to be the reset state.

In this manner, when the reset voltage or the set voltage is applied, the element(s) (mainly, the element(s) α) in the memory layer ML moves in the memory layer ML, thereby causing the memory layer ML of each memory cell to be changed (transition) between the low-resistance state (the set state, ON state) in which the conductive path CDP is formed so as to connect the bottom electrode BE and the top electrode TE to each other and the high-resistance state (reset state, OFF state) in which the conductive path CDP is not formed in the manner connecting the bottom electrode BE and the top electrode TE to each other. Therefore, the electric field between the bottom electrode BE and the top electrode TE can be controlled by controlling the voltage applied to the bottom electrode BE and the top electrode TE; thus, movement of the metal elements (mainly, the element(s) α) in the memory layer ML can be controlled so as to control the formation state of the conductive path CDP, and, in the memory layer ML of each memory cell, the state can be changed (transited) between the low-resistance set state and the high-resistance reset state or can be maintained in either one of the states. Consequently, the resistance value (resistivity) of the memory layer ML, in other words, the resistance value of the memory element RM can be changed, thereby forming a non-volatile storage element (memory). The memory element RM stores information by the high-resistance state (reset state) in which the electric resistance value of the memory layer ML between the bottom electrode BE and the top electrode TE is high and the low-resistance state (set state) in which electric resistance value is low. Specifically, memory information is indicated by whether the memory layer ML between the bottom electrode BE and the top electrode TE is in the low-resistance state (the state in which the conductive path CDP is formed so as to connect the bottom electrode BE and the top electrode TE to each other) or the memory layer ML is in the high-resistance state (the state in which the conductive path CDP is not formed in the manner connecting the bottom electrode BE and the top electrode TE to each other). The information can be stored (recorded) in the memory layer ML when the metal elements (mainly, the element(s) α) contained in the memory layer ML move in the memory layer ML (mainly, the first layer ML1).

The read voltage for reading the information stored in the memory element RM (memory layer ML) is set to a value which does not make the elements (particularly, the element(s) α) in the memory layer ML move both in the first layer ML1 and the second layer ML2 (in other words, the state of the conductive path CDP is not changed). For example, the absolute value of the read voltage is smaller than the absolute values of the reset voltage and the set voltage. When such a read voltage is applied between the bottom electrode BE and the top electrode TE, the resistance value of the memory element RM can be read, thereby reading whether the memory layer ML (memory element RM) is in the high-resistance state or the low-resistance state, that is, the memory information of the memory element RM. The resistance upon resetting (electrical resistance between the top electrode TE and the bottom electrode BE) is higher than the resistance upon setting (the electrical resistance between the top electrode TE and the bottom electrode BE), and the ratio thereof is, for example, about ten (ten fold).

In this manner, when the atoms or ions (herein, mainly, the element(s) α) move in the memory layer ML so as to change the physical property (for example, the electric resistance), information can be stored (recorded) in the memory layer ML; also, when the atoms or ions (herein, mainly, the element(s) α) move in the memory layer ML so as to change the physical property (for example, the electric resistance), the information stored in the memory layer ML can be rewritten. The memory information (high resistance or low resistance) of the memory layer ML in a selected memory cell can be read by a passing current or the like of the selected memory cell, which is an access object, upon accessing. The above-described change of the physical property is, for example, change of the electrical resistance between the top electrode TE and the bottom electrode BE or change of the capacitance; and as described herein, change of the electric resistance is more preferred.

When the electric potential difference between the bottom electrode BE and the top electrode TE is zero or smaller than a predetermined threshold value, the element(s) α does not move in the memory layer ML; therefore, the information stored in the memory layer ML is retained even when power is not supplied to the semiconductor device. Thus, the memory layer ML or the memory element RM can function as a non-volatile storage element. The memory element RM can be also considered to be a solid electrolyte memory.

And, different from the present embodiment, constituting the memory layer ML by merely either one of the first layer ML1 and the second layer ML2 (in other words, omitting formation of either one of the first layer ML1 and the second layer ML2) can be also conceived; however, in this case, the element(s) (herein, the element(s) α) that contributes to formation of the conductive path in the memory layer ML moves to and present unevenly at the top electrode TE side or the bottom electrode BE side depending on the direction of an applied voltage, and the conductive path CDP which reaches from the top electrode TE to the bottom electrode BE cannot be well formed.

In a solid electrolyte memory which comprises, different from the present embodiment, one chalcogenide solid electrolyte layer sandwiched by metal electrodes, the solid electrolyte layer is one layer, and the mobility of the element constituting the anode (the metal electrode of the positive electric potential side) in the solid electrolyte layer is high; therefore, even when metal ions diffuse from the anode (metal electrode) into the solid electrolyte, a conductive path having a high ion concentration maintains connection with the anode in the solid electrolyte layer and does not extend to the cathode (the metal electrode of the negative electric potential side). Then, the metal ions diffused and moved from the anode into the solid electrolyte are accumulated in the vicinity of the cathode, and a high-concentration region (conductive region) in which the metal ions are present at a high concentration is formed in the vicinity of the cathode in a mountain-like shape (a mountain-like or a triangular shape in which the anode side serves as a peak, and the region adjacent to the cathode serves as the bottom). The high-concentration region gradually grows toward the direction of the anode, and, when the peak of the high-concentration region reaches the anode, both the electrodes (the anode and the cathode) are electrically connected. In this case, when a voltage of the opposite direction is applied, the metal ions are removed from the top of the mountain-like high-concentration region, and the connection between both the electrodes (the anode and the cathode) is disconnected when the height of the mountain-like high-concentration region is reduced. The base part of the mountain-like high-concentration region (conductive region) may be spread wider than the lateral width of the electrode, which may be an obstacle of high integration.

On the other hand, in the present embodiment, the memory layer ML disposed between the top electrode TE and the bottom electrode BE has the stacked structure of the first layer ML1 of the bottom electrode BE side and the second layer ML2 of the top electrode TE side so that the mobility of the element(s) (herein, the element(s) α) which contributes to formation of the conductive path CDP is different in the first layer ML1 and the second layer ML2. Consequently, the conductive path CDP which is formed when the ions are forcibly compressed thereinto extends downward (in the direction toward the bottom electrode BE) from the top electrode TE and has an electric-wire-like shape or a filament-like shape in the vertical direction, and the connection with the bottom electrode BE is connected or disconnected depending on the direction of the applied voltage or the applying manner (for example, the pulse width or pulse voltage) of the voltage. Since the above-described thin electric-wire-like or filament-like conductive path CDP can be controlled and formed by the applied voltage, a memory element having excellent performance and functions can be realized.

Specifically, in the present embodiment, the mobility of the element(s) α is caused to be different in the first layer ML1 and in the second layer ML2 so that the element(s) α moves in the first layer ML1 although the element(s) α hardly moves in the second layer ML upon application of the reset voltage or the set voltage. Therefore, the conductive path CDP in the second layer ML2 is hardly changed by application of the reset voltage or the set voltage, the connection between the conductive path CDP and the top electrode TE is always maintained, and the connection between the conductive path CDP and the bottom electrode BE is connected or disconnected by application of the reset voltage or the set voltage. Therefore, by controlling the applied voltage, the above-described thin electric-wire-like or filament-like conductive path CDP can be appropriately formed in the memory layer ML between the top electrode TE and the bottom electrode BE.

Further, in the present embodiment, the mobility of the element(s) α is caused to be different in the first layer ML1 and the second layer ML2, so that the element(s) α moves in the first layer ML1, while the element(s) α hardly moves in the second layer ML upon application of the reset voltage or the set voltage. Therefore, the conductive path CDP in the second layer ML2 is hardly changed by application of the reset voltage and the set voltage. Therefore, the position of the conductive path CDP formed in the first layer ML1 by application of the reset voltage or the set voltage is limited to the position connecting the part between the edge of the conductive path CDP in the second layer ML2 (part contacting the interface between the first layer ML and the second layer ML2) and the bottom electrode BE. In other words, even in the reset state, the conductive path CDP maintained in the second layer ML2 substantially determines the position and thickness of the conductive path CDP that is recovered in the first layer ML1 upon setting. As a result, occurrence of instability of rewriting due to variation of the formation position of the conductive path CDP in the in-plane direction (direction parallel to the formation surface of the memory layer ML) can be prevented. Moreover, reproducibility of the resistance value of the case in which rewrite is repeated can be enhanced. Moreover, rewrite by repeating setting and resetting can be stably performed.

And, the area of the bottom electrode BE is smaller than the area of the lower surface of the memory layer ML so that part of the lower surface of the memory layer ML is planarly (plane parallel to the main surface of the semiconductor substrate) overlapped with the bottom electrode BE, however, the other part of the memory layer ML is not planarly overlapped with the bottom electrode BE. Consequently, occurrence of the instability of rewriting due to variation of the formation position of the conductive path CDP formed in the first layer ML1 of the memory layer ML in the in-plane direction (direction parallel to the formation surface of the recording layer ML) can be further appropriately prevented. Moreover, the reproducibility of the resistance value of the case where rewrite is repeated can be further appropriately enhanced.

As described above, in the present embodiment, the performance of the semiconductor device capable of storing information can be improved. Furthermore, the low-power-consumption semiconductor device having stable data rewriting characteristics can be realized. Moreover, multiple rewrite is enabled at a low voltage and by low power consumption.

Moreover, in the second layer ML2 which is the ion feeding layer, the ions (herein, the ions of the element(s) α) which form the conductive path therein can move; therefore, the layer itself can also function as a solid electrolyte layer. It is also conceivable that, in the case where the conductive path CDP is like a filament, the second layer ML serves as a solid electrolyte layer merely in the periphery where the filament (conductive path CDP) is formed.

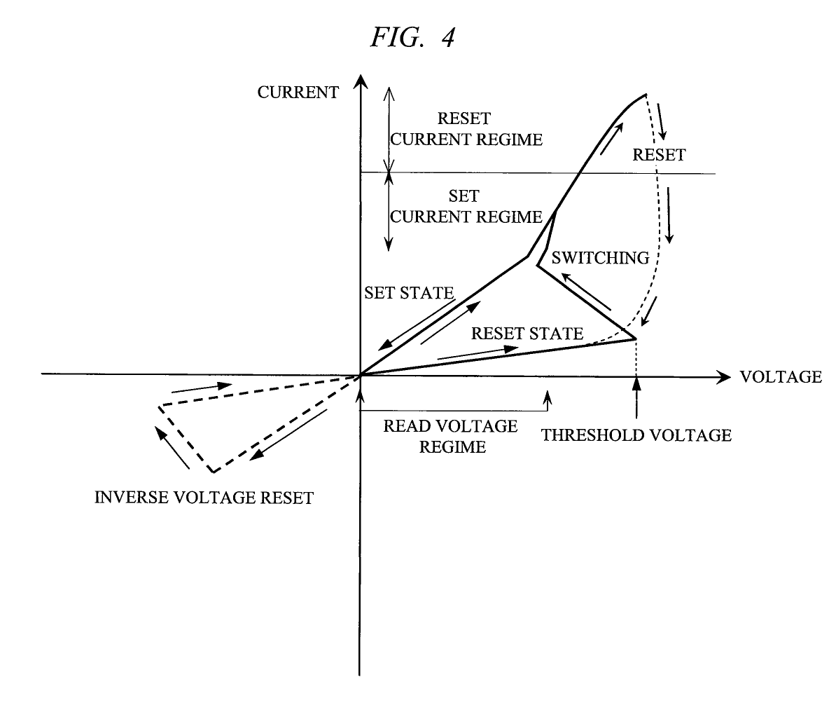

FIG. 4 is an explanatory diagram (graph) schematically showing voltage/current characteristics of the memory element RM.

The voltage/current characteristics of the memory element RM are as shown in FIG. 4. First, when the voltage is increased from the high-resistance reset state and exceeds a threshold value, impact ionization occurs, thereby increasing the number of carriers and also the ionized metal atoms (element(s) α) move, thereby forming the filament-like conductive path CDP; and the resistance is further reduced a little, then the set state is attained. Even when the voltage is reduced, the low-resistance state is maintained. In order to attain the high-resistance state, when a large current is caused to flow through the conductive path for a short period of time, the ions of the conductive path are diffused to the periphery by the generated heat, and it returns to the high-resistance state.

Next, the compositions of the first layer ML1 and the second layer ML2 of the memory layer ML will be described in more detail.

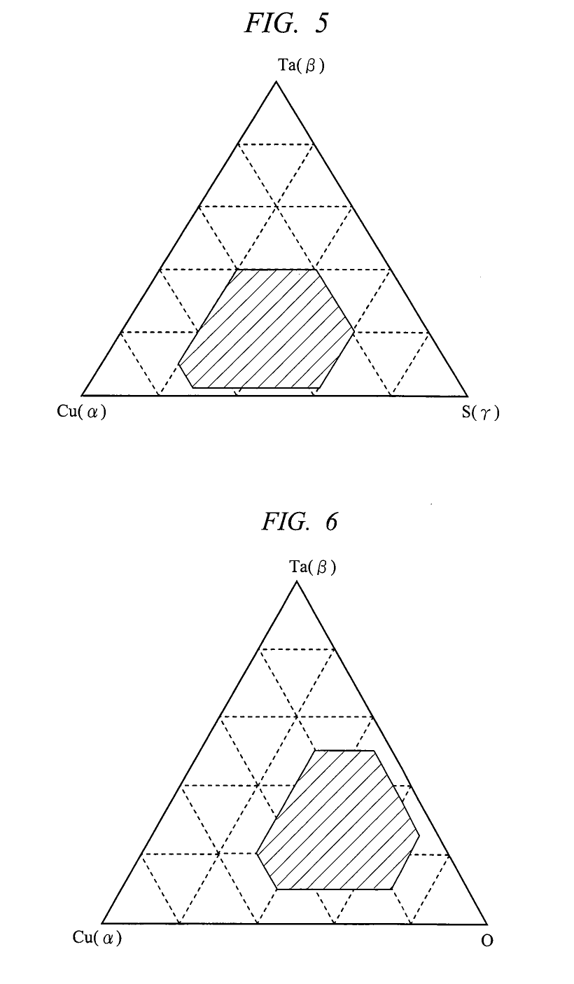

FIG. 5 is an explanatory diagram (graph, triangular diagram, or composition diagram) showing a desired composition range of the material constituting the first layer ML1 of the memory layer ML, and FIG. 6 is an explanatory diagram (graph, triangular diagram, or composition diagram) showing a desired composition range of the material constituting the second layer ML2 of the memory layer ML.

The inventors of the present invention have made memory elements like that shown in above-described FIG. 1 by using materials having various compositions as the materials of the first layer ML1 and the second layer ML2 of the memory layer ML and checked various characteristics thereof; and found out that the first layer ML1 of the memory layer ML preferably comprises a material containing: 20 atom percent (at. %) or more and 70 at. % or less of at least one element selected from the group (first element group) of Cu (copper), Ag (silver), Au (gold), Al (aluminum), Zn (zinc), and Cd (cadmium); 3 at. % or more and 40 at. % or less of at least one element selected from the group (second element group) of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements; and 20 at. % or more and 60 at. % or less of at least one element selected from the group (third element group) of S (sulfur), Se (selenium), and Te (tellurium). The first layer ML1 may contain 10 at. % or less of the other elements (elements other than those of the first element group, the second element group, and the third element group).

In other words, the inventors of the present invention have found out that the composition of the first layer ML1 of the memory layer ML being a composition expressed by a composition formula α_{X}β_{Y}γ_{Z}, wherein 0.2≦X≦0.7, 0.03≦Y≦0.4, 0.2≦Z≦0.6, and X+Y+Z=1, is significantly effective for improving the performance of the memory element. Herein, α in the composition formula α_{X}β_{Y}γ_{Z} of the first layer ML1 of the memory layer ML is at least one element selected from the first element group, β in the composition formula α_{X}β_{Y}γ_{Z} of the first layer ML1 of the memory layer ML is at least one element selected from the second element group, and γ in the composition formula α_{X}β_{Y}γ_{Z} of the first layer ML1 of the memory layer ML is at least one element selected from the third element group. Note that, the composition α_{X}β_{Y}γ_{Z} of the first layer ML1 of the memory layer ML shown herein is expressed by an average composition of the first layer ML1 in the film-thickness direction.

Such desired composition range of the first layer ML1 of the memory layer ML is shown by hatching in FIG. 5. In the present embodiment, the first layer ML1 of the memory layer ML contains the element(s) α, the element(s) β, and the element(s) γ as constituent elements; therefore, the composition triangular diagram of FIG. 5 shows the desired composition range of the first layer ML1 of the memory layer ML. Note that, in FIG. 5, Cu (copper) and Ta (tantalum) are described as examples of the element α and the element β, respectively.

Also, the inventors of the present invention have generated memory elements like that shown in above-described FIG. 1 by using materials having various compositions as the materials of the first layer ML1 and the second layer ML2 of the memory layer ML, checked various characteristics thereof, and found out that the second layer ML2 of the memory layer ML preferably comprises a material containing 5 at. % or more and 50 at. % or less of at least one element selected from the group (first element group) consisting of Cu (copper), Ag (silver), Au (gold), Al (aluminum), Zn (zinc), and Cd (cadmium); containing 10 at. % or more and 50 at. % or less of at least one element selected from the group (second element group) consisting of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements; and containing 30 at. % or more and 70 at. % or less of O (oxygen). The second layer ML2 may contain 10 at. % or less of the other elements (the elements other than those of the first element group, the second element group, and oxygen).

In other words, the inventors of the present invention have found out that the composition of the second layer ML2 of the memory layer ML being a composition expressed by a composition formula α_{Z}β_{Y}O_{Z}, wherein 0.05≦X≦0.5, 0.1≦Y≦0.5, 0.3≦Z≦0.7, and X+Y+Z=1, is significantly effective for improving the performance of the memory element. Herein, α in the composition formula α_{X}β_{Y}O_{Z} of the second layer ML2 of the memory layer ML is at least one element selected from the first element group, β in the composition formula α_{X}β_{Y}O_{Z} of the second layer ML2 of the memory layer ML is at least one element selected from the second element group, and O in the composition formula α_{X}β_{Y}O_{Z} of the second layer ML2 of the memory layer ML is oxygen (O). Note that, the composition α_{X}β_{Y}O_{Z} of the second layer ML2 of the memory layer ML shown herein is expressed by an average composition of the second layer ML2 in the film-thickness direction.

Such desired composition range of the second layer ML2 of the memory layer ML is shown by hatching in FIG. 6. In the present embodiment, the second layer ML2 of the memory layer ML contains the element(s) α, the element(s) β, and oxygen (O) as constituent elements; therefore, the composition triangular diagram of FIG. 6 shows the desired composition range of the second layer ML2 of the memory layer ML. Note that, in FIG. 6, Cu (copper) and Ta (tantalum) are described as examples of the element α and the element β, respectively.

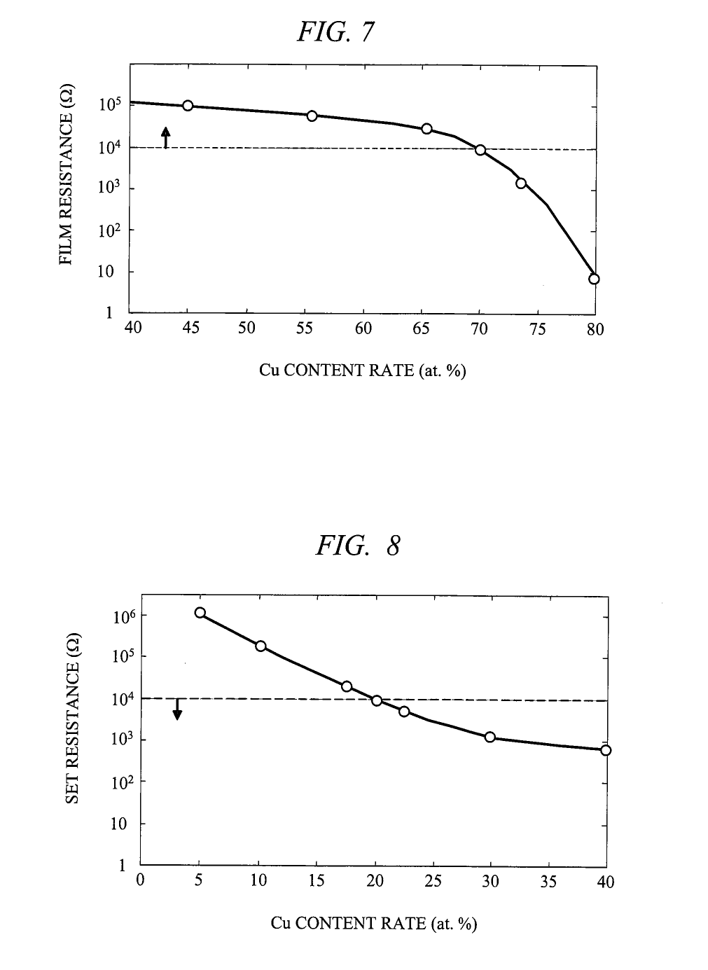

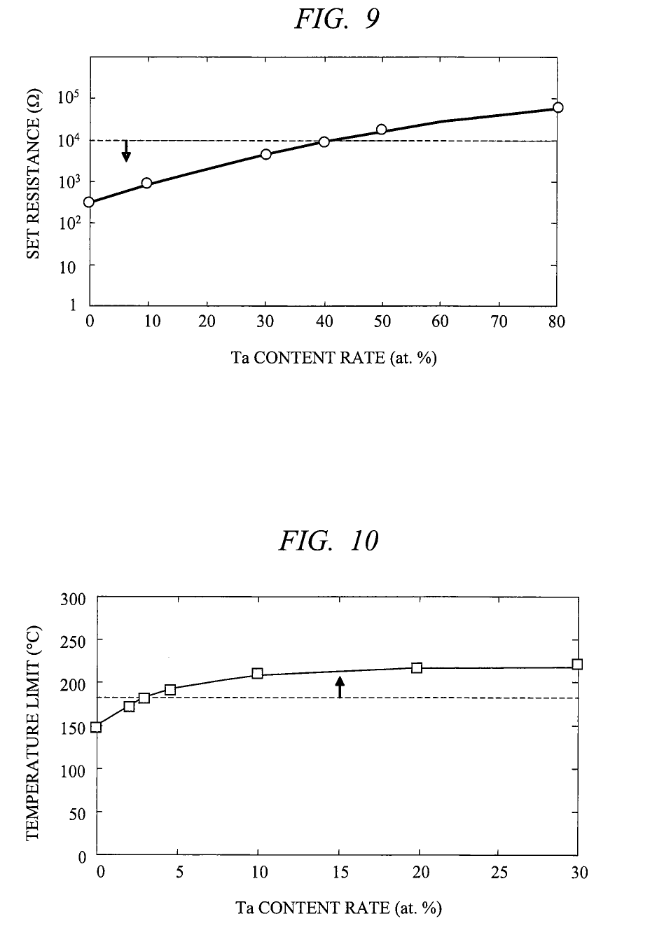

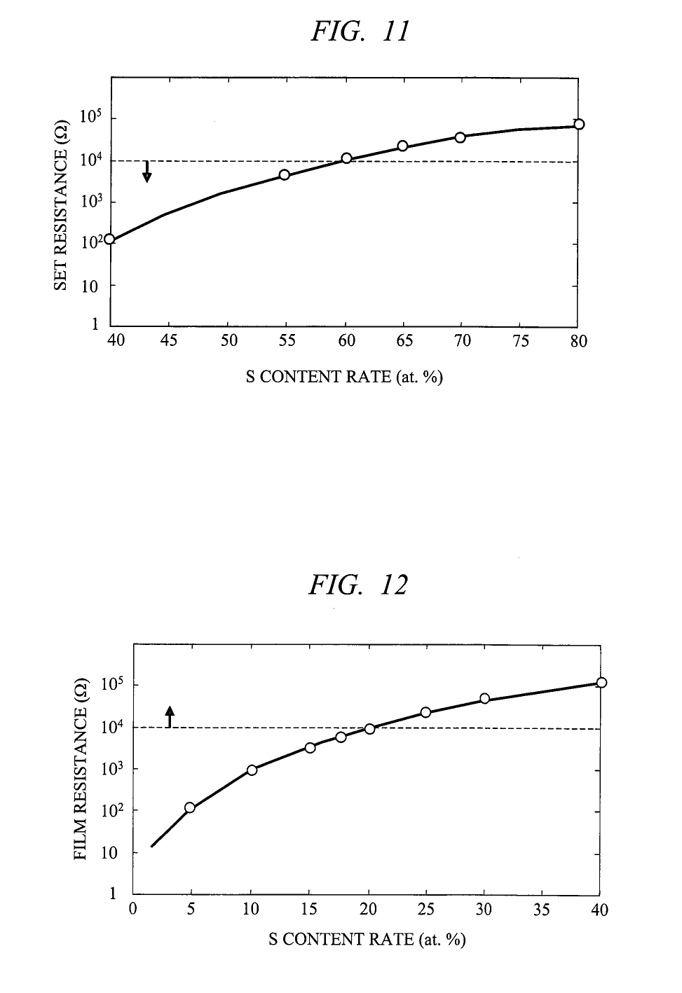

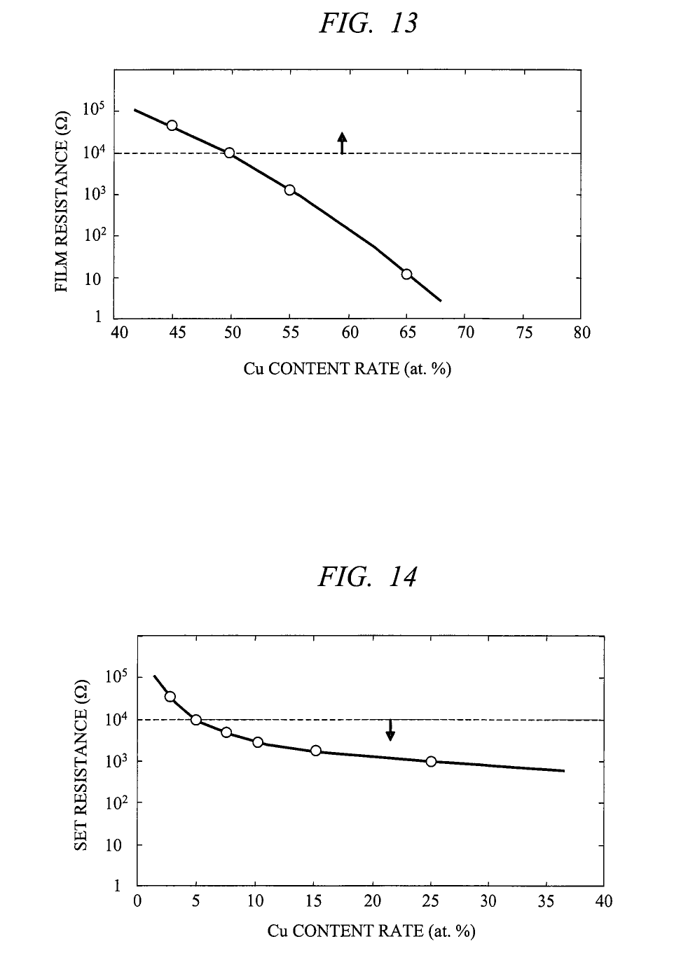

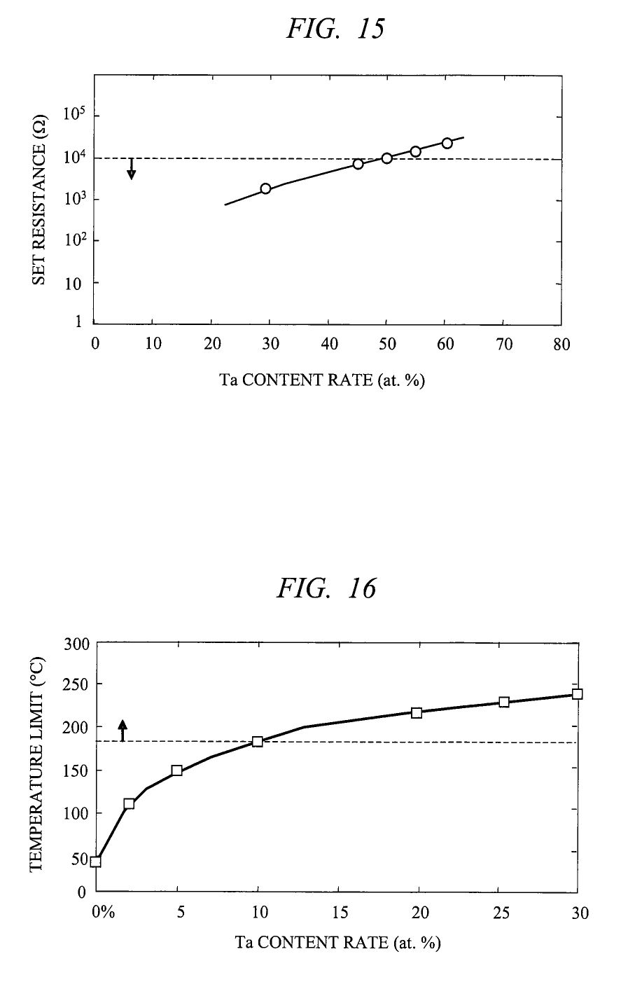

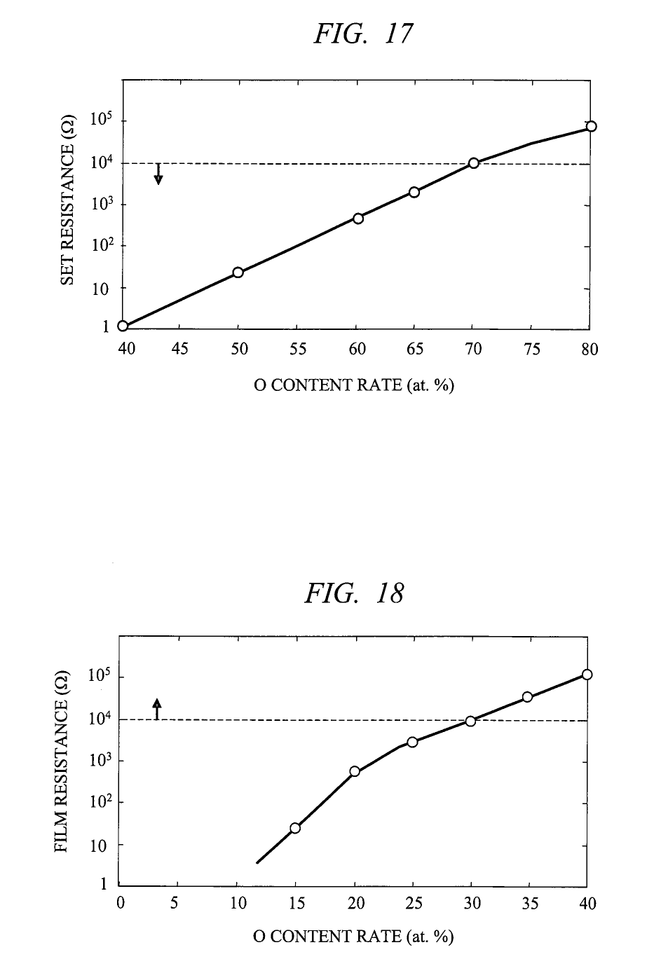

Representative examples of the composition dependence of characteristics of the memory elements studied by the inventors of the present invention are shown in FIG. 7 to FIG. 18. Among these, FIG. 7, FIG. 12, FIG. 13, and FIG. 18 are graphs showing a composition dependence of film resistance; FIG. 8, FIG. 9, FIG. 11, FIG. 14, FIG. 15, and FIG. 17 are graphs showing a composition dependence of set resistance; and FIG. 10 and FIG. 16 are graphs showing a composition dependence of allowed temperature limit.

Note that, the film resistance of the vertical axes of the graphs of FIG. 7, FIG. 12, FIG. 13, and FIG. 18 corresponds to the resistance (electrical resistance) of the film itself in the case where the above-described conductive path CDP is not present. The film resistance is obtained as the electrical resistance between one surface and a surface opposed thereto (for example, a top surface and a bottom surface) of a cube in the case where the material constituting the film is made into a cube having sides each length is 100 nm. When the film resistance is measured by the films having different areas and film thicknesses, the film resistance is converted according to the ratio of the areas and the film thicknesses.

And, the set resistance of the vertical axes of the graphs of FIG. 8, FIG. 9, FIG. 11, FIG. 14, FIG. 15, and FIG. 17 corresponds to the resistance (electrical resistance) between the top electrode TE and the bottom electrode BE in the case where the above-described conductive path CDP is present (the set state of FIG. 2).

Further, the temperature limit (operation guarantee temperature) of the vertical axes of the graphs of FIG. 10 and FIG. 16 corresponds to the upper-limit temperature until which the data written to the memory elements can be stably retained. Herein, in order to check the temperature limit (operation guarantee temperature) of the memory elements, after data was written to the memory elements, they were left in a high-temperature environment for about three minutes, then it has checked whether decrease of the resistance, increase of the resistance, or increase of the set voltage occurred or not due to the high-temperature retention. Then, the upper-limit temperature capable of suppressing the decrease of the resistance, increase of the resistance, and increase of the set voltage of the memory elements was determined as the temperature limit (operation guarantee temperature). Therefore, even when the memory element is heated to a temperature equal to or less than the temperature limit (operation guarantee temperature) after data is written to the memory element, decrease of the resistance, increase of the resistance, and very little increase of the set voltage of the memory element due to the heating occurs so that the data written to the memory element is stably retained. However, when the memory element is heated to a temperature higher than the temperature limit (operation guarantee temperature) after the data is written to the memory element, decrease of the resistance, increase of the resistance, or increase of the set voltage of the memory element occurs due to the heating, and the data written to the memory element cannot be stably retained.

With reference to the graphs of FIG. 7 to FIG. 18, desired compositions of the first layer ML1 and the second layer ML2 of the memory layer ML will be described. Note that, in FIG. 7 to FIG. 12, the composition of the second layer ML2 is fixed to Cu_{0.25}Ta_{0.25}O_{0.5}, and the content rates of the respective elements in the composition of the first layer ML1 are varied while using Cu_{0.5}Ta_{0.15}S_{0.35} as a base composition. In FIG. 13 to FIG. 18, the composition of the first layer ML1 is fixed to Cu_{0.5}Ta_{0.15}S_{0.35}, and the content rates of the elements in the composition of the second layer ML2 are varied while using Cu_{0.25}Ta_{0.25}O_{0.5} as a base composition. The set resistances and the temperature limits were measured while setting each of the film thicknesses of the first layer ML1 and the second layer ML2 to 30 nm.

FIG. 7 is a graph showing the dependence of the film resistance of the first layer ML1 with respect to the Cu content rate of the first layer ML1, where the horizontal axis of the graph corresponds to the content rate of Cu (copper) in the first layer ML1, and the vertical axis of the graph corresponds to the film resistance of ML1. FIG. 8 is a graph showing the dependence of the set resistance with respect to the Cu content rate in the first layer ML1, where the horizontal axis of the graph corresponds to the content rate of Cu (copper) in the first layer ML1, and the vertical axis of the graph corresponds to the set resistance. In the case of the graphs of FIG. 7 and FIG. 8, an atomic ratio (ratio of the number of atoms) of Ta (tantalum) and S (sulfur) in the first layer ML1 is fixed to 15:35, and the content rate of Cu (copper) in the first layer ML1 is varied. In other words, when the number of atoms of Cu (copper) in the first layer ML1 is expressed by M_{Cu}, the number of atoms of Ta (tantalum) in the first layer ML1 is expressed by M_{Ta}, and the number of atoms of S (sulfur) in the first layer ML1 is expressed by M_{S}; in the cases of FIG. 7 and FIG. 8, “M_{Cu}/(M_{Cu}+M_{Ta}+M_{S})” corresponds to the horizontal axis of the graph, and M_{Ta}:M_{S}=15:35. The concept similar to this also applies to FIG. 9 to FIG. 18.

As shown in FIG. 7, when the content rate of Cu (copper) in the first layer ML1 is too high, the film resistance of the first layer ML1 becomes too low; and, as shown in FIG. 8, when the content rate of Cu (copper) in the first layer ML1 is too low, the set resistance, which should be a low resistance, becomes too high. Therefore, the content rate of Cu (copper) in the first layer ML1 is preferably equal to or more than 20 at. % (at. %: atomic percent, atom percent, atom %, atomic %) and equal to or less than 70 at. %. Consequently, a resistance difference between the set state and the reset state can be ensured. If the content rate of Cu (copper) in the first layer ML1 is higher than 70 at. %, the resistance of the first layer ML1 is reduced like an electrode and thus it does not function as a solid electrolyte. On the other hand, if the content rate of Cu (copper) in the first layer is lower than 20 at. %, the first layer ML1 becomes chemically unstable, and setting becomes insufficient. However, when the content rate of Cu (copper) in the first layer ML1 is equal to or more than 20 at. % and equal to or less than 70 at. %, these problems are solved, and operations as a non-volatile memory element can be appropriately performed.

FIG. 9 is a graph showing a dependence of the set resistance with respect to the Ta content rate in the first layer ML1, where the horizontal axis of the graph corresponds to the content rate of Ta (tantalum) in the first layer ML1, and the vertical axis of the graph corresponds to the set resistance. FIG. 10 is a graph showing a dependence of the temperature limit with respect to the Ta content rate in the first layer ML1, where the horizontal axis of the graph corresponds to the content rate of Ta (tantalum) in the first layer ML1, and the vertical axis of the graph corresponds to the temperature limit. In the cases of the graphs of FIG. 9 and FIG. 10, the atomic ratio (the ratio of the number of atoms) of Cu (copper) and S (sulfur) in the first layer ML1 is fixed to 50:35, and the content rate of Ta (tantalum) in the first layer ML1 is varied.

As shown in FIG. 9, when the content rate of Ta (tantalum) in the first layer is too high, the set resistance, which should be a low resistance, becomes too high; and, as shown in FIG. 10, when the content rate of Ta (tantalum) in the first layer ML1 is too low, the temperature limit becomes low. Therefore, the content rate of Ta (tantalum) in the first layer ML1 is preferably equal to or more than 3 at. % and equal to or less than 40 at. %. Consequently, the set resistance can be reduced so that operations as a non-volatile memory can be performed, and the temperature limit can be increased (for example, increased to 180° C. or more). If the content rate of Ta (tantalum) in the first layer ML1 is higher than 40 at. %, the set resistance becomes too high. On the other hand, if the content rate of Ta (tantalum) in the first layer ML1 is lower than 3 at. %, the temperature limit in the low-resistance state (set resistance) becomes insufficient. However, when the content rate of Ta (tantalum) in the first layer ML1 is equal to or more than 3 at. % and equal to or less than 40 at. %, these problems are solved, and operations as a non-volatile memory can be appropriately performed.

FIG. 11 is a graph showing a dependence of the set resistance with respect to S content rate in the first layer ML1, where the horizontal axis of the graph corresponds to the content rate of S (sulfur) in the first layer ML1, and the vertical axis of the graph corresponds to the set resistance. FIG. 12 is a graph showing a dependence of the film resistance of the first layer ML1 with respect to the S content rate in the first layer ML1, where the horizontal axis of the graph corresponds to the content rate of S (sulfur) in the first layer ML1, and the vertical axis of the graph corresponds to the film resistance of the first layer ML1. In the cases of FIG. 11 and FIG. 12, the atomic ratio (the ratio of the number of atoms) of Cu (copper) and Ta (tantalum) in the first layer ML1 is fixed to 50:15, and the content rate of S (sulfur) in the first layer ML1 is varied.

As shown in FIG. 11, when the content rate of S (sulfur) in the first layer ML1 is too high, the set resistance, which should be a low resistance, becomes too high; and, as shown in FIG. 12, when the content rate of S (sulfur) in the first layer ML1 is too low, the film resistance of the first layer ML1 becomes too low. Therefore, the content rate of S (sulfur) in the first layer ML1 is preferably equal to or more than 20 at. % and equal to or less than 60 at. %. Consequently, a resistance difference between the set state and the reset state can be ensured. If the content rate of S (sulfur) in the first layer ML1 is higher than 60 at. %, setting becomes insufficient. On the other hand, if the content rate of S (sulfur) in the first layer ML1 is lower than 20 at. %, the resistance of the first layer ML1 itself becomes low like an electrode and thus it does not function as a solid electrolyte. However, when the content rate of S (sulfur) in the first layer ML1 is equal to or more than 20 at. % and equal to or less than 60 at. %, these problems are solved, and operations as a non-volatile memory can be appropriately performed.

FIG. 13 is a graph showing a dependence of the film resistance of the second layer ML2 with respect to the Cu content rate in the second layer ML2, where the horizontal axis of the graph corresponds to the content rate of Cu (copper), and the vertical axis of the graph corresponds to the film resistance of the second layer ML2. FIG. 14 is a graph showing a dependence of the set resistance with respect to the Cu content rate in the second layer ML2, where the horizontal axis of the graph corresponds to the content rate of Cu (copper) in the second layer ML2, and the vertical axis of the graph corresponds to the set resistance. In the cases of FIG. 13 and FIG. 14, the atomic ratio (ratio of the number of atoms) of Ta (tantalum) and O (oxygen) in the second layer ML2 is fixed to 25:50, and the content rate of Cu (copper) in the second layer ML2 is varied.

As shown in FIG. 13, when the content rate of Cu (copper) in the second layer ML2 is too high, the film resistance of the second layer ML2 becomes too low; and, as shown in FIG. 14, when the content rate of Cu (copper) in the second layer ML2 is too low, the set resistance, which should be a low resistance, becomes too high. Therefore, the content rate of Cu (copper) in the second layer ML2 is preferably equal to or more than 5 at. % and equal to or less than 50 at. %. Consequently, a resistance difference between the set state and the reset state can be ensured. If the content rate of Cu (copper) in the second layer ML2 is higher than 50 at. %, chemical stability of the second layer ML2 becomes insufficient, and the resistance of the second layer ML2 itself becomes low like an electrode, which makes resetting difficult. On the other hand, if the content rate of Cu (copper) in the second layer ML2 is less than 5 at. %, setting becomes insufficient. However, when the content rate of Cu (copper) in the second layer ML2 is equal to or more than 5 at. % and equal to or less than 50 at. %, these problems are solved, and operations as a non-volatile memory element can be appropriately performed.

FIG. 15 is a graph showing a dependence of the set resistance with respect to the Ta content rate in the second layer ML2, where the horizontal axis of the graph corresponds to the content rate of Ta (tantalum) in the second layer ML2, and the vertical axis of the graph corresponds to the set resistance. FIG. 16 is a graph showing a dependence of the temperature limit with respect to the Ta content rate in the second layer ML2, where the horizontal axis of the graph corresponds to the content rate of Ta (tantalum) in the second layer ML2, and the vertical axis of the graph corresponds to the temperature limit. In the cases of the graphs of FIG. 15 and FIG. 16, the atomic ratio (the ratio of the number of atoms) of Cu (copper) and O (oxygen) in the second layer ML2 is fixed to 25:50, and the content rate of Ta (tantalum) in the second layer ML2 is varied.

As shown in FIG. 15, if the content rate of Ta (tantalum) in the second layer ML2 is too high, the set resistance, which should be a low resistance, becomes too high; and, as shown in FIG. 16, if the content rate of Ta (tantalum) in the second layer ML2 is too low, the temperature limit becomes low. Therefore, the content rate (atomic ratio) of Ta (tantalum) in the second layer ML2 is preferably equal to or more than 10 at. % and equal to or less than 50 at. %. Consequently, the set resistance can be reduced, so that operations as a non-volatile memory can be performed and the temperature limit can be increased (for example, increased to 180° C. or more). If the content rate of Ta (tantalum) in the second layer ML2 is higher than 50 at. %, the set resistance becomes too high. On the other hand, if the content rate of Ta (tantalum) in the second layer ML2 is lower than 10 at. %, the heat resistance in the low-resistance state (set state) becomes insufficient. However, when the content rate of Ta (tantalum) in the second layer ML2 is equal to or more than 10 at. % and equal to or less than 50 at. %, these problems are solved, and operations as a non-volatile memory element can be appropriately performed.

FIG. 17 is a graph showing a dependence of the set resistance with respect to the O content rate in the second layer ML2, where the horizontal axis of the graph corresponds to the content rate of O (oxygen) in the second layer ML2, and the vertical axis of the graph corresponds to the set resistance. FIG. 18 is a graph showing a dependence of the film resistance of the second layer ML2 with respect to the O content rate in the second layer ML2, where the horizontal axis of the graph corresponds to the content rate of O (oxygen) in the second layer ML2, and the vertical axis of the graph corresponds to the film resistance of the second layer ML2. In the cases of the graphs of FIG. 17 and FIG. 18, the atomic ratio (the ratio of the number of atoms) of Cu (copper) and Ta (tantalum) in the second layer ML2 is fixed to 25:25, and the content rate of O (oxygen) in the second layer ML2 is varied.

As shown in FIG. 17, if the content rate of O (oxygen) in the second layer ML2 is too high, the set resistance becomes too high; and, as shown in FIG. 18, if the content rate of O (oxygen) in the second layer ML2 is too low, the film resistance of the second layer ML2 becomes too low. Therefore, the content rate (atomic ratio) of O (oxygen) in the second layer ML2 is preferably equal to or more than 30 at. % and equal to or less than 70 at. %. Consequently, the resistance difference between the set state and the reset state can be ensured. If the content rate of O (oxygen) in the second layer ML2 is higher than 70 at. %, setting becomes insufficient. On the other hand, if the content rate of O (oxygen) in the second layer ML2 is lower than 30 at. %, the resistance of the second layer ML2 itself becomes low like an electrode, which makes resetting difficult. However, when the content rate of O (oxygen) in the second layer ML2 is equal to or more than 30 at. % and equal to or less than 70 at. %, these problems are solved, and operations as a non-volatile memory element can be appropriately performed.

Therefore, in consideration of the composition dependences of FIG. 7 to FIG. 18, when copper (Cu), tantalum (Ta), and sulfur (S) are contained, in a desired composition of the first layer ML1 of the memory layer ML, the content rate of copper (Cu) is equal to or more than 20 at. % and equal to or less than 70 at. %, the content rate of tantalum (Ta) is equal to or more than 3 at. % and equal to or less than 40 at. %, and the content rate of sulfur (S) is equal to or more than 20 at. % and equal to or less than 60 at. %. In a desired composition of the second layer ML2 of the memory layer ML, when copper (Cu), tantalum (Ta), and oxygen (O) are contained, the content rate of copper (Cu) is equal to or more than 5 at. % and equal to or less than 50 at. %, the content rate of tantalum (Ta) is equal to or more than 10 at. % and equal to or less than 50 at. %, and the content rate of oxygen (O) is equal to or more than 30 at. % and equal to or less than 70 at. %. In this case, the composition of the material constituting the first layer ML1 of the memory layer ML (average composition in the film-thickness direction of the first layer ML1) can be expressed by the following composition formula, Cu_{X}Ta_{Y}S_{Z}, where 0.2≦X≦0.7, 0.03≦Y≦0.4, and 0.2≦Z≦0.6; and the composition of the material constituting the second layer ML2 of the memory layer ML (average composition in the film-thickness direction of the second layer ML2) can be expressed by the following formula, Cu_{X}Ta_{Y}O_{Z}, where 0.5≦X≦0.5, 0.1≦Y≦0.5, and 0.3≦Z≦0.7. A desired composition of the first layer ML1 of the memory layer ML is, for example, Cu_{0.5}Ta_{0.15}S_{0.35}, and a desired composition of the second layer ML2 of the memory layer ML is, for example, Cu_{0.25}Ta_{0.25}O_{0.5}.

Such desired composition ranges of the first layer ML1 and the second layer ML2 of the memory layer ML correspond to the composition ranges hatched in above-described FIG. 5 and FIG. 6.

Further, in FIG. 7 to FIG. 18, the material constituting the first layer ML1 of the memory layer ML is a Cu—Ta—S-based material, and the material constituting the second layer ML2 of the memory layer ML is a Cu—Ta—O-based material. However, according to the study (experiment) of the inventors of the present invention, it was found out that, even when an element(s) other than Cu which belongs to the first element group is used, an element(s) other than Ta which belongs to the second element group is used, and an element(s) other than S which belongs to the third element group is used, the inclinations similar to those of the composition dependences of FIG. 7 to FIG. 18 were obtained.

Therefore, the first layer ML1 of the memory layer ML preferably comprises a material containing 20 at. % or more and 70 at. % or less of at least one element selected from the first element group (particularly preferably, Cu, Ag), containing 3 at. % or more and 40 at. % or less of at least one element selected from the second element group (particularly preferably, Ta, V, Nb, Cr), and containing 20 at. % or more and 60 at. % or less of at least one element selected from the third element group (particularly preferably, S). The second layer ML2 of the memory layer ML preferably comprises the material containing 5 at. % or more and 50 at. % or less of at least one element selected from the first element group (particularly preferably, Cu, Ag), containing 10 at. % or more and 50 at. % or less of at least one element selected from the second element group (particularly preferably, Ta, V, Nb, Cr), and containing 30 at. % or more and 70 at. % or less of O (oxygen).

Note that, although the preferred compositions of the first layer ML1 and the second layer ML2 have been described, these compositions correspond to the compositions in the state that is after the conductive path CDP is formed by applying the initialization voltages to the memory layer ML (before application of the reset voltage and set voltage) after fabrication of the semiconductor device. The above-described preferred compositions of the first layer ML1 and the second layer ML2 may be achieved when mutual diffusion with another layer(s) occurs due to temperature increase in a process after film formation of the memory layer ML (memory layer 52, which will be described later). The same applies to the compositions described in the embodiments below.

When the first layer ML1 and the second layer ML2 of the memory layer ML have such compositions, the performance of the semiconductor device which can store information can be improved. Furthermore, the semiconductor device which consumes low power and has stable data rewrite characteristics can be realized. Moreover, multiple rewrite can be performed with a low voltage and low power consumption.

Further, in the above-described preferred compositions of the first layer ML1 and the second layer ML2, as described above, Cu (copper) and Ag (silver) are preferred as the element(s) (element(s) α) of the first group contained in the first layer ML1 and the second layer ML2; Ta (tantalum), V (vanadium), Nb (niobium), and Cr (chromium) are preferred as the element(s) (element(S) β) of the second group contained in the first layer ML1 and the second layer ML2; and S (sulfur) is preferred as the element (element γ) of the third element group contained in the first layer ML1.

In the case where the content rate of either one of the element α (element which belongs to the first element group) and the element β (element which belongs to the second element group) is practically zero in either one of the layers of the first layer ML1 and the second layer ML2, the stability of the low-resistance conductive path CDP becomes insufficient; however, depending on the use, for example, the use in which a low price is required even the performance is low, it can be used. The above-described low performance is, for example, low performance in the number of rewritable times and data storage life.

Moreover, it has been found out according to the study (experiment) of the inventors of the present invention that, when the thickness t1 of the first layer ML1 or the thickness t2 of the second layer ML2 is too thin, the number of rewritable times of the memory element RM is reduced; and that, when the thickness t1 of the first layer ML1 or the thickness t2 of the second layer ML2 is too thick, the set voltage is increased. Therefore, the thickness t1 of the first layer ML1 is preferably in the range of 10 to 100 nm, particularly preferably, 15 to 60 nm. And, the thickness t2 of the second layer ML2 is preferably in the range of 10 to 100 nm, particularly preferably, 15 to 60 nm. Consequently, the number of rewritable times of the memory element RM is improved, and increase of the set voltage can be suppressed.

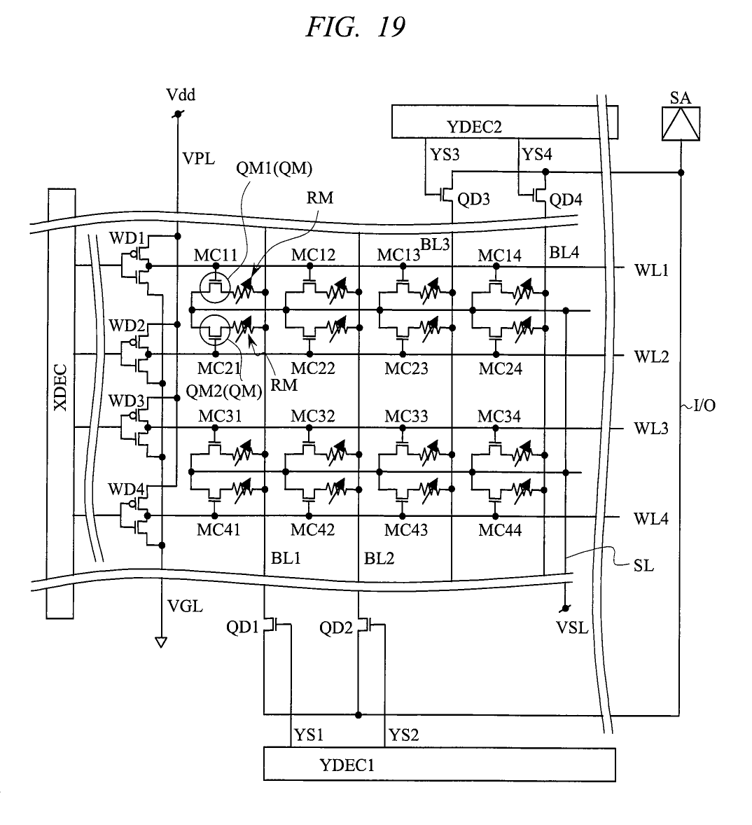

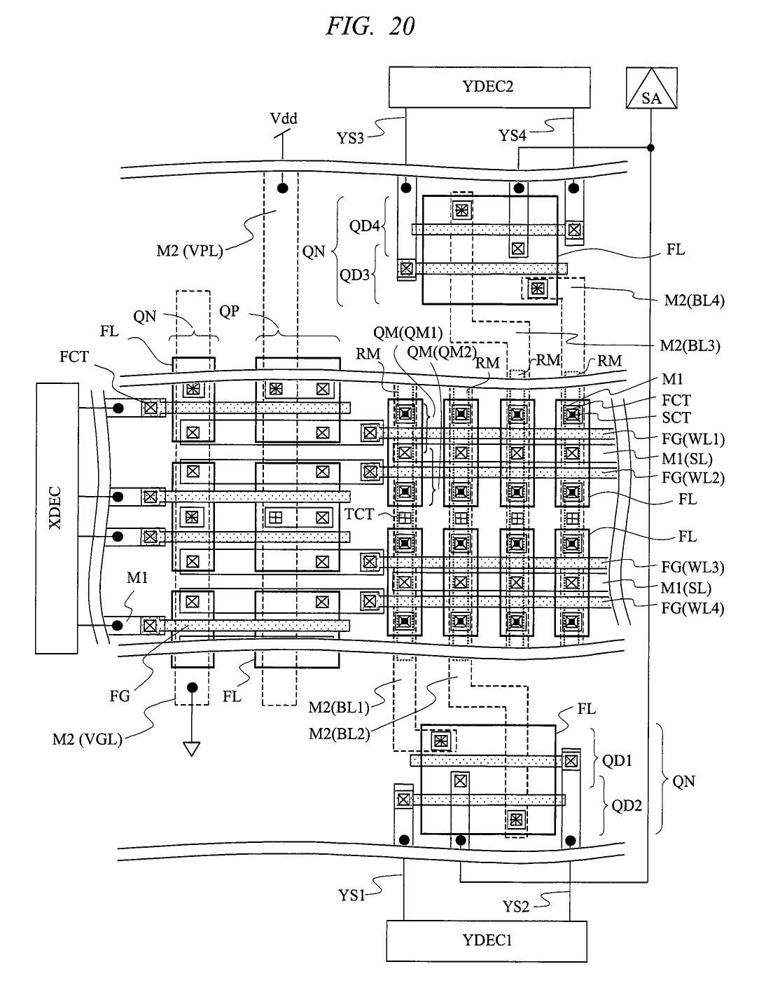

Next, a configuration example of a memory array (memory cell array) of the semiconductor device of the present embodiment will be described with reference to the circuit diagram of FIG. 19. FIG. 19 is a circuit diagram showing a configuration example of the memory array of the semiconductor device of the present embodiment and peripheral parts thereof. FIG. 20 is a plan view showing a plane layout (plan view) corresponding to the array configuration (circuit) of FIG. 19.

In FIG. 19 and FIG. 20, to prevent the drawings and explanations from becoming complex, numerous word lines and bit lines which are usually included are simplified, and four word lines WL1 to WL4 and four bit lines BL1 to BL4 are shown, thereby showing just part of the array. The structure of the memory array shown in FIG. 19 and FIG. 20 is the structure known as a NOR type which is capable of performing reading at a high speed; therefore, it is suitable for storage of system programs and used for, for example, logical LSI combination mounting of, for example, single memory chips or microcomputers.

In FIG. 19, memory cells MC11, MC12, MC13, and MC14 are electrically connected to the word line WL1. Similarly, the memory cells MC21 to MC24, MC31 to MC34, and MC41 to MC44 are electrically connected to the word lines WL2, WL3, and WL4, respectively. The memory cells MC11, MC21, MC31, and MC41 are electrically connected to the bit line BL1. Similarly, the memory cells MC12 to MC42, MC13 to MC43, and MC14 to MC44 are electrically connected to the bit lines BL2, BL3, and BL4, respectively. Hereinafter, the memory cells configuring the memory cells MC11 to MC44 may be referred to as memory cells MC. Also, hereinafter, the word lines configuring the word lines WL1 to WL4 may be referred to as word lines WL. Also, hereinafter, the bit lines configuring the bit lines BL1 to BL4 may be referred to as bit lines BL.

Each of the memory cells MC11 to MC44 comprises one memory cell transistor (MISFET) QM comprising a MISFET (Metal Insulator Semiconductor Field Effect Transistor) and one memory element RM connected thereto in series. Since the configuration of the memory element RM has been described above, the description thereof will be omitted herein. Each of the word lines (WL1 to WL4) is electrically connected to a gate electrode of the memory cell transistor QM configuring each of the memory cells (MC11 to MC44). The bit lines (BL1 to BL4) are electrically connected to the memory elements (storage elements) RM configuring the memory cells (MC11 to MC44). And, one end of each of the memory cell transistors QM of a side opposite to a side connected to the memory element RM is electrically connected to a source line SL.

The word lines WL1 to WL4 are driven by word drivers WD1 to WD4, respectively. Which driver to be selected among the word drivers WD1 to WD4 is determined by a signal from an X address decoder (row decoder) XDEC. Herein, a symbol VPL denotes a power feeding line for the word drivers WD1 to WD4, Vdd denotes a power supply voltage, and VGL denotes an electric potential drawing line of the word drivers WD1 to WD4. Note that, the electric potential drawing line VGL is fixed to a ground voltage (ground potential).

One end of each of the bit lines BL1 to BL4 is connected to a sense amplifier SA via select transistors QD1 to QD4 comprising MISFETs, respectively. The select transistors QD1 to QD4 are selected according to an address input via a Y address decoder (bit decoder, column decoder) YDEC1 or YDEC2. The present embodiment has a configuration in which the select transistors QD1 and QD2 are selected by the Y address decoder YDEC1, and the select transistors QD3 and QD4 are selected by the Y address decoder YDEC2. The sense amplifier SA detects and amplifies signals read from the memory cells (MC11 to MC44) via the select transistors QD1 to QD4. Note that, although it is not shown in the drawing, a circuit which feeds a voltage or a current for read or write is connected to the select transistor QD1 to QD4 in addition to the sense amplifier SA.

In FIG. 20, a symbol FL denotes an active region, M1 denotes a first layer wiring (corresponding to wiring 37, which will be described later), M2 denotes a second layer wiring (corresponding to wiring 72, which will be described later), FG denotes a gate electrode layer (corresponding to a conductive film pattern forming gate electrodes 16a, 16b, 16c, and the like, which will be described later) which is used as gates of the MISFETs formed on a silicon substrate. A symbol FCT denotes a contact hole (corresponding to a contact hole 32, which will be described later) connecting an upper surface of the active region FL and a lower surface of the first layer wiring M1, SCT denotes a contact hole (corresponding to a through hole 42, which will be described later) connecting an upper surface of the first layer wiring M1 and a lower surface of the memory element RM, and TCT denotes a contact hole (corresponding to a through hole 65, which will be described later) connecting an upper surface of the first layer wiring M1 and a lower surface of the second layer wiring M2.

The memory element RM is raised by the second layer wiring M2 via the contact hole TCT between the memory cells (MC) electrically connected to the same bit line (BL). The second layer wiring M2 is used as each of the bit lines (BL). The word lines WL1 to WL4 are formed by the gate electrode layer FG. For example, a stacked layer of polysilicon and silicide (alloy of silicon and a high-melting point metal) is used as the gate electrode layer FG. For example, the memory cell transistor QM1 configuring the memory cell MC11 and the memory cell transistor QM2 configuring the memory cell MC21 share a source region, and this source region is connected to the source line SL, which comprises the first layer wiring M1, via the contact hole FCT. As shown in FIG. 20, the same applies also to the memory cell transistors QM configuring the other memory cells.

The bit lines BL1 to BL4 are connected to the source side of the select transistors QD1 to QD4 which are disposed on the outer periphery of the memory cell array. The select transistors QD1 and QD2 share a drain region, and the select transistors QD3 and QD4 share a drain region. These select transistors QD1 to QD4 have a function of selecting a specified bit line when a signal from the Y address decoder YDEC1 or YDEC2 is received. Note that, the select transistors QD1 to QD4 are, for example, n-channel type in the present embodiment.

Next, the structure of the semiconductor device of the present embodiment will be described in more detail.

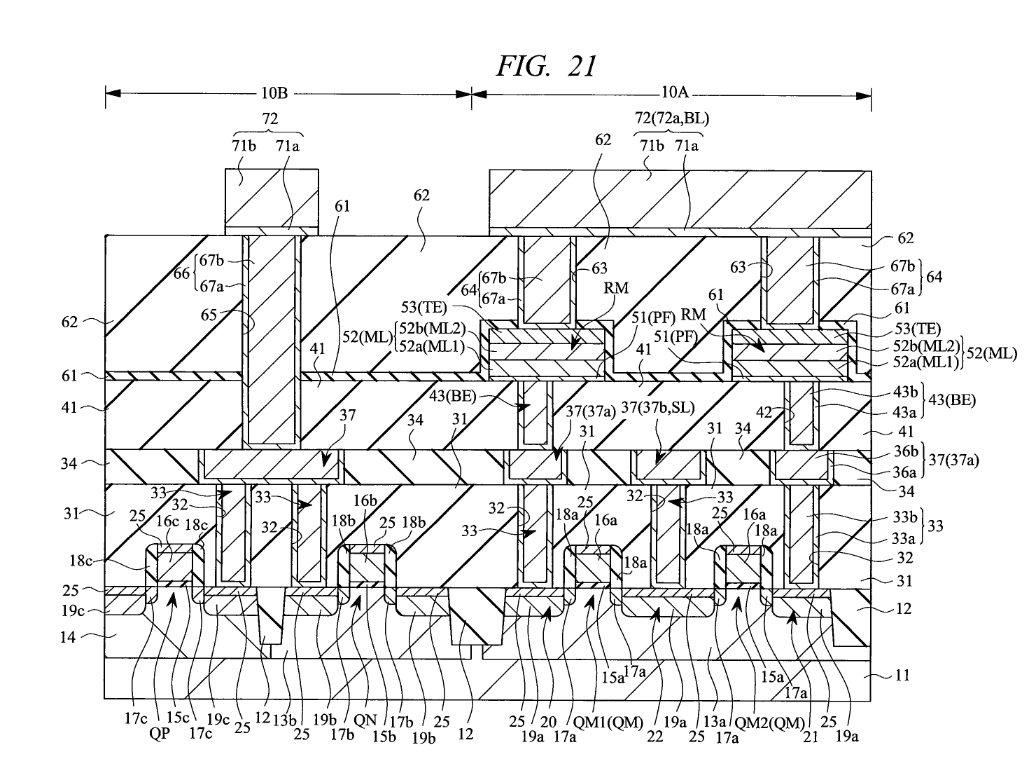

FIG. 21 is a cross sectional view of main parts of the semiconductor device of the present embodiment. In FIG. 21, a cross section (main-part cross section) of a memory cell region 10A and a cross section (main-part cross section) of a peripheral circuit region (logical circuit region) 10B are shown. In the memory cell region 10A, the memory cells MC including the above-described memory cell transistors QM are arranged in an array, and a cross sectional view of a part thereof is shown in FIG. 21 (cross sectional view). In the peripheral circuit region 10B, for example, in the case of a semiconductor device in which various memory peripheral circuits including the sense amplifier SA and the like shown in above-described FIG. 19 and FIG. 20, logics and memories are mounted in combination, a plurality of various logic circuits and the like are arranged in addition, and a cross sectional view of part thereof is shown in FIG. 21. Note that, in FIG. 21, in order to facilitate understanding, the cross section of the memory cell region 10A and the peripheral circuit region 10B are illustrated to be adjacent to each other; however, the positional relation between the memory cell region 10A and the peripheral circuit region 10B may be changed in accordance with needs.

As shown in FIG. 21, for example, a device isolation region 12 is formed on a main surface of the semiconductor substrate (semiconductor wafer) 11 which is formed of, for example, p-type single crystal silicon, and p-type wells 13a and 13b and an n-type well 14 are formed in the active regions isolated by the device isolation region 12. Among these, the p-type well 13a is formed in the memory cell region 10A, and the p-type well 13b and the n-type well 14 are formed in the peripheral circuit region 10B.

On the p-type well 13a of the memory cell region 10A, the memory cell transistors QM (herein, the memory cell transistors QM1 and QM2) which comprise the n-channel type MISFETs are formed. A MIS transistor QN comprising an n-channel type MISFET is formed on the p-type well 13b of the peripheral circuit region 10B, and a MIS transistor QP comprising a p-channel type MISFET is formed on the n-type well 14. Note that, in the present application, a MISFET is sometimes referred to as a MIS transistor.

The memory cell transistors QM1 and QM2 of the memory cell region 10A are MISFETs for memory cell selection of the memory cell region 10A. The memory cell transistors QM1 and QM2 are formed above the p-type well 13a so as to be spaced away from each other, and each of them has a gate insulating film 15a on a surface of the p-type well 13a and a gate electrode 16a on the gate insulating film 15a. On sidewalls of the gate electrode 16a, a sidewall (sidewall spacer) 18a which comprises, for example, a silicon oxide or a silicon nitride film or a stacked film thereof is formed. In the p-type well 13a, a semiconductor region (n-type impurity diffusion layer) 20 serving as a drain region of the memory cell transistor QM1, a semiconductor region (n-type impurity diffusion layer) 21 serving as a drain region of the memory cell transistor QM2, and a semiconductor region (n-type impurity diffusion layer) 22 serving as a source region of the memory cell transistors QM1 and QM2 are formed.

Each of the semiconductor regions 20, 21, and 22 has a LDD (Lightly Doped Drain) structure and is formed by a n⁻-type semiconductor region 17a and a n⁺-type semiconductor region 19a having a higher impurity concentration than that of the n⁻-type semiconductor region 17a. The n⁻-type semiconductor region 17a is formed in the p-type well 13a below the sidewall 18a, the n⁺-type semiconductor region 19a is formed in the p-type well 13a outside the gate electrode 16a and the sidewall 18a, and the n⁺-type semiconductor region 19a is formed in the p-type well 13a at a position away from the channel region by the distance of the n⁻-type semiconductor region 17a. The semiconductor region 22 is shared by the memory cell transistors QM1 and QM2 which are formed in the same device active region and adjacent to each other so as to serve as a common source region. Note that, in the present embodiment, the case where the source region of the MISFETs QM1 and QM2 is common is described; however, as another mode, the drain region may be common, and in this case, the semiconductor region 22 is a drain region, and the semiconductor regions 20 and 21 are source regions.

The MIS transistor QN formed in the peripheral circuit region 10B has a configuration substantially same as the memory cell transistors QM1 and QM2. Specifically, the MIS transistor QN has a gate insulating film 15b on the surface of the p-type well 13b and a gate electrode 16b on the gate insulating film 15b, and a sidewall (sidewall spacer) 18b which comprises, for example, silicon oxide is formed on the sidewalls of the gate electrode 16b. An n⁻-type semiconductor region 17b is formed in the p-type well 13b below the sidewall 18b, and an n⁺-type semiconductor region 19b having a higher impurity concentration than the n⁻-type semiconductor region 17b is formed outside the n⁻-type semiconductor region 17b. The n⁻-type semiconductor region 17b and the n⁺-type semiconductor region 19b form the source/drain regions (semiconductor regions) having the LDD structure of the MIS transistor QN.

The MIS transistor QP formed in the peripheral circuit region 10B has a gate insulating film 15c on a surface of the n-type well 14 and a gate electrode 16c on the gate insulating film 15c, and a sidewall (sidewall spacer) 18c which comprises silicon oxide or the like is formed on the sidewalls of the gate electrode 16c. A p⁻-type semiconductor region 17c is formed in the n-type well 14 below the sidewall 18c, and a p⁺-type semiconductor region 19c having a higher impurity concentration than the p⁻-type semiconductor region 17c is formed outside the p⁻-type semiconductor region 17c. The p⁻-type semiconductor region 17c and the p⁺-type semiconductor region 19c form source/drain regions (semiconductor regions) having the LDD structure of the MIS transistor QP.

On each of the surfaces of the gate electrodes 16a, 16b, and 16c, the n⁺-type semiconductor regions 19a and 19b, and the p⁺-type semiconductor region 19c, a metal silicide layer (for example, a cobalt silicide (CoSi₂) layer) 25 is formed. Consequently, diffusion resistance and contact resistance of the n⁺-type semiconductor regions 19a and 19b, the p⁺-type semiconductor region 19c and the like can be reduced.

On the semiconductor substrate 11, an insulating film (interlayer insulating film) 31 is formed so as to cover the gate electrodes 16a, 16b, and 16c. The insulating film 31 comprises, for example, a silicon oxide film, and the upper surface of the insulating film 31 is planarly formed so that the height thereof is substantially the same in the memory cell region 10A and the peripheral circuit region 10B.

In the insulating film 31, contact holes (opening portion, connection hole, penetrating hole) 32 are formed, and a plug (contact electrode) 33 is formed in each of the contact holes 32. The plug 33 comprises: a conductive barrier film 33a formed of, for example, a titanium film, a titanium nitride film, or a stacked film thereof formed on the bottom and the sidewalls of the contact hole 32; and a main conductive film 33b which is formed on the conductive barrier film 33a so as to fill the interior of the contact hole 32. The main conductive film 33b comprises, for example, a tungsten (W) film. The contact holes 32 and the plugs 33 are formed above the n⁺-type semiconductor regions 19a and 19b and the p⁺-type semiconductor region 19c and, although not illustrated, also above the gate electrodes 16a, 16b, and 16c.

On the insulating film 31 in which the plugs 33 are buried, an insulating film 34 formed of, for example, a silicon oxide film, is formed, and the wiring 37 (corresponding to the above-described wiring M1) serving as a first layer wiring is formed in the wiring trench (opening portion) formed in the insulating film 34. The wiring 37 comprises: a conductive barrier film 36a formed on the bottom and the sidewalls of the wiring trench and formed of, for example, a titanium film, a titanium nitride film, or a stacked film thereof: and a main conductive film 36b which is formed on the conductive barrier film 36a so as to fill the interior of the wiring trench and comprises, for example, a tungsten film. The wiring 37 is electrically connected to, for example, the n⁺-type semiconductor region 19a, 19b, the p⁺-type semiconductor region 19c, the gate electrode 16a, 16b, or 16c via the plug 33. In the memory cell region 10A, the wiring 37 connected to the semiconductor region 22 (n⁺-type semiconductor region 19a) for the source of the memory cell transistors QM1 or QM2 forms a source wiring 37b (corresponding to the above-described source wiring SL).

On the insulating film 34 in which the wiring 37 is buried, an insulating film (interlayer insulating film) 41 which comprises, for example, a silicon oxide film is formed. In the memory cell region 10A, through holes (opening portions, holes, connection holes, through holes) 42 are formed in the insulating film 41, and a plug (contact electrode, bottom electrode) 43 is formed in each of the through holes 42. The plug 43 comprises: a conductive barrier film 43a formed of, for example, a titanium film, a titanium nitride film, or a stacked film thereof formed on the bottom or the sidewalls of the through hole 42; and a main conductive film 43b formed on the conductive barrier film 43a so as to fill the interior of the through hole 42. The main conductive film 43b is formed of, for example, a tungsten (W) film. Therefore, the plug 43 is a conductive portion formed (buried) in the opening portion (through hole 42) of the insulating film 41 which is an interlayer insulating film. The plug 43 is connected to the memory element RM and functions as the bottom electrode BE thereof. The through hole 42 and the plug 43 (bottom electrode BE) are formed above the wiring (conductive portion) 37a which is, among the wiring 37, connected to the semiconductor region 20 or 21 (n⁺-type semiconductor region 19a) for the drain of the memory cell transistor QM1 or QM2 of the memory cell region 10A via the plug 33 and electrically connected to the wiring 37a.

In the memory cell region 10A, the memory element RM comprising: the thin peeling prevention film (interface layer) 51; the memory layer (recording layer, recording material film) 52 on the peeling prevention film 51; and the top electrode film (top electrode) 53 on the memory layer 52 is formed on the insulating film 41 in which the plugs 43 are buried. In other words, the memory element RM is formed by a stacked layer pattern which comprises the peeling prevention film 51, the memory layer 52, and the top electrode film 53. Note that, the combination of the peeling prevention film 51, the memory layer 52, the top electrode film 53, and the plug 43 that is further added as the bottom electrode BE may be considered as the memory element RM. The plug 43 corresponds to the above-described bottom electrode BE, the peeling prevention film 51 corresponds to the above-described peeling prevention film PE, the memory layer 52 corresponds to the above-described memory layer ML, and the top electrode film 53 corresponds to the above-described top electrode TE.

The peeling prevention film 51 is interposed between the insulating film 41 in which the plug 43 is buried and the memory layer 52 so as to improve the bonding (adhesiveness) therebetween and functions to prevent removal of the memory layer 52. The peeling prevention film 51 comprises, for example, a chromium oxide (for example, Cr₂O₃) or tantalum oxide (for example, Ta₂O₅), and the film thickness thereof is, for example, about 0.5 to 5 nm. The peeling prevention film 51 is preferred to be formed; however, depending on the case, formation thereof can be omitted. When formation of the peeling prevention film 51 is omitted, the memory layer 52 is directly formed on the insulating film 41 in which the plugs 43 are buried.

And, even in the case where the peeling prevention film 51 (peeling prevention film PF) is interposed between the upper surface of the plug 43 (bottom electrode BE) and the lower surface of the memory layer ML, when the peeling prevention film 51 (PF) is formed thinly, the peeling prevention film 51 (PF) is not completely continuously formed in the plane, and a current can flow therethrough by the tunneling effect. Therefore, even when the peeling prevention film 51 (PF) is interposed therebetween, the plug 43 (bottom electrode BE) and (the second layer ML2 of) the memory layer ML can be electrically connected to each other, for example, when a voltage is applied. In the present application, contacting includes not only the case in which members are in direct contact, but also the case in which contact is made with the interposition of a layer or a region of an insulating substance, semiconductor, or the like which is thin so as to allow current flow therethrough.

The memory layer 52 comprises a stacked film of a first layer 52a and a second layer 52b on the first layer 52a, where the first layer 52a corresponds to the above-described first layer ML1, and the second layer 52b corresponds to the above-described second layer ML2. The composition of the memory layer 52 comprising the stacked film of the first layer 52a and the second layer 52b is similar to the composition of the memory layer ML comprising a stacked film of the first layer ML1 and the second layer ML2 which has already been described in detail; therefore, the description thereof will be omitted here.

The top electrode film 53 comprises a conductive film such as a metal film and can be formed of, for example, a tungsten (W) film or a tungsten alloy film, and the film thickness thereof may be, for example, about 50 to 200 nm. The top electrode film 53 can function so as to reduce the contact resistance of the plug 64 and the memory layer 52 and prevent sublimation of the memory layer 52 when a conductive barrier film 67a is formed after forming a through hole along with the plug 64.

The bottom of the memory element RM (lower surface of the peeling prevention film 51) is electrically connected to the plug 43 and electrically connected to the drain region 20 or 21 (n⁺-type semiconductor region 19a) of the memory cell transistor QM1 or QM2 of the memory cell region 10A via the plug 43, the wiring 37a, and the plug 33. Therefore, the plug 43 is electrically connected to the lower surface side of the memory layer 52.

Note that, the current path between the plug 43 (bottom electrode BE) and the top electrode film 53 (top electrode TE) is the memory layer 52 (memory layer ML) at the above-region of the plug 43 (bottom electrode BE), and the memory layer 52 (memory layer ML) at a position away from the plug 43 (bottom electrode BE) hardly functions as a current path. Therefore, even when the stacked layer pattern of the memory layer 52 (memory layer ML) and the top electrode film 53 (top electrode TE) is made to be a stripe pattern that passes above the plurality of plugs 43 (bottom electrode BE), the memory element RM can be formed for each of the plugs 43 (bottom electrode BE) by the memory layer 52 (memory layer ML) and the top electrode film 53 (top electrode TE) in the region above each of the plugs 43 (bottom electrodes BE). The stacked layer pattern of the memory layer 52 (memory layer ML) and the top electrode film 53 (top electrode TE) can be divided for each of the plugs 43 (bottom electrodes BE) so as to cause the memory element RM to be an independent pattern.

Further, on the insulating film 41, the insulating film 61 and the insulating film (interlayer insulating film) 62 on the insulating film 61 are formed so as to cover the memory element RM. Specifically, the insulating film 61 is formed on the upper surface of the top electrode film 53 and on the sidewalls of, for example, the memory layer 52, and the insulating film 62 is formed as an interlayer insulating film on the insulating film 61. The film thickness of the insulating film 61 is thinner than that of the insulating film 62 (for example, several hundreds of nm) and may be, for example, about 5 to 20 nm. The insulating film 61 comprises, for example, a silicon nitride film, and the insulating film 62 comprises, for example, a silicon oxide film. The upper surface of the insulating film 62 is planarly formed so that the height thereof is substantially the same in the memory cell region 10A and in the logical circuit region 10B.

In the memory cell region 10A, through holes (opening portions, connection holes, through holes) 63 are formed in the insulating films 61 and 62, at least part of the top electrode film 53 of the memory element RM is exposed at the bottom of the through hole 63, and the plug (contact electrode) 64 is formed in the through hole 63. The plug 64 comprises: the conductive barrier film 67a comprising, for example, a titanium film, a titanium nitride film, or a stacked film thereof formed on the bottom and sidewalls of the through hole 63; and a main conductive film 67b which is formed on the conductive barrier film 67a so as to fill the interior of the through hole 63. The main conductive film 67b is formed of, for example, a tungsten (W) film. As the main conductive film 67b, an aluminum film or the like can be used instead of the tungsten film. The through hole 63 and the plug 64 are formed above the memory element RM, and the plug 64 is electrically connected to the top electrode film 53 of the memory element RM. Therefore, the plug 64 is a conductor portion (conductive portion) which is formed in the opening portion (through hole 63) of the insulating film 62 which is an interlayer insulating film and is electrically connected to the top electrode film 53.

In the peripheral circuit region 10B, a through hole (opening portion, connection hole, penetrating hole) 65 is formed in the insulating films 41, 61, and 62, and the upper surface of the wiring 37 is exposed at the bottom of the through hole 65. In the through hole 65, a plug (contact electrode) 66 is formed. The plug 66 comprises: the conductive barrier film 67a formed of, for example, a titanium film, a titanium nitride film, or a stacked film thereof formed on the bottom and the sidewalls of the through hole 65; and the main conductive film 67b such as a tungsten film which is formed on the conductive barrier film 67a so as to fill the interior of the through hole 65. The through hole 65 and the plug 66 are electrically connected to the wiring 37.

On the insulating film 62 in which the plugs 64 and 66 are buried, the wiring (second wiring layer) 72 serving as the second layer wiring is formed. The wiring 72 comprises: a conductive barrier film 71a comprising, for example, a titanium film, a titanium nitride film, or a stacked film thereof; and a main conductive film 71b on the conductive barrier film 71a. The main conductive film 71b is formed of, for example, an aluminum (Al) film or an aluminum alloy film. A conductive barrier film similar to the conductive barrier film 71a may be further formed on the main conductive film 71b such as an aluminum alloy film to form the wiring 72.

In the memory cell region 10A, the wiring (bit line) 72a in the wiring 72 serves as the bit line BL and electrically connected to the top electrode film 53 of the memory element RM via the plug 64. Therefore, the wiring 72a configuring the bit line BL of the memory cell region 10A is electrically connected to the drain region 20 or 21 (n⁺-type semiconductor region 19a) of the memory cell transistor QM1 or QM2 of the memory cell region 10A via the plug 64, the memory element RM, the plug 43, the wiring 37a, and the plug 33.

In the peripheral circuit region 10B, the wiring 72 is electrically connected to the wiring 37 via the plug 66 and is further electrically connected to the n⁺-type semiconductor region 19b of the MIS transistor QN and the p⁺-type semiconductor region 19c of the MIS transistor QP via the plugs 33.

On the insulating film 62, an insulating film (not shown) serving as an interlayer insulating film is formed so as to cover the wiring 72, and an upper-layer wiring layer (wiring after third layer wiring) and the like are further formed; however, illustrations and descriptions thereof will be omitted here.

As described above, a semiconductor integrated circuit including the memory elements of the memory cell region 10A and the MISFETs of the peripheral circuit region 10B is formed on the semiconductor substrate 11, thereby configuring the semiconductor device of the present embodiment.

In the above-described constitution, the memory cell (corresponding to the above-described memory cell MC) of the memory comprises the memory element RM and the memory cell transistor QM1 or QM2 connected thereto. The gate electrode 16a of the memory cell transistor QM1 or QM2 is electrically connected to the word line WL (corresponding to the above-described word line WL1 to WL4 of FIG. 19). One end of the memory element RM (herein, the upper surface of the top electrode film 53) is electrically connected to the bit line BL (corresponding to the above-described bit lines BL1 to BL4) comprising the wiring 72 via the plug 64. The other end of the memory element RM (herein, the lower surface side of the memory layer 52, that is, the interface layer 51) is electrically connected to the semiconductor region 20 or 21 for drain of the memory cell transistor QM1 or QM2 via the plug 43 (that is, the bottom electrode BE), the wiring 37a, and the plug 33. The semiconductor region 22 for the source of the memory cell transistors QM1 and QM2 is electrically connected to the source wiring 37b (corresponding to the above-described source line SL in FIG. 19) via the plug 33.

Note that, in the present embodiment, the case where n-channel type MISFETs are used as the memory cell transistors QM1 and QM2 (transistors for memory cell selection) of the memory has been shown; however, as another mode, instead of the n-channel type MISFETs, other field-effect transistors, for example, p-channel type MIS transistors can be used as the memory cell transistors QM1 and QM2. However, from the viewpoint of high integration, MISFETs are preferably used as the memory cell transistors QM1 and QM2 of the memory, and n-channel type MISFETs having low channel resistance in an ON state are more preferred compared with p-channel type MISFETs.

In the present embodiment, the memory element RM is electrically connected to the drain (semiconductor region 10 or 11) of the memory cell transistor QM1 or QM2 of the memory cell region 10A via the plug 43, the wiring 37 (37a), and the plug 33; however, as another mode, the memory element RM may be electrically connected to the source of the memory cell transistors QM1 and QM2 of the memory cell region 10A via the plug 43, the wiring 37 (37a), and the plug 33. In other words, the memory element RM is required be electrically connected to one of the source and drain of the memory cell transistor QM1 or QM2 of the memory cell region 10A via the plug 43, the wiring 37 (37a), and the plug 33. However, the case in which the drain, instead of the source, of the memory cell transistor QM1 or QM2 of the memory cell region 10A is more preferred to be electrically connected to the memory element RM via the plug 33, the wiring 37 (37a), and the plug 43 in consideration of the function as a non-volatile memory.

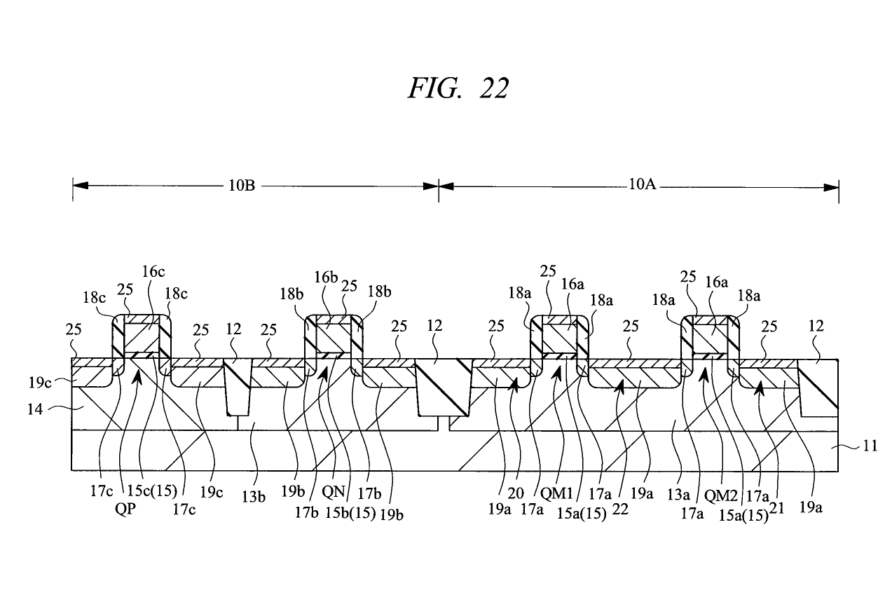

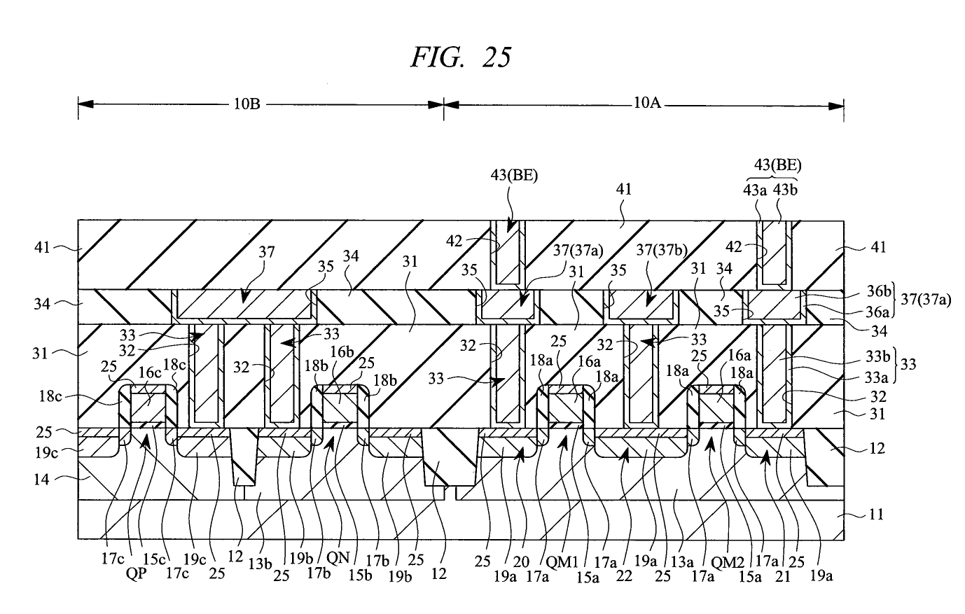

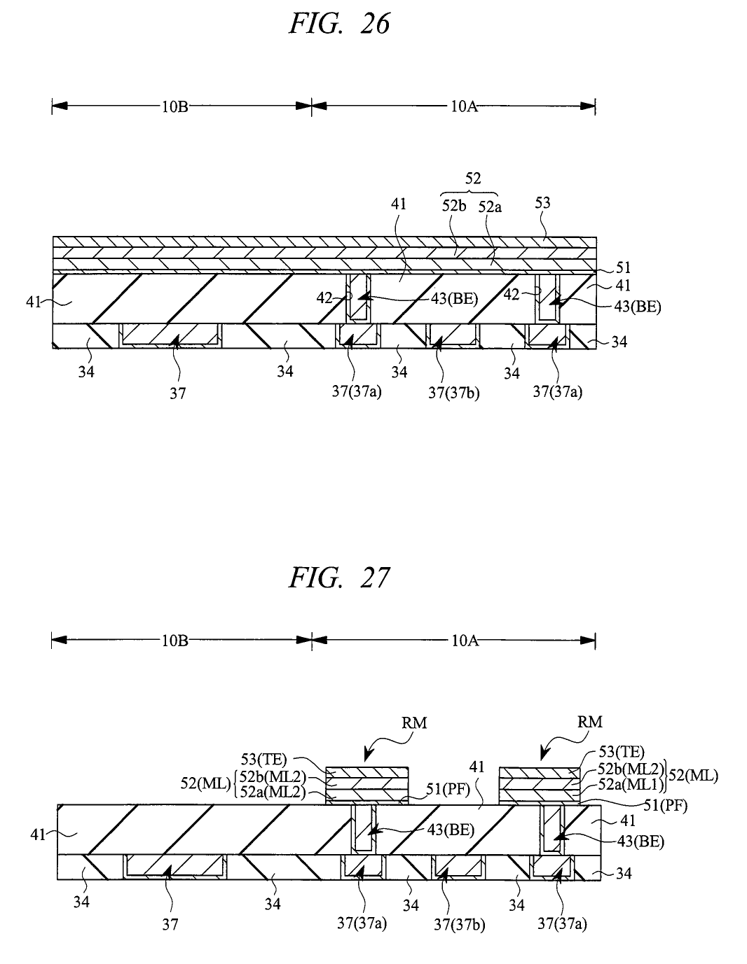

Next, fabrication steps of the semiconductor device of the present embodiment will be described with reference to the drawings. FIG. 22 to 31 are cross sectional views showing main parts of the semiconductor device of the present embodiment during fabrication steps, where a region corresponding to above-described FIG. 21 is shown. Note that, to facilitate understanding, in FIG. 26 to FIG. 31, illustrations of the insulating film 31 of FIG. 25 and the part corresponding to the structure below the insulating film 31 are omitted.

First, as shown in FIG. 22, the semiconductor substrate (semiconductor wafer) 11 formed of, for example, p-type single crystal silicon is prepared. Then, on the main surface of the semiconductor substrate 11, the device isolation regions 12 formed of an insulator are formed, for example, by the STI (Shallow Trench Isolation) method or the LOCOS (Local Oxidization of Silicon) method. When the device isolation regions 12 are formed, on the main surface of the semiconductor substrate 11, the active region having the periphery defined by the device isolation regions 12 is formed.

Next, on the main surface of the semiconductor substrate 11, the p-type wells 13a and 13b and the n-type well 14 are formed. Among these, the p-type well 13a is formed in the memory cell region 10A, and the p-type well 13b and the n-type well 14 are formed in the peripheral circuit region 10B. For example, the p-type wells 13a and 13b can be formed, for example, by subjecting a p-type impurity (for example, boron (B)) to ion implantation into part of the semiconductor substrate 11, and the n-type well 14 can be formed, for example, by subjecting an n-type impurity (for example, phosphorous (P) or arsenic (As)) to ion implantation into the other part of the semiconductor substrate 11.

Next, for example, by using the thermal oxidation method, the insulating film 15 for the gate insulating film which comprises a thin silicon oxide film or the like is formed on the surface of the p-type wells 13a and 13b and the n-type well 14 of the semiconductor substrate 11. A silicon oxynitride film or the like may be used as the insulating film 15. The film thickness of the insulating film 15 is, for example, about 1.5 to 10 nm.

Next, on the insulating film 15 of the p-type wells 13a and 13b and the n-type well 14, the gate electrodes 16a, 16b, and 16c are formed. For example, a low-resistance polycrystalline silicon film is formed as a conductive film on the entire surface of the main surface of the semiconductor substrate 11 including the part on the insulating film 15, and the polycrystalline silicon film is patterned by using, for example, the photoresist method and the dry etching method, thereby forming the gate electrodes 16a, 16b, and 16c which comprise the patterned polycrystalline silicon film (conductive film). The insulating film 15 remaining below the gate electrode 16a serves as the gate insulating film 15a, the insulating film 15 remaining below the gate electrode 16b serves as the gate insulating film 15b, and the insulating film 15 remaining below the gate electrode 16c serves as the gate insulating film 15c. By doping impurities during film formation or after film formation, the gate electrodes 16a and 16b are formed by a polycrystalline silicon film (doped polysilicon film) into which an n-type impurity is introduced, and the gate electrode 16c is formed by a polycrystalline silicon film (doped polysilicon film) into which a p-type impurity is introduced.

Next, for example, by subjecting an n-type impurity such as phosphorous (P) or arsenic (As) to ion implantation, the n⁻-type semiconductor regions 17a are formed in the regions in the both sides of the gate electrode 16a of the p-type well 13a, and the n⁻-type semiconductor regions 17b are formed in the regions at the both sides of the gate electrode 16b of the p-type well 13b. Also, for example, by subjecting a p-type impurity such as boron (B) to ion implantation, the p⁻-type semiconductor regions 17c are formed in the regions at the both sides of the gate electrode 16c of the n-type well 14.

Next, on the sidewalls of the gate electrodes 16a, 16b, and 16c, the sidewalls 18a, 18b, and 18c are formed. The sidewalls 18a, 18b, and 18c are formed, for example, by depositing an insulating film which comprises a silicon oxide film, a silicon nitride film, or a stacked film thereof on the semiconductor substrate 11 and subjecting the insulating film to anisotropic etching.

Next, for example, an n-type impurity such as phosphorous (P) or arsenic (As) is subjected to ion implantation, thereby forming the n⁺-type semiconductor regions 19a in the regions at the both sides of the gate electrode 16a and the sidewall 18a in the p-type well 13a and forming the n⁺-type semiconductor regions 19b in the both sides of the gate electrode 16b and the sidewall 18b of the p-type well 13b. Also, for example, a p-type impurity such as boron (B) is subjected to ion implantation, thereby forming p⁺-type semiconductor regions 19c at the regions in the both sides of the gate electrode 16c and the sidewall 18c of the n-type well 14. After the ion implantation, annealing treatment (thermal treatment) for activating the introduced impurities can be also carried out.

Consequently, each of the n-type semiconductor regions 20 and 21 which function as the drain regions of the memory cell transistors QM1 and QM2 of the memory cell region 10A and the n-type semiconductor region 22 which functions as a common source region are formed by the n⁺-type semiconductor region 19a and the n⁻-type semiconductor region 17a. Then, each of the n-type semiconductor region which functions as the drain region and the n-type semiconductor region which functions as the source region of the MIS transistor QN of the peripheral circuit region 10B is formed by the n⁺-type semiconductor region 19b and the n⁻-type semiconductor region 17b; and each of the p-type semiconductor region which functions as a drain region and the p-type semiconductor region which functions as a source region of the MIS transistor QP is formed by the p⁺-type semiconductor region 19c and the p⁻-type semiconductor region 17c.

Next, the surfaces of the gate electrodes 16a, 16b, and 16c, the n⁺-type semiconductor regions 19a and 19b, and the p⁺-type semiconductor region 19c are caused to be exposed, and a metal film such as a cobalt (Co) film is deposited thereon and subjected to thermal treatment, thereby forming metal silicide layers 25 on the surfaces of the gate electrodes 16a, 16b, and 16c, the n⁺-type semiconductor regions 19a and 19b, and the p⁺-type semiconductor region 19c, respectively. Then, the unreacted cobalt film (metal film) is removed.

In this manner, the structure of FIG. 22 is obtained. As a result of the steps until this point, the memory cell transistors QM1 and QM2 which comprise n-channel type MISFETs are formed in the memory cell region 10A, and the MIS transistor QN which comprises the n-channel type MISFET and the MIS transistor QP which comprises the p-channel type MISFET are formed in the peripheral circuit region 10B. Therefore, the memory cell transistors QM1 and QM2 of the memory cell region 10A and the MIS transistors QN and QP of the peripheral circuit region 10B can be formed in the same fabrication steps.

In addition, instead of the above-described transistors (memory cell transistors QM1 and QM2), a diode may be formed at each intersecting point of the matrix (matrix of the memory cells). When the diode serves as a select element (element for selecting a memory cell), the diode is desired to be able to cause the memory element RM to be ON (low-resistance state) or OFF (high-resistance state) by a voltage of one direction. The diode can be formed by annealing after forming thin-film silicon.

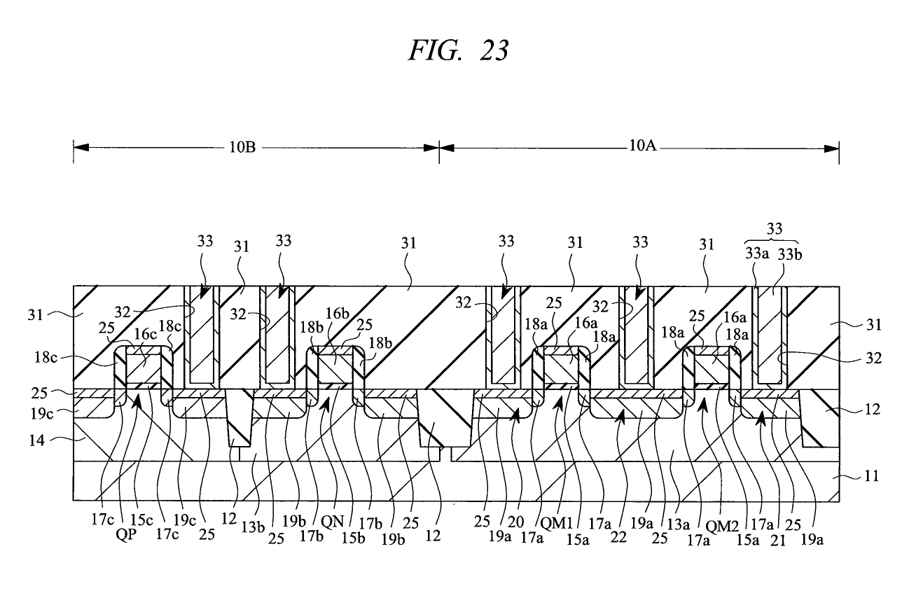

Next, as shown in FIG. 23, the insulating film (interlayer insulating film) 31 is formed on the semiconductor substrate 11 so as to cover the gate electrodes 16a, 16b, and 16c. The insulating film 31 comprises, for example, a silicon oxide film. The insulating film 31 can be formed by a stacked film of a plurality of insulating films. After formation of the insulating film 31, in accordance with needs, a CMP process or the like is carried out, thereby planarizing the upper surface of the insulating film 31. Consequently, the height of the upper surface of the insulating film 31 becomes substantially same in the memory cell region 10A and in the peripheral circuit region 10B.

Next, a photoresist pattern (not shown) formed on the insulating film 31 by using the photolithography method is used as an etching mask, and the insulating film 31 is subjected to dry etching, thereby forming the contact holes 32 in the insulating film 31. In the bottom of the contact holes 32, for example, part of the main surface of the semiconductor substrate 11 such as part of (the metal silicide layers 25 on the surfaces of) the n⁺-type semiconductor regions 19a and 19b and the p⁺-type semiconductor region 19c and part of (the metal silicide layers 25 on the surfaces of) the gate electrodes 16a, 16b, and 16c are exposed.

Next, the plugs 33 are formed in the contact holes 32. In this process, for example, the conductive barrier film 33a is formed by the sputtering method on the insulating film 31 including the interior of the contact holes 32, the main conductor 33b comprising, for example, a tungsten (W) film is then formed on the conductive barrier film 33a by the CVD method so as to fill the contact holes 32, and the unnecessary part of the main conductive film 33b and the conductive barrier film 33a on the insulating film 31 is removed by the CMP method or the etch-back method. Consequently, the plugs 33 which comprise the main conductive film 33b and the conductive barrier film 33a remaining and buried in the contact holes 32 can be formed.

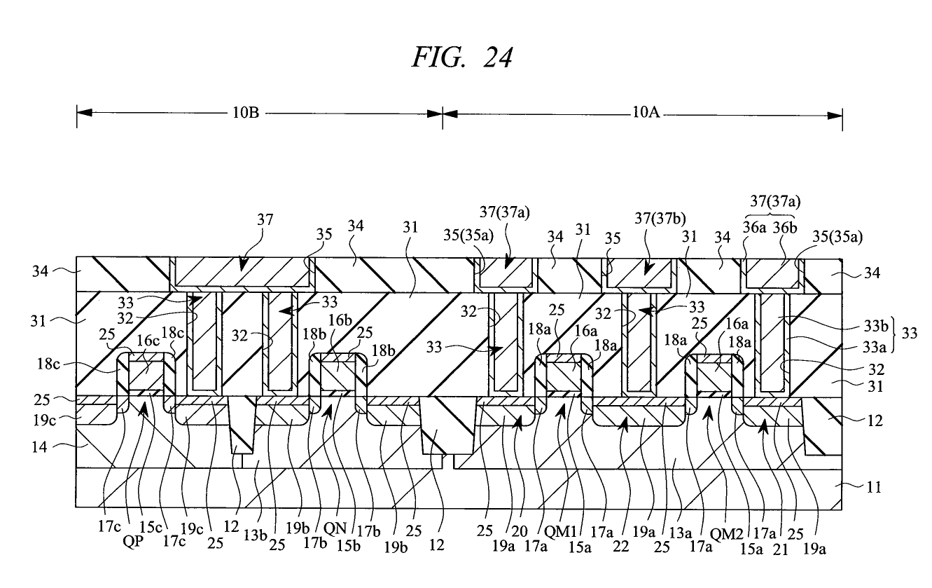

Next, as shown in FIG. 24, the insulating film 34 is formed on the insulating film 31 in which the plugs 33 are buried. Then, a photoresist pattern (not shown) formed on the insulating film 34 by the photolithography method is used as an etching mask, and the insulating film 34 is subjected to dry etching, thereby forming the wiring trenches (opening portions) 35 in the insulating film 34. The upper surfaces of the plugs 33 are exposed at the bottom of the wiring trenches 35. Among the wiring trenches 35, the ones in which the plugs 33 formed on the drain regions (semiconductor regions 20 and 21) of the memory cell transistors QM1 and QM2 of the memory cell region 10A, that is, the opening portions 35a are exposed may be formed as, instead of a trench-like pattern, a pattern of holes (connection holes) each of which having a size larger than the plane size of the plug 33 exposed therefrom. And, in the present embodiment, the opening portions 35a are formed at the same time as the other wiring trenches 35; however, the opening portions 35a and the other wiring trenches 35 can be formed in different steps by separately using a photoresist pattern for forming the opening portions 35a and a photoresist pattern for forming the other wiring trenches 35.

Next, the wiring (first layer wiring) 37 is formed in the wiring trenches 35. In this process, for example, the conductive barrier film 36a is formed by the sputtering method or the like on the insulating film 34 including the interior (on the bottom and sidewalls) of the wiring trenches 35, the main conductive film 36b which comprises, for example, a tungsten (W) film is then formed by the CVD method or the like on the conductive barrier film 36a so as to fill the wiring trenches 35; and the unnecessary part of the main conductive film 36b and the conductive barrier film 36a on the insulating film 34 is removed by the CMP method, the etch back method, or the like. Consequently, the wiring 37 which comprises the main conductive film 36b and the conductive barrier film 36a remaining and buried in the wiring trenches 35 can be formed.

Among the wirings 37, the one formed in the opening portion 35a in the memory cell region 10A is electrically connected to the drain region (semiconductor region 20 or 21) of the memory cell transistor QM1 or QM2 of the memory cell region 10A via the plug 33. The wiring 37a is not extended on the insulating film 31 in the manner mutually connecting the semiconductor elements formed on the semiconductor substrate 11, but is locally present on the insulating film 31 and interposed between the plugs 43 and the plugs 33 so as to electrically connect the plugs 43 and the plugs 33 to each other. Therefore, the wiring 37a can be considered to be conductor portions (contact electrodes, conductive portions) for connection, instead of wiring. Also, in the memory cell region 10A, the source wiring 37b which is connected to the semiconductor region 22 (n⁺-type semiconductor region 19a) for the source of the memory cell transistor QM1 and QM2 via the plug 33 is formed by the wiring 37.

The wiring 37 is not limited to the above-described buried tungsten wiring, but can be variously changed. For example, the wiring may be tungsten wiring, aluminum wiring, or the like other than the buried one.

Next, as shown in FIG. 25, the insulating film (interlayer insulating film) 41 is formed on the insulating film 34 in which the wiring 37 is buried.

Next, a photoresist pattern (not shown) formed on the insulating film 41 by using the photolithography method is used as an etching mask, and the insulating film 41 is subjected to dry etching, thereby forming the through holes (opening portions, connection holes) 42 in the insulating film 41. The through hole 42 is formed in the memory cell region 10A, and the upper surface of the above-described wiring 37a is exposed at the bottom of the through hole 42.

Next, in the through holes 42, the conductive plugs 43 are formed. In this process, for example, the conductive barrier film 43a is formed by the sputtering method or the like on the insulating film 41 including the interior of the through holes 42, the main conductive film 43b which comprises, for example, the tungsten (W) film is then formed by the CVD method or the like on the conductive barrier film 43a so as to fill the through holes 42, and the unnecessary part of the main conductive film 43b and the conductive barrier film 43a on the insulating film 41 is removed by the CMP method, the etch back method, or the like. Consequently, the plugs 43 which comprise the main conductive film 43b and the conductive barrier film 43a remaining and buried in the contact holes 42 can be formed. In this manner, the plugs 43 are formed by filling a conductive material in the opening portions (through holes 42) formed in the insulating film 41.

Further, in the present embodiment, the tungsten (W) film is used as the main conductive film 43b so that the plugs 43 are buried in the through holes 42; however, a metal having good CMP flatness which causes the upper surfaces of the plugs 43 to be flat may be used as the main conductive film 43b instead of the tungsten film. For example, Mo (molybdenum) having a small crystal grain size can be used as the main conductive film 43b. The metal having good CMP flatness has the effect of suppressing local change of the memory layer 52 due to electric field concentration that occurs at nonflat parts of the upper surfaces of the plugs 43. As a result, the uniformity of the electric characteristics, the reliability of the number of rewritable times, and high-temperature tolerant operation characteristics of the memory cell elements can be further improved.

Next, as shown in FIG. 26, the peeling prevention film 51, the memory layer 52, and the top electrode film 53 are sequentially formed (deposited) on the insulating film 41 in which the plugs 43 are buried. Note that, as described above, in FIG. 26 to FIG. 31, illustrations of the insulating film 31 and the part corresponding to the structure below the insulating film 31 of FIG. 25 are omitted. The film thickness (deposited film thickness) of the peeling prevention film 51 is, for example, about 0.5 to 5 nm, the film thickness (deposited film thickness) of the memory layer 52 is, for example, about 20 to 200 nm, and the film thickness (deposited film thickness) of the top electrode film 53 is, for example, about 50 to 200 nm.

In this process, when forming the memory layer 52, for example, the sputtering method using an inert gas such as Ar (argon), Xe (xenon), and Kr (krypton) and two types of targets can be used. The memory layer 52 comprises, as described above, the stacked film of the first layer 52a and the second layer 52b. Therefore, when forming the memory layer 52, first, preferably about 10 to 100 nm, more preferably about 15 to 60 nm of the first layer 52a is formed (deposited), for example, by Cu_{0.5}Ta_{0.15}S_{0.35}; then, preferably about 10 to 100 nm, more preferably about 15 to 60 nm of the second layer 52b is formed (deposited) on the first layer, for example, by Cu_{0.25}Ta_{0.25}O_{0.5}.

Next, as shown in FIG. 27, by using the photolithography method and the dry etching method, the stacked film which comprises the peeling prevention film 51, the memory layer 52, and the top electrode film 53 is patterned. Consequently, the memory element RM which comprises the stacked pattern of the top electrode film 53, the memory layer 52, and the peeling prevention film 51 is formed on the insulating film 41 in which the plugs 43 are buried. The peeling prevention film 51 can be also used as an etching stopper film when the top electrode film 53 and the memory layer 52 are subjected to dry etching.

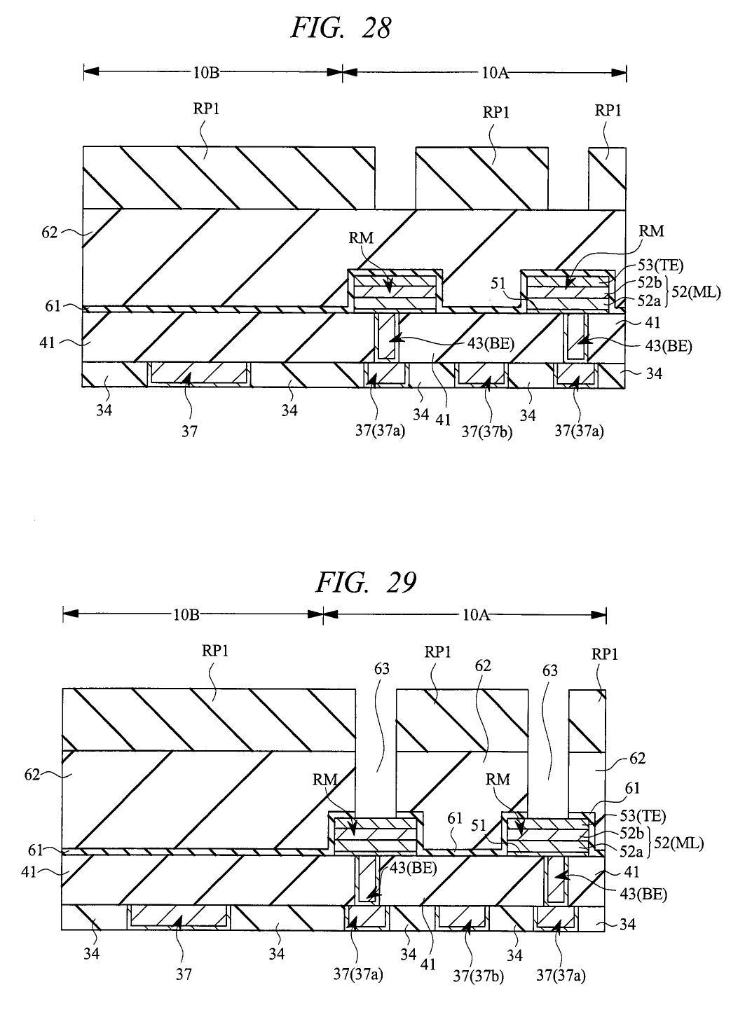

Next, as shown in FIG. 28, the insulating film (etching stopper film) 61 is formed on the insulating film 41 so as to cover the memory elements RM. Consequently, the state that the insulating film 61 is formed on the upper surface of the top electrode film 53, the sidewalls (side surfaces) of the memory layer 52, and the part of the insulating film 41 other than the region covered by the memory elements RM is attained.

As the insulating film 61, it is preferable to use a material film which can be formed at a temperature (for example, 400° C. or less) which does not make the memory layer 52 sublimated. For example, when a silicon nitride film is used as the insulating film 61, film formation can be carried out by the plasma CVD method or the like at a temperature (for example, 400° C. or less) which does not make the memory layer 52 sublimated; therefore, this case is more preferred, and sublimation of the memory layer 52 upon film formation of the insulating film 61 can be consequently prevented.

Next, the insulating film (interlayer insulating film) 62 is formed on the insulating film 61. Therefore, the insulating film 62 is formed on the insulating film 61 so as to cover the stacked pattern (memory elements RM) of the top electrode film 53, the memory layer 52, and the peeling prevention film 51. The insulating film 62 is thicker than the insulating film 61 and can function as an interlayer insulating film. After film formation of the insulating film 62, the upper surface of the insulating film 62 can be planarized by performing, for example, a CMP process, in accordance with needs.

Next, a photoresist pattern RP1 is formed on the insulating film 62 by using the photolithography method. The photoresist pattern RP1 has opening portions at the region where the through holes 63 will be formed.

Next, as shown in FIG. 29, the photoresist pattern RP1 is used as an etching mask, and the insulating film 62 is subjected to dry etching, thereby forming the through holes (opening portions, connection holes, penetrating holes) 63 in the insulating films 61 and 62.

In this case, first, under the conditions where the insulating film 62 (silicon oxide film) is more readily etched than the insulating film 61 (silicon nitride film) (in other words, the conditions where the etching speed (etch rate) of the insulating film 62 is higher than that of the insulating film 61), the insulating film 62 is dry-etched until the insulating film 61 is exposed, and the insulating film 61 is caused to function as an etching stopper film. The dry etching preferably uses the etching method having a selectivity of, for example, 10 or more in which the insulating film 62 formed of, for example, silicon oxide is etched, but the insulating film 61 serving as the etching stopper is not etched. At this point, although the insulating film 61 is exposed at the bottom of the through hole 63, the insulating film 61 functions as an etching stopper; therefore, etching is stopped in a state where the insulating film 61 is exposed at the bottom of the through hole 63, so that the top electrode film 53 of the memory element RM is not exposed. Then, dry etching is carried out under the condition that the insulating film 61 (silicon nitride film) is readily etched than the insulating film 62 (silicon oxide film) (condition that the etching speed of the insulating film 61 is higher than that of the insulating film 62), thereby dry-etching and removing the insulating film 61 exposed at the bottom of the through hole 63. Consequently, the through holes 63 can be formed in the insulating films 61 and 62, and at least part of the top electrode film 53 of the memory elements RM is exposed at the bottom of the through holes 63. The dry etching of the insulating film 62 and the insulating film 61 are preferably carried out by anisotropic dry etching. Then, the photoresist pattern RP1 is removed.

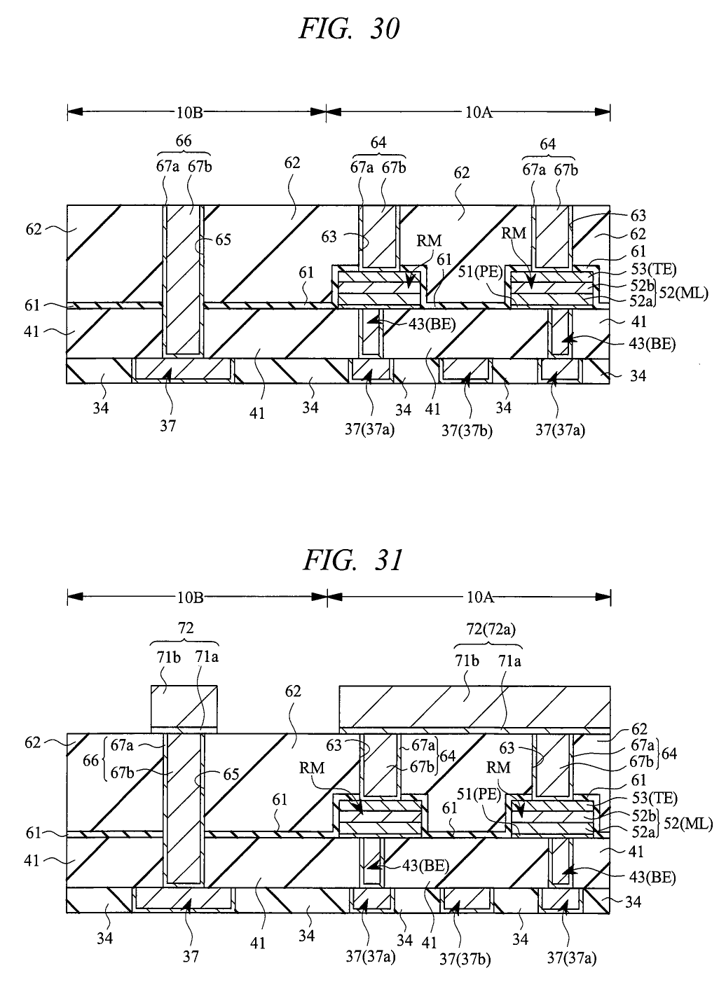

Next, as shown in FIG. 30, another photoresist pattern (not shown) formed on the insulating film 62 by using the photolithography method is used as an etching mask, and the insulating films 62, 61, and 41 are subjected to dry etching, thereby forming the through hole (opening portion, connection hole) 65 in the insulating films 62, 61, and 41. The through hole 65 is formed in the peripheral circuit region 10B, and the upper surface of the wiring 37 is exposed at the bottom thereof. Then, the photoresist pattern is removed. Note that, the above-described through holes 63 can be formed after forming the through holes 65. The through holes 63 and the through hole 65 are preferably formed in different steps; however, they can be formed in the same step.

Next, the plugs 64 and 66 are formed in the through holes 63 and 65. In this process, for example, the conductive barrier film 67a is formed by the sputtering method or the like on the insulating film 62 including the interior of the through holes 63 and 65, the main conductive film 67b which comprises, for example, a tungsten (W) film is then formed by the CVD method or the like on the conductive barrier film 67a so as to fill the through holes 63 and 65, and the unnecessary part of the main conductive film 67b and the conductive barrier film 67a on the insulating film 62 is removed by the CMP method, the etch back method, or the like. Consequently, the plug 64 which comprises the main conductive film 67b and the conductive barrier film 67a remaining and buried in the through hole 63 and the plug 66 which comprises the main conductive film 67b and the conductive barrier film 67a remaining and buried in the through hole 65 can be formed. As the main conductive film 67b, instead of the tungsten film, for example, an aluminum (Al) film or an aluminum alloy film (main conductive film) can be also used.

Next, as shown in FIG. 31, wiring (second layer wiring) 72 is formed as second layer wiring on the insulating film 62 in which the plugs 64 and 66 are buried. For example, on the insulating film 62 in which the plugs 64 and 66 are buried, the conductive barrier film 71a and the aluminum film or aluminum alloy film 71b are sequentially formed by the sputtering method or the like and patterned by using the photolithography method and the dry etching method or the like, thereby forming the wiring 72. The wiring 72 is not limited to the above-described aluminum wiring, but can be variously modified; and the wiring may be, for example, tungsten wiring or copper wiring (buried copper wiring).

Then, an insulating film (not shown) serving as an interlayer insulating film is formed on the insulating film 62 so as to cover the wiring 72, and wiring layers (wiring after the third wiring layer) and the like are further formed; meanwhile, the illustrations and descriptions thereof will be omitted here. Then, after annealing in hydrogen at about 400° C. to 450° C. is carried out in accordance with needs, the semiconductor device (semiconductor memory device) is completed.

In addition, in the present embodiment, the case where the first layer ML1 of the memory layer ML is at the bottom electrode BE side and the second layer ML2 is at the top electrode TE side has been described; however, as another mode, the memory layer ML may be formed upside-down so that the first layer ML1 of the memory layer ML is disposed at the top electrode TE side, and the second layer ML2 is disposed at the bottom electrode BE side. In this case, the direction of the reset voltage applied across the top electrode TE and the bottom electrode BE is required to be inverted to the above-described voltage, and the direction of the set voltage applied across the top electrode TE and the bottom electrode BE is required to be inverted to the above-described voltage. However, the appropriate direction of the set voltage more strongly depends on the direction of the voltage of the initialization (forming, initial resistance reducing process) than on the stacking order; therefore, the voltage is not always required to be inverted to carry out operations. Also, the structure of the entire memory element RM can be upside-down. The same also applies to the embodiments below.

Further, in the present embodiment, the conductive path CDP is controlled by generating a potential gradient in the memory layer ML by the top electrode TE and the bottom electrode BE; however, as another mode, a third electrode and a fourth electrode can be further provided in addition to the top electrode TE and the bottom electrode BE, and the potential gradient can be generated by the electrodes in the direction other than the vertical direction, thereby controlling the conductive path CDP more finely. The same also applies to the embodiments below.

Still further, in the present embodiment, the case where the planar sizes (planar shapes) of the layers (in the present embodiment, the first layer ML1 and the second layer ML) of the memory layer ML and the top electrode TE are same has been described; however, they are not limited to this case, and the planar sizes (planar shapes) of the layers (in the present embodiment, the first layer ML1 and the second layer ML2) of the memory layer ML and the top electrode TE may be different from one another. However, it is more preferred that the patterns having the same planar size (planar shape) are stacked to form the memory layer ML and the top electrode TE, since processing is easy. The same also applies to the embodiments below.

Moreover, in the present embodiment, compared with the planar size of the bottom electrode BE (plug 43), the planar sizes of the memory layer ML (52) and the top electrode TE (53) are larger. However, as another mode, the planar size of the memory layer ML (52) and the top electrode TE (53) may be made same as the planar size of the bottom electrode BE (plug 43) by, for example, making the stacked film of the memory layer ML (memory layer 52) and the top electrode TE (top electrode film 53) to be columnar or prismatic; and, in this case, the bottom electrode BE (plug 43), the memory layer ML (52), and the top electrode TE (53) are arranged to be overlapped with one another. The same also applies to the embodiments below.

### Second Embodiment

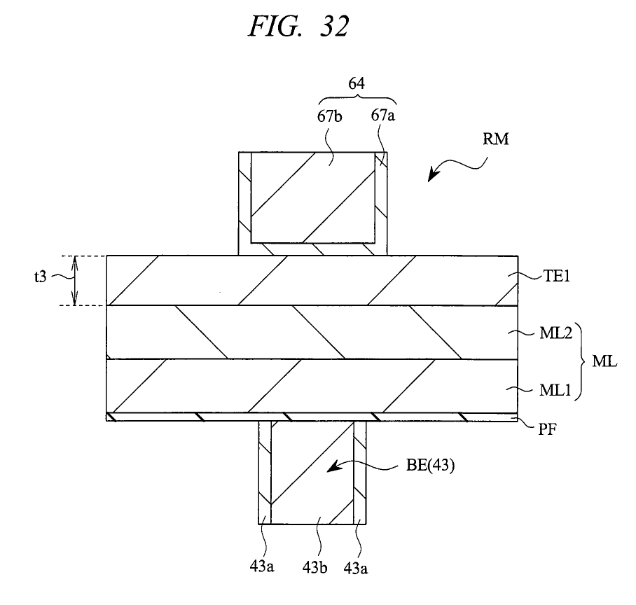

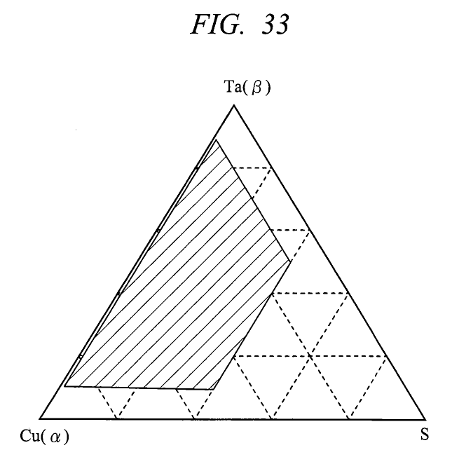

FIG. 32 is an explanatory diagram (cross sectional view) schematically showing a memory element RM in a semiconductor device according to the present embodiment and corresponds to FIG. 1 of the above-described first embodiment. FIG. 33 is an explanatory diagram (graph, triangular diagram, composition diagram) showing a desired composition range of the material forming a top electrode TE1 in the memory element RM of the present embodiment.

The memory element RM of the present embodiment shown in FIG. 32 has an approximately same constitution as the memory element RM of the above-described first embodiment except that the top electrode TE1 having a material different from that of the top electrode TE is used instead of the top electrode TE; therefore, the explanations thereof will be omitted herein except for some descriptions about the material of the top electrode TE1.

In the memory element RM of the present embodiment, the top electrode TE1 also has a function as an ion feeding layer. Therefore, the top electrode TE1 comprises a material containing: as main components, at least one element selected from a group (first element group) of Cu (copper), Ag (silver), Au (gold), Al (aluminum), Zn (zinc), and Cd (cadmium); at least one element selected from a group (second element group) of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements; and at least one element selected from a group (this group will be referred to as a fourth element group) consisting of O (oxygen), S (sulfur), Se (selenium), and Te (tellurium).

Note that, hereinafter, for simplification, the above-described group of O (oxygen), S (sulfur), Se (selenium), and Te (tellurium) will be referred to as a fourth element group. The fourth element group is the group of the third element group to which O (oxygen) is added.

As a result of forming the top electrode TE1 by such materials, when a higher voltage is applied to the bottom electrode BE side than that to the top electrode TE1, the element(s) (element(s) α) that contributes to the above-described conductive path CDP formation is fed from the top electrode TE1 into the memory layer ML (second layer ML2). Therefore, in the present embodiment, in the memory layer ML, the metal atoms or metal ions (element(s) α) sufficient for forming the conductive path CDP so as to connect the top electrode TE1 and the bottom electrode BE to each other can be ensured, and deficiency of the element(s) (herein, the element(s) α) that contributes to the above-described conductive path CDP formation in the memory layer ML can be prevented. Therefore, insufficient formation of the conductive path CDP which causes a high resistance upon setting can be prevented, and stability of the set state (low-resistance state) can be enhanced.

On the other hand, in the first embodiment, the top electrode TE comprises the element(s) that does not readily diffuse into the memory layer ML (second layer ML2) adjacent thereto; therefore, excessive feeding of the metal element(s) or metal ions from the top electrode TE into the memory layer ML (second layer ML2) can be prevented. Therefore, the disconnection of the conductive path CDP between the top electrode TE and the bottom electrode BE upon resetting can be prevented from becoming insufficient which causes low resistance, the stability of the reset state (high-resistance state) can be enhanced, and the rewrite ability can be improved.

A desired composition of the top electrode TE1 in the present embodiment will be described below. Specifically, the top electrode TE1 preferably comprises a material containing 9 at. % or more and 90 at. % or less of at least one element (element α) selected from the group (first element group) of Cu (copper), Ag (silver), Au (gold), Al (aluminum), Zn (zinc), and Cd (cadmium); 9 at. % or more and 90 at. % or less of at least one element (element β) selected from the group (second element group) consisting of V (vanadium), Nb (niobium), Ta (tantalum), Cr (chromium), Mo (molybdenum), W (tungsten), Ti (titanium), Zr (zirconium), Hf (hafnium), Fe (iron), Co (cobalt), Ni (nickel), Pt (platinum), Pd (palladium), Rh (rhodium), Ir (iridium), Ru (ruthenium), Os (osmium), and lanthanoid elements; and 1 at. % or more and 40 at. % or less of at least one element selected from the group (fourth element group) consisting of O (oxygen), S (sulfur), Se (selenium), and Te (tellurium). The top electrode TE1 may contain 10 at. % or less of other elements (elements other than those of the first element group, the second element group, and the fourth element group).

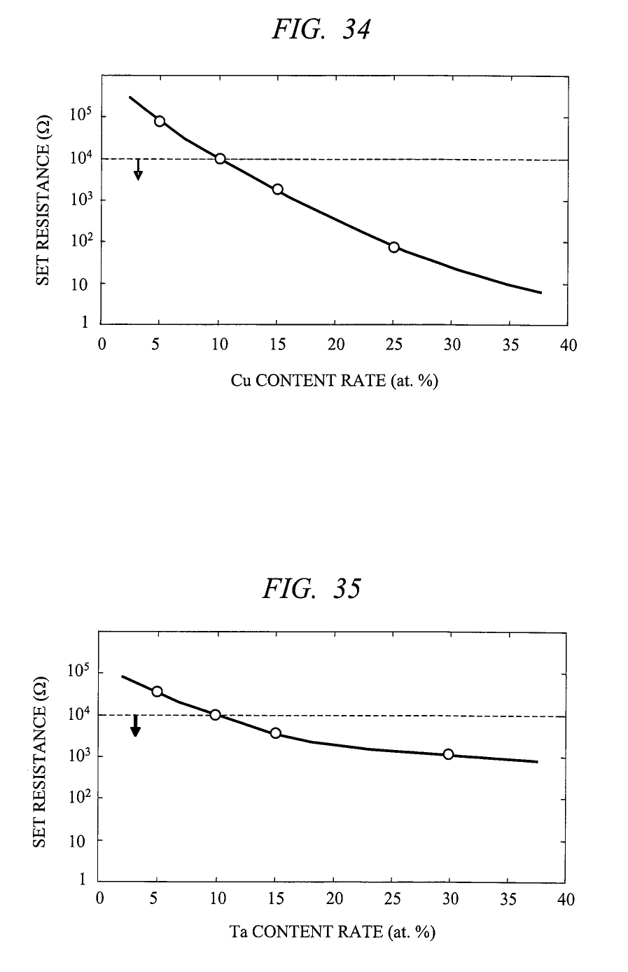

Typical examples of composition dependences of the characteristics of the memory elements studied by the inventors of the present invention are shown in FIG. 34 to FIG. 37. Among these, FIG. 34 to FIG. 36 are graphs showing a composition dependence of the set resistance, and FIG. 37 is a graph showing a composition dependence of the number of rewritable times.

Note that, the set resistance of the vertical axes of the graphs of FIG. 34 to FIG. 36 correspond to the resistance (electrical resistance) between the top electrode TE1 and the bottom electrode BE of the case where the above-described conductive path CDP is present (the above-described set state of FIG. 2).

Also, the number of rewritable times of the vertical axis of the graph of FIG. 37 corresponds to the number of rewritable times of the memory element RM; and, within the number of rewritable times, the memory element RM can be rewritten without causing defective rewriting. The larger the number of rewritable times becomes, the higher the rewriting performance (rewriting reliability) of the memory element RM is.

With reference to the graphs of FIG. 34 to FIG. 37, preferred compositions of the top electrode TE1 will be described. Note that, in FIG. 34 to FIG. 37, the composition of the first layer ML1 of the memory layer ML is fixed to Cu_{0.5}Ta_{0.15}S_{0.35}, the composition of the second layer ML2 is fixed to Cu_{0.25}Ta_{0.25}O_{0.5}, and the content rates of the elements in the composition of the top electrode TE1 are varied while using Cu_{0.4}Ta_{0.4}S_{0.2} as a base composition. The set resistance and the number of rewritable times are measured when the film thicknesses of the top electrode TE1, the first layer ML1, and the second layer ML2 are 100 nm, 30 nm, and 30 nm, respectively.

FIG. 34 is the graph showing a dependence of the set resistance with respect to the Cu content rate in the top electrode TE1, wherein the horizontal axis of the graph corresponds to Cu (copper) content rate in the top electrode TE1, and the vertical axis of the graph corresponds to set resistance. In the case of the graph of FIG. 34, the atomic ratio (ratio of the number of atoms) of Ta (tantalum) and S (sulfur) in the top electrode TE1 is fixed to 40:20, and the content rate of Cu (copper) in the top electrode TE1 is varied.

As shown in FIG. 34, when the content rate of Cu (copper) in the top electrode TE1 is too low, the set resistance which should be a low resistance becomes too high; and, when it is less than 9 at. %, setting becomes insufficient. Although it is not shown in the graph, when the content rate (atomic ratio) of Cu (copper) in the top electrode TE1 is higher than 90 at. %, a problem occurs that the number of rewritable times is reduced due to downward diffusion of Cu. Therefore, the content rate (atomic ratio) of Cu (copper) of the top electrode TE1 is preferably equal to or more than 9 at. % and equal to or less than 90 at. %. Consequently, the above-described problem is solved, and operations as a non-volatile memory element can be appropriately performed.

FIG. 35 is a graph showing a dependence of the set resistance with respect to the Ta content rate in the top electrode TE1, where the horizontal axis of the graph corresponds to the content rate of Ta (tantalum) in the top electrode TE1, and the vertical axis of the graph corresponds to the set resistance. In the case of the graph of FIG. 35, the atomic ratio (ratio of the number of atoms) of Cu (copper) and S (sulfur) in the top electrode TE1 is fixed to 40:20, and the content rate of Ta (tantalum) in the top electrode TE1 is varied.

As shown in FIG. 35, when the content rate of Ta (tantalum) in the top electrode TE1 is too low, the set resistance which should be a low resistance becomes too high; and, when it is less than 9 at. %, setting becomes insufficient. Although it is not shown in the graph, when the content rate (atomic ratio) of Ta (tantalum) in the top electrode TE1 is higher than 90 at. %, a problem that Ta readily diffuses into the adjacent layer occurs. Therefore, the content rate (atomic ratio) of Ta (tantalum) of the top electrode TE1 is preferably equal to or more than 9 at. % and equal to or less than 90 at. %. Consequently, the above-described problem is solved, and operations as a non-volatile memory element can be appropriately performed.

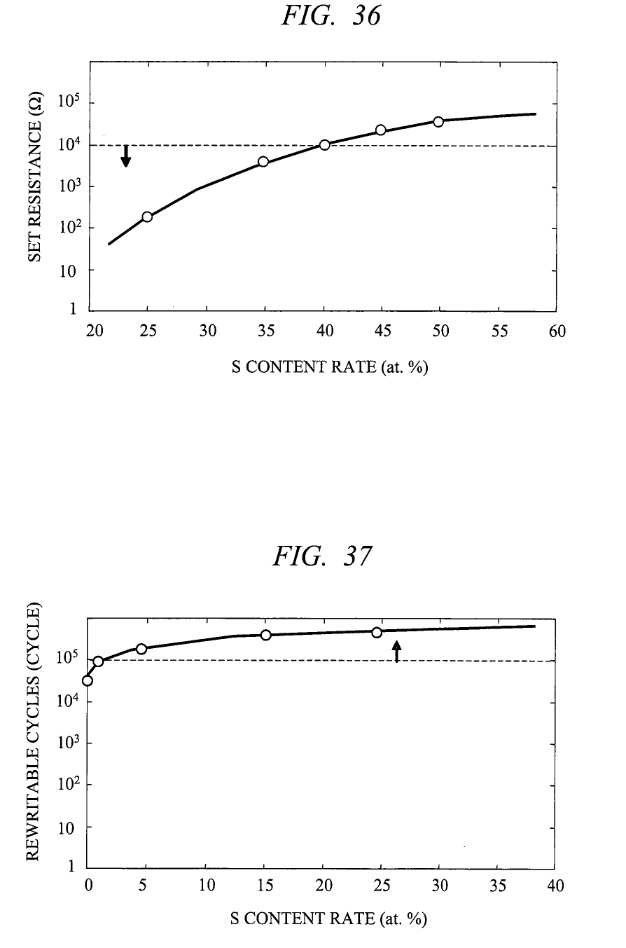

FIG. 36 is a graph showing a dependence of the set resistance with respect to S content rate in the top electrode TE1, where the horizontal axis of the graph corresponds to the content rate of S (sulfur) in the top electrode TE1, and the vertical axis of the graph corresponds to the set resistance. FIG. 37 is a graph showing a dependence of the number of rewritable times with respect to the S content rate in the top electrode TE1, where the horizontal axis of the graph corresponds to the content rate of S (sulfur) in the top electrode TE1, and the vertical axis of the graph corresponds to the number of rewritable times. In the case of the graphs of FIG. 36 and FIG. 37, the atomic ratio (ratio of the number of atoms) of Cu (copper) and Ta (tantalum) in the top electrode TE1 is fixed to 40:40, and the content rate of S (sulfur) in the top electrode TE1 is varied.

As shown in FIG. 36, when the content rate of S (sulfur) in the top electrode TE1 is too high, the set resistance which should be a low resistance becomes too high. As shown in FIG. 37, when the content rate of S (sulfur) in the top electrode TE1 is too low, the number of rewritable times becomes too small. Specifically, when the content rate (atomic ratio) of S (sulfur) in the top electrode TE1 is higher than 40 at. %, setting becomes insufficient; and, when the content rate (atomic ratio) of S (sulfur) in the top electrode TE1 is lower than 1 at. %, the number of rewritable times becomes small because diffusion of the metal element(s) in the top electrode TE1 into the memory layer ML is too quick. Therefore, the content rate (atomic ratio) of S (sulfur) of the top electrode TE1 is preferably equal to or more than 1 at. % and equal to or less than 40 at. %. Consequently, the above-described problems are solved, and operations as a non-volatile memory element can be appropriately performed.

Therefore, in consideration of the composition dependences of FIG. 34 to FIG. 37 etc., in a desired composition of the top electrode TE1 in the case where copper (Cu), tantalum (Ta), and sulfur (S) are contained, the content rate of copper (Cu) is equal to or more than 9 at. % and equal to or less than 90 at. %, the content rate of tantalum (Ta) is equal to or more than 9 at. % and equal to or less than 90 at. %, and the content rate of sulfur (S) is equal to or more than 1 at. % and equal to or less than 40 at. %. In this case, the composition of the material forming the top electrode TE1 (average composition of the top electrode TE1 in the film thickness direction) can be expressed by the following composition formula, Cu_{X}Ta_{Y}S_{Z}, where 0.09≦X≦0.9, 0.09≦Y≦0.9, and 0.01≦Z≦0.4.

Such a desired composition range of the top electrode TE1 corresponds to the composition range hatched in above-described FIG. 33.

Further, in FIG. 34 to FIG. 37 etc., the material constituting the top electrode TE1 is the Cu—Ta—S-based material. However, according to the study (experiments) made the inventors of the present invention, it has been found out that a similar inclination as the composition dependences of above-described FIG. 34 to FIG. 37 etc. can be obtained even when the element(s) (element(s) α) of the first element group other than Cu is used, the element(s) other than Ta which belongs to the second element group is used, and the element(s) other than S which belongs to the fourth element group is used.

Therefore, the top electrode TE1 preferably comprises the material which contains: 9 at. % or more and 90 at. % or less of at least one element selected from the first element group; 9 at. % or more and 90 at. % or less of at least one element selected from the second element group; and 1 at. % or more and 40 at. % or less of at least one element selected from the fourth element group.

In other words, the composition of the top electrode TE1 is preferably the composition expressed by a composition formula α_{X}β_{Y}δ_{Z}, where 0.09≦X≦0.9, 0.09≦Y≦0.9, 0.01≦Z≦0.4, and X+Y+Z=1. Herein, in the composition formula α_{X}β_{Y}δ_{Z} of the top electrode TE1, α is at least one element selected from the first element group, β is at least one element selected from the second element group, and δ is at least one element selected from the fourth element group. Note that, the composition α_{X}β_{Y}δ_{Z} of the top electrode TE1 shown herein is expressed by an average composition in the film thickness direction of the top electrode TE1.

More preferably, the element(s) which is contained by the top electrode TE1 and belongs to the first element group is same as the element which is contained by the first layer ML1 of the memory layer ML and belongs to the first element group. For example, when the element which is contained by the first layer ML1 and belongs to the first element group is Cu, the element contained by the top electrode TE1 and belongs to the first element group is also preferred to be Cu. Consequently, the element(s) (element(s) α) that contributes to the formation of the conductive path CDP can be appropriately fed from the top electrode TE1 into the memory layer ML.

Also, more preferably, the element(s) which is contained by the top electrode TE1 and belongs to the second element group is same as the element(s) which is contained by the first layer ML1 of the memory layer ML and belongs to the second element group. Consequently, there are advantages that the element(s) of the second element group readily contributes to the formation of the conductive path CDP, and characteristics are not readily changed by rewrite.

When the top electrode TE1 has such a composition, the performance of the semiconductor device capable of storing information can be improved. Moreover, the semiconductor device which consumes low power and has stable data rewrite characteristics can be realized.

In addition, a thickness t3 of the top electrode TE1 is preferably in the range of 15 to 100 nm, particularly preferably, 25 to 60 nm. Consequently, since voltage drop does not readily occur in the top electrode, the effects that low-voltage drive can be performed and exfoliation due to stress does not readily occur can be obtained.

Further, when the top electrode TE1 does not contain at least either one of the element which belongs to the second element group and the element which belongs to the fourth element group, although the performance is lowered, it can be used in some cases depending on the use.

Moreover, to prevent the element(s) (element(s) α) which contributes to the formation of the conductive path CDP in the memory layer ML from becoming deficient, the top electrode TE1 is preferred to have the composition described in the present embodiment. However, although the effects are reduced, as another mode, the top electrode TE1 may be an alloy or a single-substance metal of the element(s) (element(s) α) which contributes to the formation of the conductive path CDP. Meanwhile, when the top electrode TE1 is a single-substance metal of the element α, a problem that the concentration (contained amount) of the metal element (element α) fed from the top electrode TE1 gradually increases in the solid electrolyte layer (first layer ML1) may occur. Therefore, the alloy is preferred than the single-substance metal as the top electrode TE1. When the alloy of the element(s) α is used, the counterpart element (the metal element which is contained in the top electrode TE1 in addition to the element(s) α so as to form the alloy) is preferred to be an element which does not readily diffuse into the second layer ML2 (for example, W, Mo, Ta, Pt, Pd, Rh, Ir, Ru, Os, Ti).

### Third Embodiment

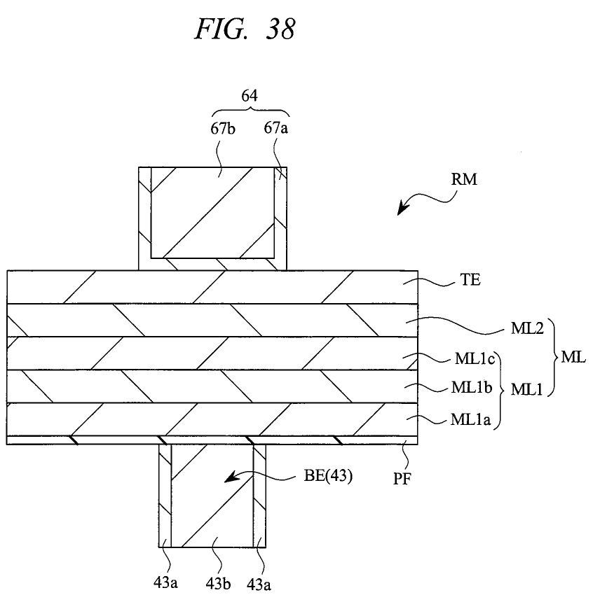

FIG. 38 is an explanatory diagram (cross sectional view) schematically showing a memory element RM in a semiconductor device according to the present embodiment and corresponds to FIG. 1 of the above-described first embodiment.

The memory element RM of the present embodiment shown in FIG. 38 has an approximately same constitution as the memory element RM of the first embodiment except that the first layer ML1 of the memory layer ML has a stacked structure of a plurality of layers having mutually different compositions. Therefore, except for a description about the first layer ML1 of the memory layer ML, descriptions thereof will be omitted.

In the first embodiment, the first layer ML1 of the memory layer ML has a single-layer structure. However, in the present embodiment, as shown in FIG. 38, the first layer ML1 of the memory layer ML is formed by a plurality of layers (chalcogenide layers) having mutually different compositions. In FIG. 38 and in the description below, the case where the first layer ML1 of the memory layer ML is formed by three layers (chalcogenide layers ML1a, ML1b, and ML1c) having mutually different compositions will be mainly described. However, the number of the layers constituting the first layer ML1 is not limited to three, and it goes without saying that the first layer ML1 of the memory layer ML can be formed by an arbitrary number of layers equal to or more than two layers. The first layer ML1 can be considered to be a chalcogenide layer since the layer contains a chalcogen element(s) (S, Se, Te). The plurality of layers having mutually different compositions which constitute the first layer ML1 also contain the chalcogen element(s) (S, Se, Te); therefore, the layers will be referred to as chalcogenide layers (herein, chalcogenide layers ML1a, ML1b, and ML1c).

As shown in FIG. 38, in the present embodiment, the first layer ML1 has the stacked structure of the chalcogenide layer ML1a, the chalcogenide layer ML1b on the chalcogenide layer ML1a, and the chalcogenide layer ML1c on the chalcogenide layer ML1b. Therefore, the memory layer ML of the present embodiment has a stacked structure of the chalcogenide layer ML1a, the chalcogenide layer ML1b on the chalcogenide layer ML1a, the chalcogenide layer ML1c on the chalcogenide layer ML1b, and the second layer ML2 on the chalcogenide layer ML1c.

As well as the above-described first embodiment, also in the present embodiment, each of the layers (herein, the chalcogenide layers ML1a, ML1b, and ML1c) configuring the first layer ML1 having the multilayer structure (plural-layer structure, stacked structure) comprises a material containing: preferably 20 at. % or more and 70 at. % or less of at least one element selected from the first element group; preferably 3 at. % or more and 40 at. % or less of at least one element selected from the second element group; and preferably 20 at. % or more and 60 at. % or less of at least one element selected from the third element group. Each of the layers (herein, the chalcogenide layers ML1a, ML1b, and ML1c) configuring the first layer ML1 may contain 10 at. % or less of the elements other than the above-described elements (elements other than those of the above-described first element group, the second element group, and the third element group). The first element group, the second element group, and the third element group are those described in the first embodiment.

In other words, in the present embodiment, each of the layers (herein, each of the chalcogenide layers ML1a, ML1b, and ML1c) constituting the first layer ML1 of the multilayer structure preferably has a composition expressed by a composition formula α_{X}β_{Y}γ_{Z}, where 0.2≦X≦0.7, 0.03≦Y≦0.4, 0.2≦Z≦0.6, and X+Y+Z=1. Note that, α, β, and γ in the above-described composition formula α_{X}β_{Y}γ_{Z} are same as those described in the first embodiment for the composition formula α_{X}β_{Y}γ_{Z} of the first layer ML1 of the memory layer ML; therefore, the description thereof will be omitted here. The above-described composition α_{X}β_{Y}γ_{Z} of each of the layers (herein, each of the chalcogenide layers ML1a, ML1b, and ML1c) configuring the first layer ML1 having the multilayer structure shown herein is expressed by an average composition of each of the layers (herein, each of the chalcogenide layers ML1a, ML1b, and ML1c) in the film thickness direction.

However, each of the layers (herein, the chalcogenide layers ML1a, ML1b, and ML1c) constituting the first layer ML1 having the multilayer structure does not have the same composition, but have mutually different compositions.

Meanwhile, the element(s) which is contained by each of the layers (herein, each of the chalcogenide layers ML1a, ML1b, and ML1c) configuring the first layer ML1 having the multilayer structure and belongs to the first element group is preferably the same in the layers. For example, when the element which is contained by the chalcogenide layer ML1a and belongs to the first element group is Cu, the element which is contained by the chalcogenide layer ML1b and belongs to the first element group is also preferred to be Cu, and the element which is contained by the chalcogenide layer ML1c and belongs to the first element group is also preferred to be Cu. Consequently, the conductive path can be more appropriately formed in the memory layer ML.

Further, more preferably, the element(s) which is contained by each of the layers (herein, each of the chalcogenide layers ML1a, ML1b, and ML1c) configuring the first layer ML1 having the multilayer structure and belongs to the second element group is same in the layers. Consequently, there is an advantage that the characteristics are not readily changed even when rewrite is repeated many times.

In the present embodiment, the first layer ML1 of the memory layer ML is formed by the plurality of layers (herein, the chalcogenide layers ML1a, ML1b, and ML1c), and the manner of containing the element(s) of the third element group in the plurality of layers (herein, the chalcogenide layers ML1a, ML1b, and ML1c) forming the first layer ML1 is characteristic. Specifically, in the present embodiment, in the plurality of layers (herein, the chalcogenide layers ML1a, ML1b, and ML1c) constituting the first layer ML1, the more distant the layer is from the second layer ML, the larger the content amount of the element having the largest atomic number among the contained element(s) of the third element group is, or the larger the atomic number of the contained element(s) of the third element group is. The manner of containing the third element group will be described in more detail.

In the case where the first layer ML1 of the memory layer ML has a multilayer structure of n layers like the present embodiment, when the layers are a first layer to a n-th layer sequentially from the side close to the second layer ML2 (herein, the layer adjacent to the second layer ML2 is the first layer, and the layer adjacent to the bottom electrode BE or the peeling prevention film is the n-th layer), the relation of the compositions of a m-th layer and a (m+1)-th layer as described below (herein, each of above-described n and m is an integer equal to or more than 2, and m≦n−1). The m-th layer and the (m+1)-th layer are adjacent to each other, the side close to the second layer ML2 is the m-th layer, and the side close to the bottom electrode BE is the (m+1)-th layer.

Specifically, compared with the content rate of a first element, which is contained in the m-th layer and has the largest atomic number among the elements belong to the third element group (that is, S, Se, and Te), in the m-th layer, the content rate of the first element in the (m+1)-th layer is higher, or the (m+1)-th layer contains a second element, which has an atomic number larger than that of the first element and belongs to the third element group (that is, S, Se, and Te).

This means that, for example, when the m-th layer contains 30 at. % of S (sulfur) and does not contain Se (selenium) and Te (tellurium) (in this case, S is considered to be the first element), the (m+1)-th layer contains more than 30 at. % (that is, the S content rate of the m-th layer) of S (sulfur), or the (m+1)-th layer contains Se or Te (that is, the element of the third group having a larger atomic number than that of S contained in the m-th layer). Also, this means that, for example, when the m-th layer contains 25 at. % of Se (selenium) and 20 at. % of S (sulfur) and does not contain Te (tellurium) (in this case, Se having a larger atomic number among Se and S is considered to be the first element), the (m+1)-th layer contains 25 at. % (that is, the Se content rate of the m-th layer) or more of Se, or the (m+1)-th layer contains Te (that is, the element of the third element group having a larger atomic number than Se and S contained in the m-th layer). Alternatively, this means that, when the m-th layer contains 23 at. % of Te (tellurium) and 27 at. % of S (sulfur) and does not contain Se (selenium) (in this case, Te having a larger atomic number among Te and S is considered to be the first element), the (m+1)-th layer contains more than 23 at. % (that is, the Te content rate of the m-th layer) of Te (there is no element of the third element group that has a larger atomic number than Te).

Further, in the case where n=3, and the first layer ML1 has a three-layer structure, a first layer corresponds to the chalcogenide layer ML1c, a second layer corresponds to the chalcogenide layer ML1b, and the third layer corresponds to the chalcogenide layer ML1a. Therefore, when the first layer ML1 of the memory layer ML has a stacked structure of the chalcogenide layer ML1a, the chalcogenide layer ML1b, and the chalcogenide layer ML1c sequentially from the bottom electrode BE side (in other words, when the first layer ML1 of the memory layer ML has a stacked structure of the chalcogenide layer ML1c, the chalcogenide layer ML1b, and the chalcogenide layer ML1a sequentially from the second layer ML2 side), the chalcogenide layers ML1a, ML1b, and ML1c contain the elements of the third element group in the following manner.

Specifically, compared with the content rate of the element, which is contained in the chalcogenide layer ML1c and has the largest atomic number among the elements belonging to the third element group, in the chalcogenide layer ML1c, the content rate of the element (that is, the element which is contained in the chalcogenide layer ML1c and has the largest atomic number among the third element group) is larger in the chalcogenide layer ML1b, or the chalcogenide layer ML1b contains an element which has a larger atomic number than the element (that is, the element which is contained in the chalcogenide layer ML1c and has the largest atomic number among the elements of the third element group) and belongs to the third element group. Furthermore, compared with the content rate of the element, which is contained in the chalcogenide layer ML1b and has the largest atomic number among the elements belonging to the third element group, in the chalcogenide layer ML1b, the content rate of the element (that is, the element which is contained in the chalcogenide layer ML1b and has the largest atomic number among the elements of the third element group) in the chalcogenide layer ML1a is higher, or the chalcogenide layer ML1a contains an element which has a further larger atomic number than the element (that is, the element which is contained in the chalcogenide layer ML1b and has the largest atomic number among the elements of the third element group) and belongs to the third element group.

As described above, in the present embodiment, in the manner of containing the elements of the third element group in the plurality of layers (herein, the chalcogenide layers ML1a, ML1b, and ML1c) constituting the first layer ML1, it is made so that the more distant the layer is from the second layer ML2 (that is, the layer close to the bottom electrode BE), the larger the contained amount of the element having the largest atomic number among the contained elements of the third element group is, or the larger the atomic number of the contained element of the third element group is. Consequently, the layers (chalcogenide layers ML1a, ML1b, and ML1c) configuring the first layer ML1 are caused to have different mobility of the element(s) (herein, the element(s) α) which contributes to the conductive path CDP formation.

Specifically, in the first layer ML1 having a multilayer structure of n layers, between the mutually adjacent m-th layer and (m+1)-th layer, the mobility of the element(s) (element(s) α) which contributes to the conductive path CDP formation is higher in the (m+1)-th layer arranged more distant from the second layer ML2 than the m-th layer arranged closer to the second layer ML2. In the chalcogenide layers ML1a, ML1b, and ML1c, the mobility of the element(s) (element(s) α) which contributes to the conductive path CDP formation is higher in the chalcogenide layer ML1b than in the chalcogenide layer ML1c which is the closest to the second layer ML2; and, the mobility of the element(s) (element(s) α) which contributes to the conductive path CDP formation is higher in the chalcogenide layer ML1a than in the chalcogenide layer ML1b.

As described in the first embodiment above, this is for the reason that, among the elements that belong to the 16 (VIB) group of the periodic table, the size of the ions (ion radius) becomes larger in the order of oxygen (O), sulfur (S), selenium (Se), and tellurium (Te), and the larger the contained amount of the element having the larger ion size, the higher the mobility of the element(s) (herein, the element(s) α) which contributes to the conductive path CDP formation become. Specifically, in the plurality of layers (chalcogenide layers ML1a, ML1b, and ML1c) configuring the first layer ML1, the more distant the layer (chalcogenide layer) is from the second layer ML2, the larger the contained amount of the element having the largest atomic number among the contained elements of the third element group is; therefore, the contained amount of the element having a large ion size becomes large, or, since the element of the third element group having a larger atomic number is contained, larger ions are contained. Consequently, in the plurality of layers (chalcogenide layers ML1a, ML1b, and ML1c) constituting the first layer ML1, the more distant the layer is from the second layer (that is, the layer close to the bottom electrode BE), the more readily the element(s) (herein, the element(s) α) which contributes to the conductive path CDP formation moves, and the mobility is increased.

The formation of the conductive path CDP in the memory layer ML of the memory element RM of the present embodiment will be described in more detail.

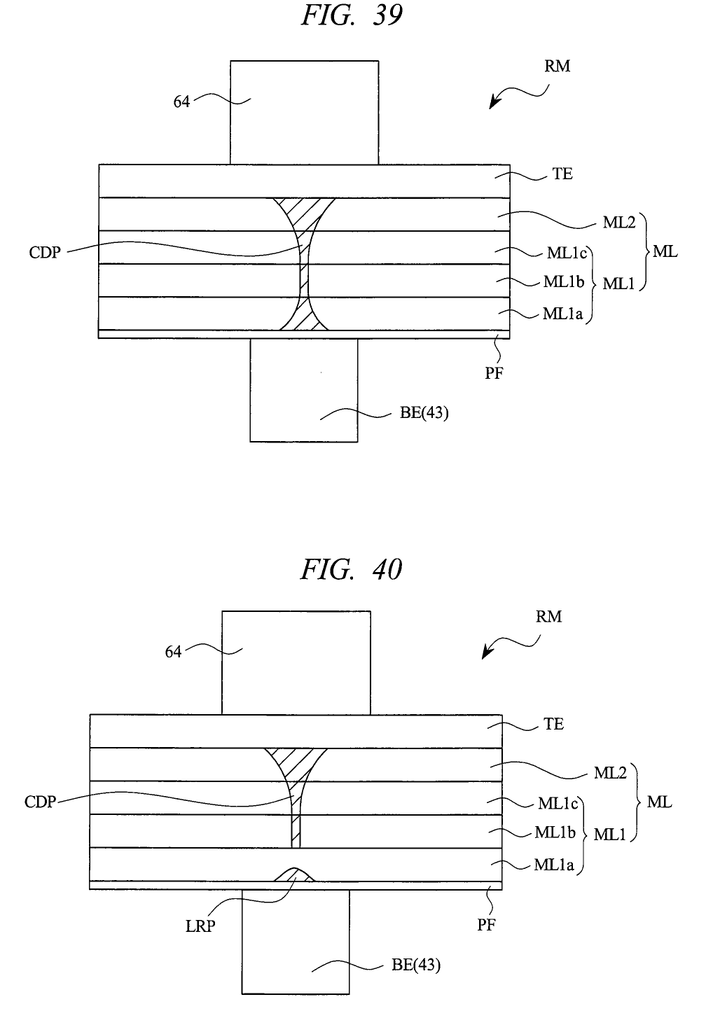

FIG. 39 is an explanatory diagram (cross sectional view) schematically showing the memory element RM in the state where the conductive path CDP is formed so as to connect the bottom electrode BE and the top electrode TE to each other (set state, ON state) and corresponds to FIG. 2 of the first embodiment. FIG. 40 to FIG. 42 are explanatory diagrams (cross sectional views) schematically showing the memory element RM in the state where the conductive path CDP is disconnected between the bottom electrode BE and the top electrode TE (reset state, OFF state) in the memory layer ML and correspond to FIG. 3 of the above-described first embodiment. FIG. 39 to FIG. 42 are same cross sectional view as above-described FIG. 38; however, in order to facilitate viewability of the drawings, merely the region which has a low resistivity in the memory layer ML, that is, the region which serves as the conductive path CDP and the low-resistance part LRP is hatched, and hatching of the other part than that is omitted.

Also in the memory element RM of the present embodiment, when initialization voltages similar to that described in the first embodiment are applied, as shown in FIG. 39, the conductive path CDP in which metal ions are present at a high concentration is formed in the memory layer ML so as to connect the bottom electrode BE and the top electrode TE to each other. In FIG. 39, since the conductive path CDP is formed so as to connect (couple) the bottom electrode BE and the top electrode TE to each other in the memory layer ML, the resistance of the memory layer ML becomes low, and the resistance of the memory element RM becomes low (in other words, the set state is attained).

When the reset voltage is applied in the state (set state) in which the conductive path CDP is formed so as to connect the bottom electrode BE and the top electrode TE to each other in the memory layer ML as shown in FIG. 39, the conductive path CDP connecting the bottom electrode BE and the top electrode TE to each other can be disconnected in the memory layer ML as shown in FIG. 40 to FIG. 42.

For example, the bottom electrode BE is caused to have a positive electric potential and the top electrode TE is caused to have a negative electric potential, thereby applying a reset voltage which causes the electric potential of the bottom electrode BE to be higher than that of the top electrode TE across the top electrode TE and the bottom electrode BE (that is, across the plug 64 and the bottom electrode BE).

The element(s) α forming the conductive path CDP in the first layer ML1 of the memory layer ML gets to move toward the top electrode TE side which is the negative electric potential side by the reset voltage. However, in the present embodiment, as described above, the mobility of the element(s) (herein, the element(s) α) which contributes to the formation of the conductive path CDP is made different among the chalcogenide layers ML1a, ML1b, and ML1c.

Therefore, if the reset voltage has a voltage value that is sufficient to cause the element(s) α to move in the chalcogenide layers ML1a, ML1b, and ML1c, the element(s) α forming the conductive path CDP in the chalcogenide layers ML1a, ML1b, and ML1c moves toward the top electrode TE side and is kept in the second layer ML2. Meanwhile, as described above in the first embodiment, the mobility of the element(s) α is low in the second layer ML2 compared with in the first layer ML1; therefore, even when the reset voltage is applied, the element(s) α hardly moves in the second layer ML2. Therefore, when the reset voltage is applied, the state as shown in FIG. 42 is attained in which the conductive path CDP in the second layer ML2 is hardly changed, on the other hand, the conductive path CDP is disconnected in the chalcogenide layers ML1a, ML1b, and ML1c in the first layer ML1 (the state where the conductive path CDP is not formed). Therefore, the resistance of the memory layer ML becomes high, and the resistance of the memory element RM becomes high.

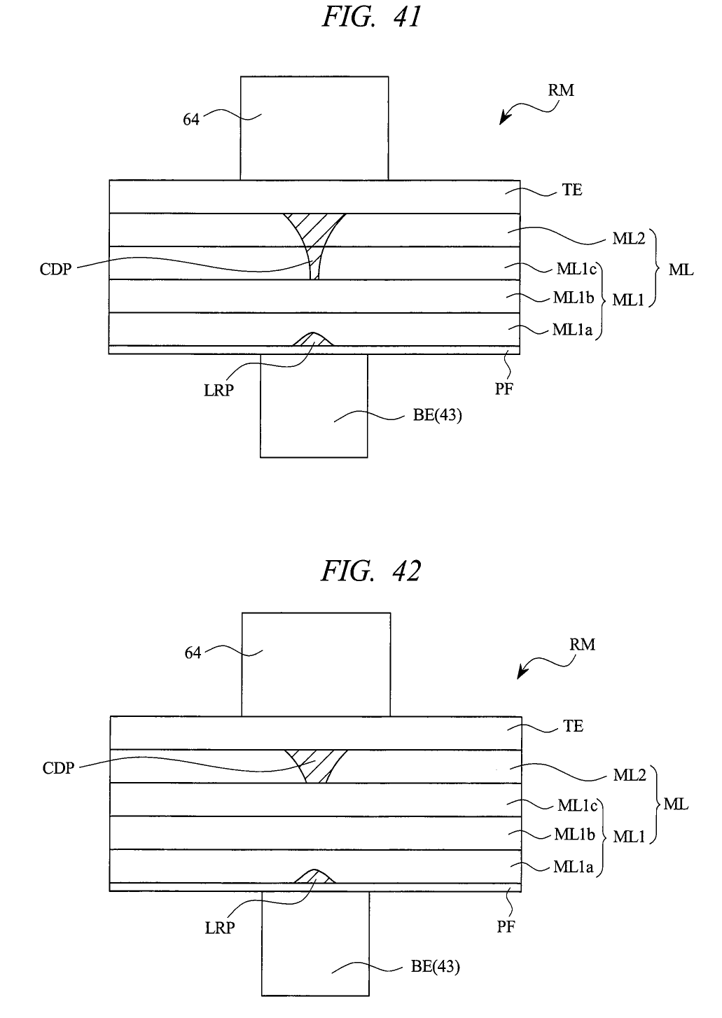

Meanwhile, by utilizing the difference of the mobility of the chalcogenide layers ML1a, ML1b, and ML1c, the reset voltage moves the element(s) α in the chalcogenide layers ML1a and ML1b; however, if the voltage value is a value which only let the element(s) α move very little in the chalcogenide layer ML1c, the element(s) α forming the conductive path CDP in the chalcogenide layers ML1a and ML1b is moved toward the top electrode TE side and kept in the chalcogenide layer ML1c. However, since the mobility of the element(s) α is low in the chalcogenide layer ML1c and the second layer ML2 compared with the chalcogenide layers ML1a and ML1b, the element(s) α therein hardly moves even when the reset voltage is applied. Therefore, when the reset voltage is applied, the state as shown in FIG. 41 is attained, where the conductive path CDP in the chalcogenide layer ML1c and the second layer ML2 is hardly changed, on the other hand, the conductive path CDP is disconnected in the chalcogenide layers ML1a and ML1b (the state where the conductive path CDP is not formed).

By utilizing the difference in the mobility of the chalcogenide layers ML1a, ML1b, and ML1c, the reset voltage let the element(s) α move in the chalcogenide layer ML1a; however, if the voltage value is a value which hardly moves the element(s) α in the chalcogenide layers ML1b and ML1c, the element(s) α forming the conductive path CDP in the chalcogenide layer ML1a is moved toward the top electrode TE side and kept in the chalcogenide layer ML1b. However, since the mobility of the element(s) α is small in the chalcogenide layers ML1b and ML1c and the second layer ML2 compared with the chalcogenide layer ML1a, the element(s) α hardly moves even when the reset voltage is applied. Therefore, when the reset voltage is applied, the state as shown in FIG. 40 is attained where the conductive path CDP in the chalcogenide layers ML1b and ML1c and the second layer ML2 hardly changes, on the other hand, the conductive path CDP is disconnected in the chalcogenide layer ML1a (the state in which the conductive path CDP is not formed).

The reset operation utilizing the above-described difference in the mobility of the chalcogenide layers ML1a, ML1b, and ML1c can be carried out, for example, by setting the reset voltage for attaining the state of FIG. 40 to be smaller (the absolute value is smaller) than the reset voltage for attaining the state of FIG. 41, and alternatively, setting the reset voltage for attaining the state of FIG. 41 to be smaller (the absolute value is smaller) than the reset voltage for attaining the state of FIG. 42.

As with the reset voltage, when the set voltage is set by utilizing the difference in the mobility of the chalcogenide layers ML1a, ML1b, and ML1c, the state of the conductive path CDP can be changed from the state of FIG. 42 to the states of FIG. 39 to FIG. 41. For example, the set operation utilizing the difference in the mobility of the chalcogenide layers ML1a, ML1b, and ML1c can be carried out by setting the set voltage for attaining the state of FIG. 39 to be larger (the absolute value is larger) than the set voltage for attaining the state of FIG. 40, alternatively, by setting the set voltage for attaining the state of FIG. 40 to be larger (the absolute value is larger) than the set voltage for attaining the state of FIG. 41.

The read voltage for reading the information stored in the memory element RM (memory layer ML) is set to a value which does not cause the elements (particularly, the element(s) α) in the memory layer ML to move both in the first layer ML1 and the second layer ML2 (in other words, the state of the conductive path CDP is not changed). When such a read voltage is applied between the bottom electrode BE and the top electrode TE, it can be read which one the resistance value of the memory layer ML (memory element RM) corresponds to the states of FIG. 39 to FIG. 42, that is, the memory information of the memory element RM.

In the order of FIG. 39 to FIG. 42, the resistance of the memory layer ML, that is, the resistance of the memory element RM is increased. When the reset voltage or the set voltage which is set by utilizing the difference of the mobility of the chalcogenide layers ML1a, ML1b, and ML1c is applied, the state of the conductive path CDP between the bottom electrode BE and the top electrode TE can be changed in the memory layer ML of each memory cell by causing the elements (mainly, the element(s) α) in the memory layer ML to move in the memory layer ML, thereby changing (transition) the state between the four resistance values of FIG. 39 to FIG. 42. Consequently, the resistance value (resistivity) of the memory layer ML, that is, the resistance value of the memory element RM can be changed between the state of three or more levels, thereby forming a multivalued non-volatile memory element (memory).

As described above, in the present embodiment, the solid electrolyte layer (first layer ML) comprises two or more layers having mutually different composition ratios (the ratio of X, Y, Z) expressed by the composition formula α_{X}β_{Y}γ_{Z}, wherein 0.2≦X≦0.7, 0.03≦Y≦0.4, 0.2≦Z≦0.6, and X+Y+Z=1, thereby facilitating control of the thickness or the reaching position of the distal end of the part of the conductive path CDP in the vertical direction and enabling multivalued recording.

Also in the present embodiment, the top electrode TE1 of the above-described second embodiment can be used instead of the top electrode TE.

### Fourth Embodiment

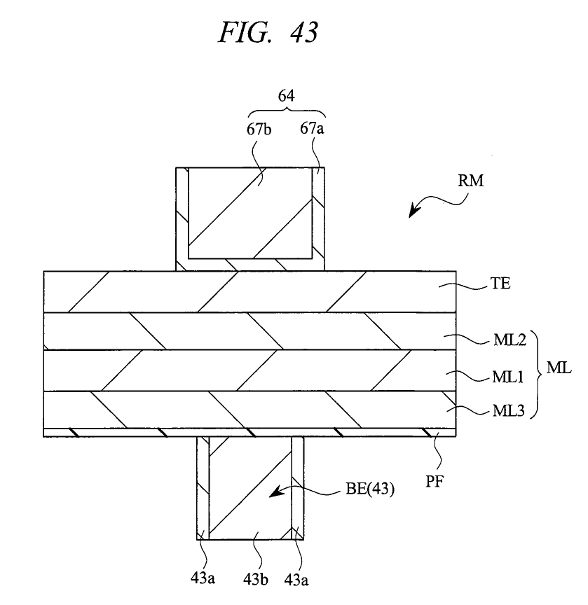

FIG. 43 is an explanatory diagram (cross sectional view) schematically showing a memory element RM in a semiconductor device of the present embodiment and corresponds to FIG. 1 of the above-described embodiment.

In the memory cell of the above-described first embodiment, the memory layer ML is formed by the first layer ML1 and the second layer ML2 adjacent to the first layer ML. However, the memory element RM of the present embodiment has, in addition to the first layer ML1 and the second layer ML2 adjacent to the first layer ML, a third layer ML3 which is adjacent to the surface which is at the opposite side to the side where the second layer ML2 are neighbors the first layer ML1. In other words, in the present embodiment, the memory layer ML further has the third layer ML3 which neighbors the first layer ML1 in the side opposite to the side where the second layer ML2 neighbors the first layer ML1 and is positioned between the bottom electrode BE and the first layer ML1. The memory element RM of the present embodiment has a constitution similar to the memory element RM of the above-described first embodiment except that the third layer ML3 is provided in the memory layer ML; therefore, except for the third layer ML3 of the memory layer ML, the descriptions thereof will be omitted.

The third layer ML (metal oxide layer) is a layer which can function as an ion feeding layer as well as the second layer ML2. As well as the second layer ML2, the third layer ML3 also comprises a material containing, as a main component, at least one element selected from the first element group, at least one element selected from the second element group, and oxygen (O). The first element group and the second element group are as described above in the first embodiment.

As with the second layer ML2, the third layer ML3 is also preferred to comprise a material containing 5 at. % or more and 50 at. % or less of at least one element selected from the first element group (particularly preferably, Cu, Ag), containing 10 at. % or more and 50 at. % or less of at least one element selected from the second element group (particularly preferably, Ta, V, Nb, Cr), and containing 30 at. % or more and 70 at. % or less of O (oxygen). The third layer ML3 may contain 10 at. % or less of the other elements (the elements other than those of the above-described first element group, the second element group, and oxygen).

In other words, the third layer ML3 of the memory layer ML preferably has the composition expressed by the composition formula α_{X}β_{Y}O_{Z}, where 0.05≦X≦0.5, 0.1≦Y≦0.5, 0.3≦Z≦0.7, and X+Y+Z=1. Note that, α, β, and O in the above-described composition formula α_{X}β_{Y}O_{Z} of the third layer ML3 are same as that described about the composition formula α_{X}β_{Y}O_{Z} of the second layer ML2 of the memory layer ML in the first embodiment; therefore, the description thereof will be omitted here. The above-described composition α_{X}β_{Y}O_{Z} of the third layer ML3 shown herein is the composition expressed by an average composition of the third layer ML3 in the film thickness direction.

More preferably, the element which is contained in the first layer ML1 and belongs to the first element group, the element which is contained in the second layer ML2 and belongs to the first element group, and the element which is contained in the third layer ML3 and belongs to the first element group are the same. For example, when the element which is contained in the first layer ML1 and belongs to the first element group is Cu, the element which is contained in the second layer ML2 and belongs to the first element group is also preferred to be Cu, and the element which is contained in the third layer ML3 and belongs to the first element group is also preferred to be Cu. Consequently, the conductive path can be more appropriately formed in the memory layer ML.

More preferably, the element which is contained by the first layer ML1 and belongs to the second element group, the element which is contained by the second layer ML2 and belongs to the second element group, and the element which is contained by the third layer ML3 and belongs to the second element group are the same. Consequently, there is an advantage that characteristics are not readily changed even when rewrite is repeated.

The compositions of the first layer ML1 and the third layer ML3 are further preferred to be the same (the contained elements and the content rates thereof are the same), since the symmetrical property of the memory layer ML is enhanced.

In the present embodiment, another layer (third layer ML3) like the ion feeding layer (second layer ML2) is added so as to form the structure sandwiching the solid electrolyte layer (first layer ML1); therefore, although asymmetric property of the shapes of the upper and lower electrodes (the top electrode TE and the bottom electrode BE) remains in terms of the structure, the memory element RM can be driven by a voltage of one direction since the asymmetric property of the vertical layer constitution is reduced. Drive of the memory element RM by the one-direction voltage will be described.

In the above-described first embodiment, to cause the memory layer between the bottom electrode BE and the top electrode TE to be in the high-resistance state (reset state), the reset voltage, which causes the electric potential of the bottom electrode BE to be higher than that of the top electrode TE, is applied between the bottom electrode BE and the top electrode TE; and, to cause the memory layer between the bottom electrode BE and the top electrode TE to be in the low-resistance state (set state), the set voltage, which causes the electric potential of the bottom electrode BE to be lower than that of the top electrode, is applied between the bottom electrode BE and the top electrode TE. In other words, the reset voltage and the set voltage are the voltages of the opposite directions. On the other hand, in the present embodiment, to cause the memory layer between the bottom electrode BE and the top electrode TE is to be in the high-resistance state (reset state), the reset voltage, which causes the electric potential of the bottom electrode BE to be lower than that of the top electrode TE is applied between the bottom electrode BE and the top electrode TE; and, to cause the memory layer between the bottom electrode BE and the top electrode TE to be the low-resistance state (set state), the set voltage, which causes the electric potential of the bottom electrode BE to be lower than that of the top electrode TE is applied between the bottom electrode and the top electrode TE. In other words, the reset voltage and the set voltage are the voltages of the same direction.

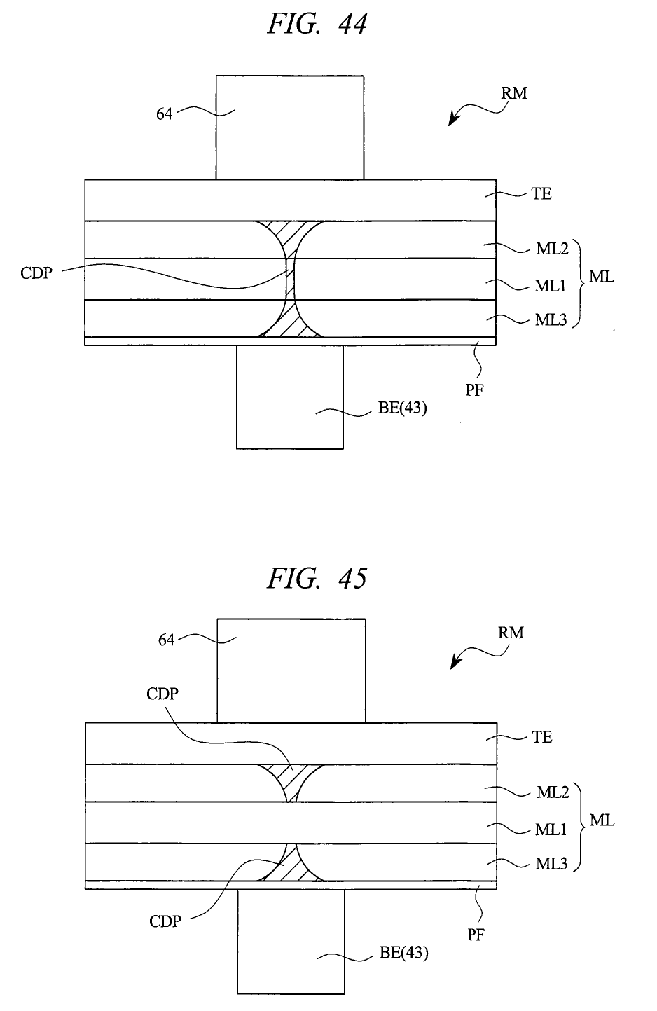

FIG. 44 is an explanatory diagram (cross sectional view) schematically showing the memory element RM of a state (set state, ON state) where the conductive path CDP is formed so as to connect the bottom electrode BE and the top electrode TE to each other in the memory layer ML and corresponds to FIG. 2 of the above-described first embodiment. FIG. 45 is an explanatory diagram (cross sectional view) schematically showing the memory element RM in a state (reset state, OFF state) where the conductive path CDP is disconnected between the bottom electrode BE and the top electrode TE in the memory layer ML and corresponds to FIG. 3 of the above-described first embodiment. FIG. 44 and FIG. 45 are same cross sectional views as above-described FIG. 43; however, in order to facilitate viewability of the drawings, merely the region serving as the conductive path CDP and the low-resistance part LRP in the memory layer ML (that is, the region having low resistivity in the memory layer ML) is hatched, and hatching of the other part is omitted.

Also in the memory element RM of the present embodiment, when the initialization voltages similar to that described above in the first embodiment are applied, as shown in FIG. 44, the conductive path CDP in which metal ions are present at a high concentration is formed in the memory layer ML so as to connect the bottom electrode BE and the top electrode TE to each other. In FIG. 44, since the conductive path CDP is formed so as to connect (couple) the bottom electrode BE and the top electrode TE to each other in the memory layer ML, the resistance of the memory layer ML becomes low, and the resistance of the memory element RM becomes low (in other words, the set state is attained).

When the reset voltage is applied in the state (set state) where the conductive path CDP is formed in the memory layer ML so as to connect the bottom electrode BE and the top electrode TE to each other as shown in FIG. 44, the conductive path CDP connecting the bottom electrode BE and the top electrode TE to each other in the memory layer ML can be disconnected as shown in FIG. 45.

In this reset operation, the reset voltage of the direction opposite to that described above in the first embodiment is applied. Specifically, for example, the bottom electrode BE is caused to have a negative electric potential, and the top electrode TE is caused to have a positive electric potential, thereby applying the reset voltage, which causes the electric potential of the bottom electrode BE to be lower than that of the top electrode TE, between the top electrode TE and the bottom electrode BE (in other words, between the plug 64 and the bottom electrode BE).

The reset voltage causes the ions (herein, the element(s) α) in the first layer ML1 (solid electrolyte layer) to gather to the third layer ML3 (ion feeding layer) side at the side of the negative electrode (bottom electrode BE) so as to disconnect a part of the conductive path CDP, and the reset state (OFF state) is attained. Meanwhile, the mobility of the ions in the second layer ML2 and the third layer ML3 (ion feeding layers) is small compared with the first layer ML1; therefore, the conductive path CDP formed in the second layer ML2 and the third layer ML3 (ion feeding layers) is maintained. Note that, the reason that the mobility of the ions (herein, the element(s) α) is lower in the third layer ML3 compared with the first layer ML1 is the same reason as that the mobility of the ions (herein, the element(s) α) is lower in the second layer ML2 compared with the first layer ML1, which has been described above in the first embodiment.

Therefore, when the reset voltage is applied, the state as shown in FIG. 45 is attained in which the conductive path CDP in the second layer ML2 and the third layer ML3 does not change almost at all, on the other hand, the conductive path CDP is disconnected in the chalcogenide layer ML1 of the first layer ML1. The state that the part between the bottom electrode BE and the top electrode TE is not connected by the conductive path CDP in the memory layer ML is attained; therefore, the resistance of the memory layer ML becomes high, and the resistance of the memory element RM becomes high.

On the other hand, when the set voltage is applied in the state (reset state, OFF state) where the conductive path CDP between the bottom electrode BE and the top electrode TE is disconnected in the memory layer ML as shown in FIG. 45, the part between the bottom electrode BE and the top electrode TE can be connected again by the conductive path CDP in the memory layer ML as shown in FIG. 44.

In this set operation, the set voltage of the direction same as that described above in the first embodiment is applied. In other words, for example, the bottom electrode BE is caused to have a negative electric potential, and the top electrode TE is caused to have a positive electric potential, thereby applying the set voltage, which causes the electric potential of the bottom electrode BE to be lower than that of the top electrode TE, between the top electrode TE and the bottom electrode BE (that is, between the plug 64 and the bottom electrode BE). Therefore, the set voltage and the reset voltage are in the same direction.

The set voltage causes the part of the first layer ML1 (solid electrolyte layer) that is positioned on the extended line of the conductive path CDP remaining in the second layer ML2 and the third layer ML3 (ion feeding layers) to generate heat, the ions (herein, the element(s) α) thermally diffuse into the first layer ML1 so as to restore the conductive path CDP, and the set state (ON state) is attained again. Specifically, as shown in FIG. 44, the state in which the conductive path CDP is formed so as to connect the bottom electrode BE and the top electrode TE to each other is attained in the memory layer ML, the resistance of the memory layer ML becomes low, and the resistance of the memory element RM becomes low. Such control can be realized by changing the magnitude or the application time of the voltages of the reset voltage and the set voltage.

In order to read the information stored in the memory element RM (memory layer ML), the read voltage is set to have a value which does not cause the ions (element(s) α) to move in the first layer ML1, the second layer ML2, and the third layer ML3 (in other words, the state of the conductive path CDP is not changed), and the read voltage is applied between the top electrode TE and the bottom electrode BE (that is, between the plug 64 and the bottom electrode BE) so that the electric potential of the bottom electrode BE is lower than that of the top electrode TE. Consequently, which the resistance value of the memory layer ML (memory element RM) is, in the low-resistance state like the set state of FIG. 44 or in the high-resistance state like the reset state of FIG. 45, that is, the memory information of the memory element RM can be read.

In this manner, the memory layer ML has the structure in which the first layer ML1 serving as the solid electrolyte layer is sandwiched by the second layer ML2 and the third layer ML3 having lower mobility of ions than the first layer, and the reset voltage and the set voltage are controlled as the voltages of the same direction. Consequently, even in the reset state (OFF state), the conductive path CDP is substantially maintained in the second layer ML2 and the third layer ML3 (ion feeding layers), and the maintained conductive path CDP substantially determines the position and thickness of the conductive path CDP that is restored in the first layer ML1 upon setting. Therefore, rewriting can be stably performed by repeating ON (set) and OFF (reset) by the one-direction voltage.

In the case where switching between the set state (low-resistance state) and the reset state (high-resistance state) is performed by moving the ions merely by the voltages in one direction as described in the present embodiment, to attain the reset state, the ions (element(s) α) constituting the conductive path CDP in the first layer ML1 are, at least partially, caused to diffuse into the direction perpendicular to the extending direction of the conductive path CDP (filament-like conductive path CDP), that is, the in-plane direction of the first layer ML1, for example, by the heat generation caused by the current. In this case, when the set state is to be attained again next time, instead of pulling the ions from the top, converging the diffused ions in the direction the original conductive path CDP has been present is preferred. Such converging can be realized by causing negative ions to remain at the location where the conductive path CDP has been present before the reset state is attained. Specifically, it can be realized by causing a strong pulse to flow through the conductive path CDP upon reset and causing the metal ions (element(s) α) to diffuse at once.

The memory element RM of the present embodiment as shown in FIG. 43 can also be driven (controlled) by the reset voltage and the set voltage as described above in the first embodiment (in other words, by causing the reset voltage and the set voltage to be the voltages of the opposite directions).

Also, the memory elements RM of the above-described first to third embodiments can also be driven (controlled) by the reset voltage and the set voltage described in the present embodiment (in other words, by causing the reset voltage and the set voltage to be the voltages of the same direction).

However, since the structure of the memory layer ML is vertically asymmetric in each of the memory elements RM of the above-described first to third embodiments, they are more suitable for controlling the state (the set state or the reset state) of the conductive path CDP by causing the reset voltage and the set voltage to be the voltages of mutually different directions as described above in the first embodiment. On the other hand, as described in the present embodiment, the memory element RM of the structure like the present embodiment is more suitable for controlling the state (the set state or the reset state) of the conductive path CDP by causing the reset voltage and the set voltage to be the voltages of the same direction, since the structure of the memory layer ML is more vertically symmetric.

Also in the present embodiment, the top electrode TE1 of the above-described second embodiment can be also used instead of the top electrode TE.

Also in the present embodiment, the first layer ML1 of the memory layer ML can have the multilayer structure like the above-described third embodiment.

### Fifth Embodiment

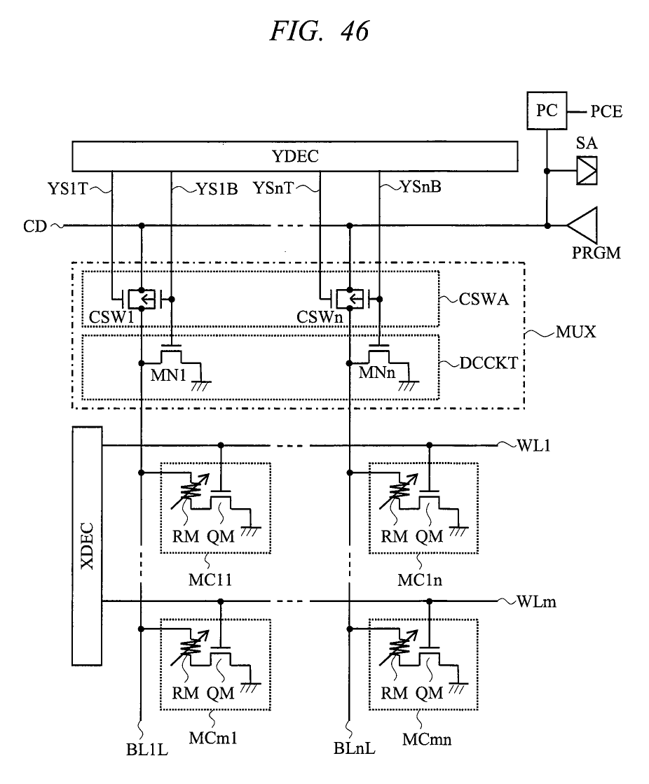

A configuration example of a memory array (memory cell array) of a semiconductor device of another embodiment of the present invention will be described with reference to a circuit diagram of FIG. 46. In the semiconductor device of the present embodiment, the circuit configuration of the memory cell array formed by the memory elements RM, and the like and the peripheral part thereof is different from the above-described first embodiment; however, the configuration of the memory element RM itself in the present embodiment is same as the memory elements RM of the above-described first to fourth embodiments; therefore, the descriptions thereof will be omitted here.

FIG. 46 is a circuit diagram showing a configuration example of the memory array (memory cell array) of the semiconductor device of the present embodiment and a peripheral part thereof and corresponds to FIG. 19 of the above-described first embodiment.

The circuit configuration of the present embodiment shown in FIG. 46 is an example of a configuration of the memory array (memory cell array) using the memory elements RM using the memory layers ML described above in the first to fourth embodiments and a feature thereof is to carry out operation by applying a high voltage to the top electrode (corresponding to the top electrode TE, that is, the top electrode film 53) side with respect to the bottom electrode (corresponding to the bottom electrode BE, that is, the plug 43).

The circuit of the semiconductor device of the present embodiment shown in FIG. 46 comprises the memory array, a multiplexer MUX, a row decoder XDEC, a column decoder YDEC, a precharge circuit PC, a sense amplifier SA, and a rewriting circuit PRGM.

The memory array has the configuration in which memory cells MC11 to MCmn are disposed at intersecting points of word lines WL1 to WLm and bit lines BL1 to BLn, respectively. Each of the memory cells has a configuration in which the memory element RM and the memory cell transistor QM connected in series are inserted between the bit line BL and a ground voltage VSS terminal, and one end of the memory element RM is connected to the bit line BL. The memory element RM herein has any of the configurations as described above in the first to fourth embodiments. Specifically, the top electrode TE is connected to the bit line BL, and the bottom electrode BE is connected to one end of the memory cell transistor QM.

The word line WL (WL1 to WLm) which is an output signal of the row decoder XDEC is connected to the gate (gate electrode) of the memory cell transistor QM. The precharge circuit PC, the sense amplifier SA, and the rewriting circuit PRGM are connected to a common data line CD, respectively. The precharge circuit PC is activated by a precharge activation signal PCE of a high level (herein, power supply voltage VDD) so as to drive the common data line CD to a read voltage VRD (voltage level will be described later).

The multiplexer MUX comprises a column select switch array CSWA and a discharge circuit DCCKT. The column select switch array CSWA comprises a plurality of CMOS transmission gates (column select switches) CSW1 to CSWn inserted between the bit lines BL1 to BLn and the common data line CD. Each of the CMOS transmission gates CSW1 to CSWn is formed by CMISFET (Complementary Metal Insulator Semiconductor Field Effect Transistor). Column select line pairs (YS1T, YS1B) to (YSnT, YSnB) serving as output signals of the column decoder YDEC are connected to the gate electrodes of the CMOS transmission gates CSW1 to CSWn, respectively. When one of the column select line pairs (YS1T, YS1B) to (YSnT, YSnB) is activated, the corresponding CMOS transmission gate is activated, thereby connecting one of the bit lines BL1 to BLn is connected to the common data line CD.

The discharge circuit DCCKT comprises NMOS transistors MN1 to MNn inserted between the bit lines BL1 to BLn and the ground voltage VSS terminals, respectively. In the present application, an n-channel type MISFET is denoted as an NMOS transistor, and a p-channel type MISFET is denoted as a PMOS transistor. The column select lines YS1B to YSnB are connected to the gate electrodes of the NMOS transistors MN1 to MNn, respectively. During standby, when the column select lines YS1B to YSnB are maintained at the power supply voltage VDD, the NMOS transistors MN1 to MNn are conducted, and the bit lines BL1 to BLn are driven to the ground voltage VSS.

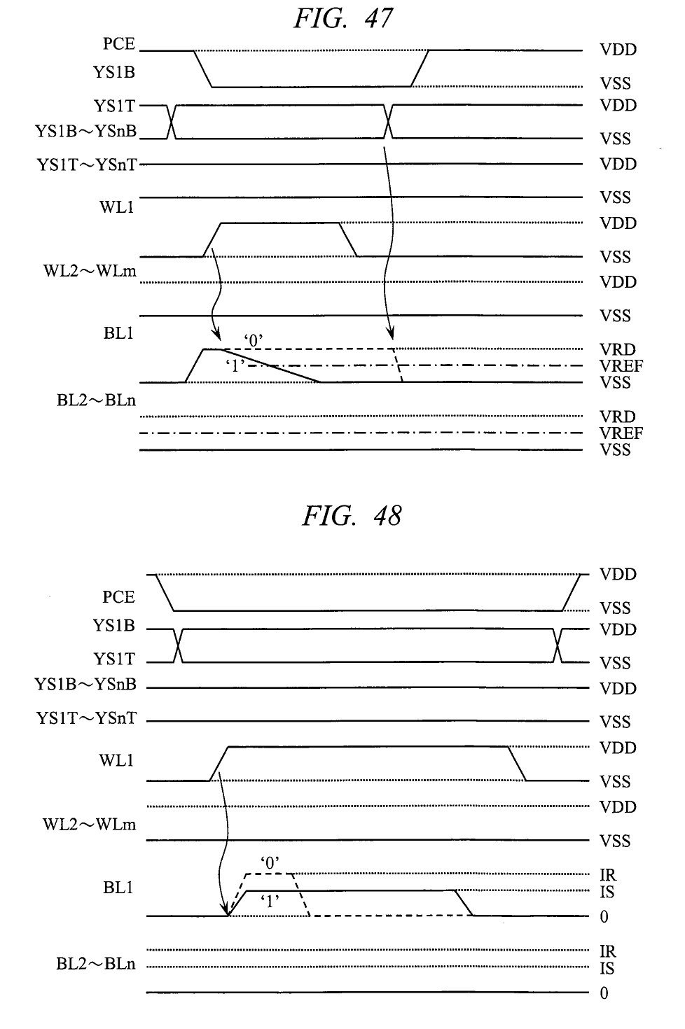

A read operation as shown in FIG. 47 is carried out by such a circuit configuration. With reference to FIG. 47 and above-described FIG. 46, a read operation of the memory cell using the array configuration shown in FIG. 46 will be described. Hereinafter, descriptions will be given on the assumption that the memory cell MC11 is selected. Herein, FIG. 47 shows an example of operation waveforms (voltage application waveforms) of the case in which the memory cell MC11 is selected.

First, the column select switch CSW1 corresponding to the column select line pair (YS1T, YS1B) selected by the column decoder YDEC is conducted, thereby connecting the bit line BL1 and the common data line CD. At this point, the activated precharge circuit PC precharges the bit line BL1 to a read voltage VRD via the common data line CD. The read voltage VRD is designed to have a voltage level between the power supply voltage VDD and the ground voltage VSS so that destruction of the memory information does not occur.

Next, the precharge activation signal PCE having the power supply voltage VDD is driven to the ground voltage VSS, thereby causing the precharge circuit PC to be in a non-active state. Furthermore, the memory cell transistor QM on the word line (WL1) selected by the row decoder XDEC is conducted, thereby forming a current path in the memory cell MC11 and generating a read signal in the bit line BL1 and the common data line CD.

The resistance value in the selected memory cell is different depending on the memory information; therefore, the voltage output to the common data line CD is different depending on the memory information. Herein, when the memory information is ‘1’, the resistance value in the memory cell is low, the bit line BL1 and the common data line CD are discharged to the ground voltage VSS, thereby having a voltage lower than a reference voltage VREF. On the other hand, when the memory information is ‘0’, the resistance value in the memory cell is high, and the bit line BL1 and the common data line CD are maintained in the precharge state, that is, the read voltage VRD. This difference is determined by the sense amplifier SA, thereby reading the memory information of the selected memory cell. Finally, the column select line pair (YS1T, YS1B) is caused to be a non-active state so as to conduct the NMOS transistor MN1, thereby driving the bit line BL1 to the ground voltage VSS and driving the precharge activation signal PCE having the ground voltage VSS to the power supply voltage VDD so as to activate the precharge circuit PC; thus, it is returned to a standby state.

Furthermore, according to FIG. 48, a write operation of the memory cell using the memory array configuration shown in above-described FIG. 46 will be described. FIG. 48 shows a write operation of the memory array shown in FIG. 46. Hereinafter, as well as above-described FIG. 47, descriptions will be given on the assumption that the memory cell MC11 is selected. Therefore, in FIG. 48, an example of operation waveforms (voltage application waveform) of the case in which the memory cell MC11 is selected is shown.

First, the precharge activation signal PCE having the power supply voltage VDD is driven to the ground voltage VSS, thereby causing the precharge circuit to be a non-active state. Subsequently, the column select switch CSW1 corresponding to the column select line pair (YS1T, YS1B) selected by the column decoder YDEC is conducted, thereby connecting the bit line BL1 and the writing circuit PRGM via the common data line CD. Next, the memory cell transistor QM on the word line (WL1) selected by the row decoder XDEC is conducted, thereby forming a current path in the memory cell MC11, and a writing current flows through the bit line BL1.

The writing circuit PRGM is designed so that the writing current and the application time thereof have the values corresponding to memory information. Herein, when the memory information is ‘0’, a large reset current IR is applied for a short period of time. On the other hand, when the memory information is ‘1’, a set current IS smaller than the reset current IR is applied for a longer period of time than the reset current. Finally, the column select line pair (YS1T, YS1B) is caused to be the non-active state so as to cause the transistor MN1 to conduct, thereby driving the bit line BL1 to the ground voltage VSS and driving the precharge activation signal PCE having the ground voltage VSS to the power supply voltage VDD so as to activate the precharge circuit PC; thus, it returns to the standby state.

As described above, in the present embodiment, the semiconductor device having the circuit configuration as shown in FIG. 46 is formed by using the memory elements RM as described in the above-described embodiments; as a result, the semiconductor device having high heat resistance property and stable data retention characteristics can be realized.

In the circuit configuration of the present embodiment, set and reset is performed by the voltages of the same direction; therefore, instead of the select transistor and the memory element, a select diode and memory element connected in series can be disposed at each of the intersecting points of the memory matrix; consequently, fabrication is facilitated. However, since reset is carried out by causing the ions forming the conductive path to laterally diffuse by a large current for a short period of time; when rewriting is repeated, the distribution of the ionized element is readily changed, and the number of rewritable times is limited.

### Sixth Embodiment

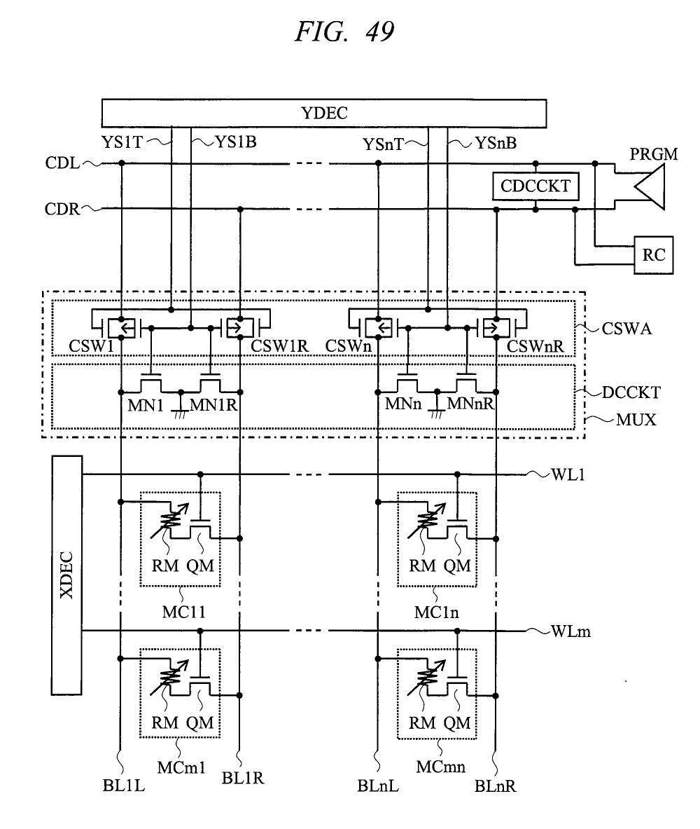

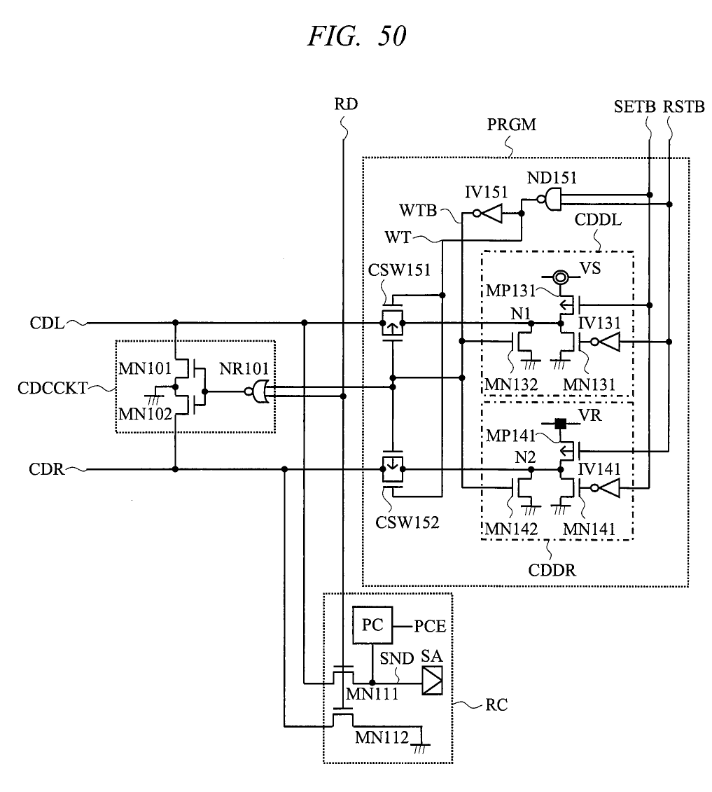

A configuration example of a memory array (memory cell array) of a semiconductor device of another embodiment of the present invention will be described with reference to the circuit diagram of FIG. 49. In the semiconductor device of the present embodiment, the circuit configuration of the memory cell array formed by the memory elements RM, and the like and the peripheral part thereof is different from the above-described first embodiment; however, the configuration of the memory element RM itself in the present embodiment is same as the memory elements RM of the above-described first to fourth embodiments; therefore, the description thereof will be omitted.

FIG. 49 is a circuit diagram showing a configuration example of the memory array (memory cell array) of the semiconductor device of the present embodiment and the peripheral part thereof and corresponds to FIG. 19 of the above-described first embodiment or FIG. 46 of the above-described fifth embodiment.

The circuit configuration of the present embodiment shown in FIG. 49 is an example of the memory array (memory cell array) configuration using the memory elements RM using the memory layers ML described above in the first to fourth embodiments and a feature thereof is that the set operation and the reset operation are carried out by the voltages of the mutually opposite directions (that is, the set voltage and the reset voltage as described above in the first embodiment).

In the voltage/current characteristics, when the opposite-direction voltage is applied (that is, when the reset operation is carried out), the ionized metal atoms move in the direction opposite to that in the setting, the conductive path is reset, and it returns to the high-resistance state as shown by a dotted line in above-described FIG. 4.

The circuit configuration of the semiconductor device according to the present embodiment shown in FIG. 49 has a circuit configuration different from that of the above-described fifth embodiment since the voltages of the mutually opposite directions are applied, and an example of the circuit configuration and operation thereof will be described.

FIG. 49 shows the memory array configuration having n×m bit memory cells as with above-described FIG. 46. The elements constituting the memory cell are also the memory cell transistor QM and the memory element RM. The present embodiment is characterized in that another bit line is added, although the bit line is one line in above-described FIG. 46, the memory cell is disposed at each intersecting point of a bit line pair and a word line, and the voltage of the opposite direction can be applied to the memory element RM. Hereinafter, focusing on the points different from above-described FIG. 46, the circuit configuration of the semiconductor device of the present embodiment shown in FIG. 49 will be described.

The circuit of the semiconductor device of the present embodiment shown in FIG. 49 comprises the memory array, the multiplexer MUX, the row decoder XDEC, the column decoder YDEC, the reading circuit RC, the rewriting circuit PRGM, and, in addition to that, a common discharge circuit CDCCKT. The memory array has the configuration in which the memory cells MC11 to MCmn are disposed at the intersecting points of the word lines WL1 to WLm and the bit line pairs (BL1L and BL1R) to (BLnL and BLnR), respectively. Each of the memory cells has the configuration in which the memory elements RM and the select transistors QM connected in series are inserted between the bit lines BL1L to BLnL and the bit lines BL1R to BLnR, respectively. Herein, the memory element RM has any of the configurations as described above in the first to fourth embodiments, the top electrode TE is connected to the side of the bit lines BL1L to BLnL, and the above-described bottom electrode BE is connected to one end of the memory cell transistor QM.

The reading circuit RC, the rewriting circuit PRGM, and the common discharge circuit CDCCKT are connected to the common data line pair (CDL, CDR), respectively. The part corresponding to the bit lines BL1R to BLnR is added to the column select switch array CSWA and the discharge circuit DCCKT in the multiplexer MUX. Specifically, CMOS transmission gates (column select switches) CSW1R to CSWnR inserted between the bit lines BL1R to BLnR and the common data line CDR are added to the column select switch array CSWA, respectively. The gate electrodes of the CMOS transmission gates CSW1 to CSWn and CSW1R to CSWnR are connected to the column select line pairs (YS1T, YS1B) to (YSnT, YSnB) which are output signals of the column decoder YDEC, respectively. When one of the column select line pairs (YS1T, YS1B) to (YSnT, YSnB) is activated, the corresponding pair of the CMOS transmission gates is activated, and one pair of the bit line pairs (BL1L, BL1R) to (BLnL, BLnR) is connected to the common data line pair (CDL, CDR).

In the discharge circuit DCCKT, NMOS transistors MN1R to MNnR inserted between the bit lines BL1R to BLnR and the ground voltage VSS, respectively, are added. The gate electrodes of the NMOS transistors MN1R to MNnR are connected to the column select lines YS1B to YSnB. During standby, the column select lines YS1B to YSnB are maintained at the power supply voltage VDD, thereby conducting the NMOS transistors MN1L to MNnL and MN1R to MNnR and driving the bit line pairs (BL1L, BL1R) to (BLnL, BLnR) to the ground voltage VSS.

FIG. 50 is a circuit diagram showing a detailed configuration (circuit configuration) example of the common discharge circuit CDCCKT, the reading circuit RC, and the rewriting circuit PRGM of above-described FIG. 49.

The common discharge circuit CDCCKT comprises NMOS transistors MN101 and MN102 and an NOR circuit NR101. The NMOS transistor MN101 is inserted between the common data line CDL and the ground voltage VSS, and the NMOS transistor MN102 is inserted between the common data line CDR and the ground voltage VSS. To each of the gate electrodes thereof, the output terminal of the NOR circuit NR101 is connected.

A reading activation signal RD and a rewrite activation signal WT, which will be described later, are input to an input terminal of the NOR circuit NR101. In a standby state, these signals are maintained at the ground voltage VSS; therefore, when the NMOS transistors MN101 and MN102 are conducted, the common data line pair (CDL and CDR) are driven to the ground voltage VSS. On the other hand, in a read operation, the reading activation signal RD is driven to the power supply voltage VDD; and, in a rewrite operation, the rewrite activation signal WT is driven to the power supply voltage VDD; therefore, the NMOS transistors MN101 and MN102 are cut off in these operations.

The reading circuit RC comprises NMOS transistors MN111 and MN112, a precharge circuit PC, and a sense amplifier SA. The precharge circuit PC is connected to the sense amplifier SA via a node SND. The precharge circuit PC is activated by the precharge activation signal PCE, which is at a high level (herein, the power supply voltage VDD), and drives the node SND, and the like to the reading voltage VRD. The NMOS transistor MN111 is inserted between the common data line CDL and the sense amplifier SA, and the NMOS transistor MN112 is inserted between the common data line CDR and the ground voltage VSS. The reading activation signal RD is input to the gate electrodes of these transistors.

As described above, the reading activation signal RD is maintained at the ground voltage VSS in a standby state; therefore, in this case, the NMOS transistors MN111 and MN112 are cut off. On the other hand, in a read operation, the reading activation signal RD having the ground voltage VSS is driven to the power supply voltage VDD; therefore, when the NMOS transistors MN111 and MN112 are conducted, the common data line CDL is connected to the precharge circuit PC and the sense amplifier SA, and the common data line CDR is connected to the ground voltage VSS. By the above configuration, in a read operation, the source electrode of the transistor QM in the selected memory cell is driven to the ground voltage VSS by the common data line CDR via the bit lines BL1R to BLnR. When a reading signal corresponding to memory information is input to the sense amplifier from the bit lines BL1L to BLnL via the common data line CDL, the read operation similar to that of above-described FIG. 47 can be carried out.

The rewriting circuit PRGM comprises common data line driving circuits CDDL and CDDR, CMOS transmission gates CSW151 and CSW152, a NAND circuit ND151, and an inverter circuit IV151. The CMOS transmission gate CSW151 is inserted between the common data line CDL and the common data line drive circuit CDDL, and the CMOS transmission gate CSW152 is inserted between the common data line CDR and the common data line drive circuit CDDR. To the gate electrodes thereof, connected are rewrite activation signals WT and WTB which are obtained as a result of subjecting a set activation signal SETB and a reset activation signal RSTB to an AND operation by using the NAND circuit ND151 and the inverter circuit IV151, respectively.

Herein, the set activation signal SETB and the reset activation signal RSTB are maintained at the power supply voltage VDD in a standby state; therefore, when the rewrite activation signal WT and the rewrite activation signal WTB are maintained at the ground voltage VSS and the power supply voltage VDD, respectively, the common data lines CDL and CDR and the common data line drive circuits CDDL and CDDR are disconnected. On the other hand, in a rewrite operation, the set activation signal SETB or the reset activation signal RSTB is driven to the ground voltage VSS; therefore, WT and WTB are driven to the power supply voltage VDD and the ground voltage VSS, respectively, and CSW151 and CSW152 are conducted; consequently, the common data lines CDL and CDR and the common data line drive circuits CDDL and CDDR are connected.

The common data line drive circuit CDDL comprises a PMOS transistor MP131, NMOS transistors MN131 and MN132, and an inverter circuit IV131. Between the set voltage VS and the ground voltage VSS, the PMOS transistor MP131 and the NMOS transistor MN131 are inserted, and the drain electrode thereof serves as a node N1. The node N1 and the transmission gate CSW 151 are connected to each other, and the NMOS transistor MN132 is inserted between the node N1 and the ground voltage VSS.

The set activation signal SETB is connected to the gate electrode of the PMOS transistor MP131. In a set operation, when the set activation signal SETB having the power supply voltage VDD is driven to the ground voltage VSS, the PMOS transistor MP131 is conducted, thereby applying the set voltage VS to the common data line CDL via the transmission gate CSW151. A signal obtained by inverting the reset activation signal RSTB by the inverter circuit IV131 is connected to the gate electrode of the NMOS transistor MN131. In a reset operation, when the reset activation signal RSTB having the power supply voltage VDD is driven to the ground voltage VSS, the NMOS transistor MN131 is conducted, thereby applying the ground voltage VSS to the common data line CDL via the transmission gate CSW151. The rewrite activation signal WTB is connected to the gate electrode of the NMOS transistor MN132. The rewrite activation signal WTB is maintained at the power supply voltage VDD in a standby state; therefore, when the NMOS transistor MN132 is conducted, the ground voltage VSS is applied to the node N1.

The common data line drive circuit CDDR comprises a PMOS transistor MP141, NMOS transistors MN141 and MN142, and an inverter circuit IV141. Between the reset voltage VR and the ground voltage VSS, the transistor MP141 and the NMOS transistor MN141 are inserted, and the drain electrode thereof serves as a node N2. The node N2 and the transmission gate CSW152 are connected to each other, and the NMOS transistor MN142 is inserted between the node N2 and the ground voltage VSS.

The reset activation signal RSTB is connected to the gate electrode of the PMOS transistor MP141. In a reset operation, when the reset activation signal RSTB having the power supply voltage VDD is driven to the ground voltage VSS, the PMOS transistor MP141 is conducted, thereby applying the reset voltage VR to the common data line CDR via the transmission gate CSW152. The signal obtained by inverting the set activation signal SETB by the inverter circuit IV141 is connected to the gate electrode of the NMOS transistor MN141. In a set operation, when the set activation signal SETB having the power supply voltage VDD is driven to the ground voltage VSS, the NMOS transistor MN141 is conducted, thereby applying the ground voltage VSS to the common data line CDR via the transmission gate CSW152. The rewrite activation signal WTB is connected to the gate electrode of the NMOS transistor MN142. The rewrite activation signal WTB is maintained at the power supply voltage VDD in a standby state; therefore, when the NMOS transistor MN142 is conducted, the ground voltage VSS is applied to the node N2.

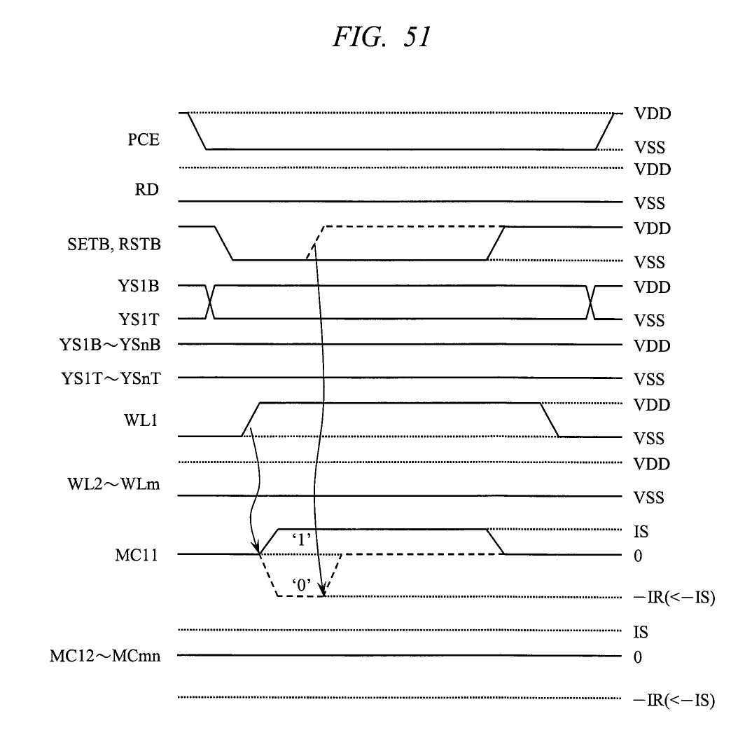

FIG. 51 is a waveform diagram showing an example of the rewrite operation using the rewriting circuit PRGM of above-described FIG. 50. Also in this case, description will be given on the assumption that the memory cell MC11 is selected.

As shown in FIG. 51, in the rewrite operation, a current of the direction corresponding to memory information can be caused to flow through the selected memory cell. Specifically, in the case of a set operation of writing memory information ‘1’, when the set activation signal SETB having the power supply voltage VDD is driven to the ground voltage VSS, the transistors MP131 and MN141 are caused to be in the conducted state. Therefore, in the selected memory cell, a current can be caused to flow in the direction from the memory element RM to the memory cell transistor QM. In the opposite manner, in the case of a reset operation of writing memory information ‘0’, when the reset activation signal RSTB having the power supply voltage VDD is driven to the ground voltage VSS, the transistors MP141 and MN131 are caused to be in the conducted state. Therefore, in the selected memory cell, a current can be caused to flow in the direction from the memory cell transistor QM to the memory element RM.

Herein, in the reset operation, Joule heat larger than the set operation has to be generated. Also, since the memory element RM side serves as the source electrode, the substrate bias drop of the memory cell transistor QM has to be taken into consideration. Therefore, the reset voltage VR is designed to be higher than the set voltage VS so that the reset voltage VP is equal to or less than the power supply voltage VDD, and the absolute value of the reset current is larger than the set current. In such a reset operation, as well as above-described FIG. 48, the reset current (−IR) in the direction opposite to the set current (IS) is caused to flow through the select memory cell MC11 for a short period of time. The absolute value of the reset current (|−IR|) is larger than the set current (IS).

As described above, in the present embodiment, the semiconductor device having the circuit configuration as shown in FIG. 49 and FIG. 50 is formed by using the memory elements RM as described in the above-described embodiments; as a result, the semiconductor device having high heat resistance property and stable data retention characteristics can be realized.

Specifically, in the set operation, for example, a high voltage and a low voltage are applied to the bit line BL1L and the bit line BL1R, respectively; therefore, an electric field is generated in the direction from the top electrode TE (top electrode film 53) of the memory element RM toward the bottom electrode BE (plug 43). Therefore, positive ions in the memory layer ML (memory layer 52) are compressed in the direction toward the bottom electrode BE. In the opposite manner, in the reset operation, for example, a high voltage and a low voltage are applied to the bit line BL1R and the bit line BL1L, respectively; therefore, an electric field is generated in the direction from the bottom electrode BE (plug 43) toward the top electrode TE (top electrode film 53). Therefore, the element ionized to be positive in the memory layer ML (memory layer 52) is returned in the direction toward the top electrode TE (top electrode film 53) along the electrical flux line. On the other hand, in the thermal diffusion by a short period of time of a high current, positive ions are diffused to be uniform. Consequently, local presence of the element caused by the rewrite operation can be avoided, and the number of rewritable times can be improved.

Note that, in the description hereinabove, the specifications of the memory cell transistor QM have not been particularly limited. However, a transistor (MISFET) having a thick gate oxide film (gate insulating film) can be used as the memory cell transistor QM so as to increase the gate voltage. By virtue of such configuration and operation, drive performance deterioration of the memory cell transistor QM due to substrate bias effects caused by the memory element RM can be suppressed, and a sufficiently large reset current can be caused to flow in the direction opposite to that of conventional cases.

### Seventh Embodiment

In the present embodiment, a modified circuit configuration and operations of the semiconductor device of above-described sixth embodiment will be described.

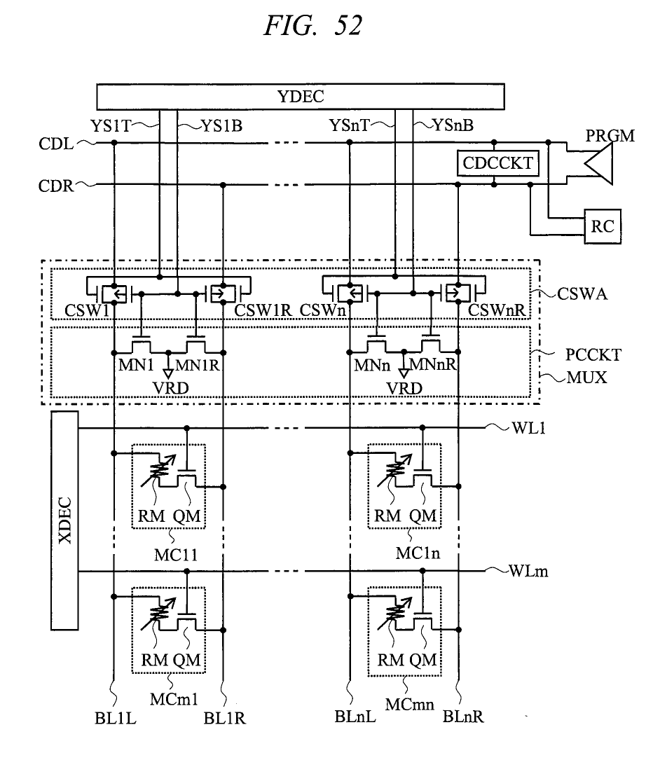

FIG. 52 is a circuit diagram showing a configuration example of a memory array (memory cell array) of a semiconductor device of the present embodiment and a peripheral part thereof and corresponds to FIG. 49 of above-described sixth embodiment.

The characteristics of the circuit configuration of the semiconductor device of the present embodiment shown in FIG. 52 lies in the reading method thereof and the point that the discharge circuit DCCKT shown in above-described FIG. 49 is replaced by a precharge circuit PCCKT as shown in FIG. 52, and the source voltage of the NMOS transistors MN1 to MNn and MN1R to MNnR in the precharge circuit PCCKT serves as the read voltage VRD.

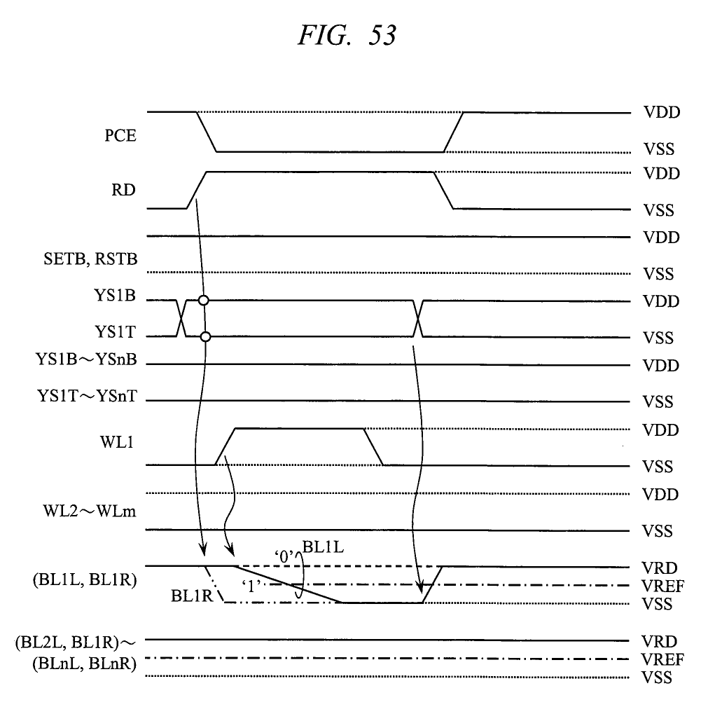

A read operation by such a configuration is shown in FIG. 53. Also in this case, descriptions will be given on the assumption that the memory cell MC11 is selected.

In a standby state, the bit line pairs (BL1L, BL1R) to (BLnL, BLnR) are maintained at the read voltage VRD by the precharge circuit PCCKT. After the column select line pair (YS1T, YS1B) is activated, when the read activation signal RD having the ground voltage VSS is driven to the power supply voltage VDD, the bit line BL1R is discharged via the common data line CDR and then via the NMOS transistor MN112 in the reading circuit RC. Next, when the word line WL1 is activated, the current path in the memory cell MC11 is formed, and a read signal corresponding to the memory information is input to the sense amplifier SA via the bit line BL1L and then via the common data line CDL and the NMOS transistor MN111 in the reading circuit RC. After a sufficient read signal is generated, the word line WL1 and the column select line pair (YS1T, YS1B) is caused to be in a non-active state; consequently, the bit line pair (BL1L, BL1R) is driven to the read voltage VRD by the precharge circuit PCCKT. Finally, the reading activation signal RD having the power supply voltage VDD is driven to the ground voltage VSS, and it returns to the standby state.

By virtue of such a configuration and operations, the reading time can be shortened in addition to the various effects described in above-described sixth embodiment. Specifically, for example, immediately after generation of the read signal, in other words, immediately after the column select line pair (YS1T, YS1B) is inactivated, the precharge operation of the bit line pair (BL1L, BL1R) can be performed in parallel with the operation of the sense amplifier SA; therefore, the time allotted to the precharge operation can be sufficiently ensured. Moreover, since the bit line BL1R is discharged by using the NMOS transistor MN112 in the reading circuit RC, the time for generating an electric potential difference in the bit line pair (BL1L, BL1R) can be shortened. Furthermore, a margin between the activation timing of the column select line pair (YS1L, YS1L) and the activation timing of the word line WL1 is not necessary to be ensured; therefore, the time of the operation of selecting the memory cell MC11 can be shortened. By virtue of the above-described effects, the access time and the cycle time in the read operation can be shortened, and a high-speed semiconductor device (memory) can be realized.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is suitable to be applied to, for example, a semiconductor device having a non-volatile memory element.

What is claimed is:

1. A semiconductor device comprising a memory element having a memory layer and a first electrode and a second electrode respectively formed on both surfaces of the memory layer, the memory element being formed on a semiconductor substrate, wherein
the memory layer has a first layer at the first electrode side and a second layer at the second electrode side neighboring each other,
the first layer comprises a material containing: at least one element selected from a first element group of Cu, Ag, Au, Al, Zn, and Cd; at least one element selected from a second element group of V, Nb, Ta, Cr, Mo, W, Ti, Zr, Hf, Fe, Co, Ni, Pt, Pd, Rh, Ir, Ru, Os, and lanthanoid elements; and at least one element selected from a third element group of S, Se, and Te, and
the second layer comprises a material containing: at least one element selected from the first element group; at least one element selected from the second element group; and oxygen.

2. The semiconductor device according to claim 1, wherein
the first layer comprises a material containing: 20 atom % or more and 70 atom % or less of at least one element selected from the first element group; 3 atom % or more and 40 atom % or less of at least one element selected from the second element group; and 20 atom % or more and 60 atom % or less of at least one element selected from the third element group.

3. The semiconductor device according to claim 2, wherein
the second layer comprises a material containing: 5 atom % or more and 50 atom % or less of at least one element selected from the first element group; 10 atom % or more and 50 atom % or less of at least one element selected from the second element group; and 30 atom % or more and 70 atom % or less of oxygen.

4. The semiconductor device according to claim 3, wherein
the first layer and the second layer comprise the material containing Cu or Ag.

5. The semiconductor device according to claim 4, wherein
the first layer and the second layer comprise the material containing at least one element selected from a group of Ta, V, Nb, and Cr.

6. The semiconductor device according to claim 5, wherein
the first layer comprises the material containing S.

7. The semiconductor device according to claim 3, wherein
the element contained in the first layer and belonging to the first element group and the element contained in the second layer and belonging to the first element group is same.

8. The semiconductor device according to claim 1, wherein
the second electrode neighbors the second layer, and
the second electrode is formed by an element which does not readily diffuse into the second layer.

9. The semiconductor device according to claim 8, wherein
the second electrode contains, as a main component, at least one element selected from a group of W, Mo, Ta, Pt, Pd, Rh, Ir, Ru, Os, and Ti.

10. The semiconductor device according to claim 1, wherein
the second electrode neighbors the second layer; and
the second electrode comprises a material containing: 9 atom % or more and 90 atom % or less of at least one element selected from the first element group; 9 atom % or more and 90 atom % or less of at least one element selected from the second element group; and 1 atom % or more and 40 atom % or less of at least one element selected from a group of O, S, Se, and Te.

11. The semiconductor device according to claim 1, wherein
a thickness of the first layer is 10 to 100 nm, and
a thickness of the second layer is 10 to 100 nm.

12. The semiconductor device according to claim 1, wherein
a layer comprising a chromium oxide or tantalum oxide is formed between the first electrode and the first layer.

13. The semiconductor device according to claim 1, wherein
the first layer is formed by a plurality of layers; and,
in the plurality of layers, the more distant the layer is from the second layer, the larger the content of the element having a largest atomic number among the contained element of the third element group is, or the larger the atomic number of the contained element of the third element group is.

14. The semiconductor device according to claim 1, wherein
the memory layer further has a third layer neighboring the first layer at the side opposite to the side the first layer is adjacent to the second layer, the third layer being positioned between the first electrode and the first layer; and
the third layer comprises a material containing: at least one element selected from the first element group; at least one element selected from the second element group; and oxygen.

15. The semiconductor device according to claim 14, wherein
the third layer comprises the material containing: 5 atom % or more and 50 atom % or less of at least one element selected from the first element group; 10 atom % or more and 50 atom % or less of at least one element selected from the second element group; and 30 atom % or more and 70 atom % or less of oxygen.

16. The semiconductor device according to claim 1, wherein
the memory element stores information when atoms or ions move and physical characteristics are changed in the memory layer.

17. The semiconductor device according to claim 16, wherein
the memory element stores information when the element belonging to the first element group moves in the memory layer and physical characteristics are changed.

18. The semiconductor device according to claim 16, wherein
the memory element stores information by a high-resistance state in which an electrical resistance value of the memory layer between the first electrode and the second electrode is high and a low-resistance state in which the electrical resistance value is low.

19. The semiconductor device according to claim 18, wherein,
when causing the memory layer between the first electrode and the second electrode to be in the high-resistance state, a voltage which causes the electric potential of the first electrode to be higher than the electric potential of the second electrode is applied across the first electrode and the second electrode; and,
when causing the memory layer between the first electrode and the second electrode to be in the low-resistance state, a voltage which causes the electric potential of the first electrode to be lower than the electric potential of the second electrode is applied across the first electrode and the second electrode.

20. The semiconductor device according to claim 18, wherein,
when causing the memory layer between the first electrode and the second electrode to be in the high-resistance state, a voltage which causes the electric potential of the first electrode to be lower than the electric potential of the second electrode is applied across the first electrode and the second electrode; and,
when causing the memory layer between the first electrode and the second electrode to be in the low-resistance state, a voltage which causes the electric potential of the first electrode to be lower than the electric potential of the second electrode is applied across the first electrode and the second electrode.
